(19) United States
(12) Patent Application Publication
(10) Pub. No.: US 2024/0349538 A1
(43) Pub. Date: Oct. 17, 2024

(54) DISPLAY SUBSTRATE AND DISPLAY DEVICE

(71) Applicants: BOE TECHNOLOGY GROUP CO., LTD., Beijing (CN); BEIJING BOE TECHNOLOGY DEVELOPMENT CO., LTD., Beijing (CN)

(72) Inventors: Hongli WANG, Beijing (CN); Pan LI, Beijing (CN); Huifeng WANG, Beijing (CN); Xinxin WANG, Beijing (CN); Xinyin WU, Beijing (CN)

(21) Appl. No.: 18/252,909

(22) PCT Filed: Apr. 11, 2022
(86) PCT No.: PCT/CN2022/086132

§ 371 Date: May 15, 2023

(51) Int. Cl. H10K 59/122; H10K 59/38; H10K 71/13

(52) U.S. Cl. CPC H10K 59/122; H10K 59/38; H10K 71/135

(57) ABSTRACT

A display substrate and a display device are provided. The display substrate includes functional elements including a functional layer and a pixel-defining pattern. The pixel-defining pattern includes openings and a defining portion. The display substrate includes first regions corresponding to the openings and second regions covered by the defining portion; the second regions include recessed regions, the functional layer includes a portion located in the recessed region and a portion located in a light-exiting region, an area of the recessed region is not greater than that of the light-exiting region, heights of a surface closest to the base substrate of the functional layer located in the recessed region relative to the base substrate and located in the light-exiting region adjacent to the recessed region relative to the base substrate are a first height and a second height, and the first height is not greater than the second height.

### TECHNICAL FIELD

At least one embodiment of the present disclosure relates to a display substrate and a display device.

### BACKGROUND

Organic light-emitting diode display panels have attracted widespread attention due to their advantages such as lightweight and thinness, flexible, colorful, high contrast, fast response, etc., and are gradually replacing liquid crystal display panels. Some film layers of the light-emitting functional layer in the organic light-emitting diode display panel can be formed by inkjet printing.

### SUMMARY

Embodiments of the present disclosure provides a display substrate and a display device.

An embodiment of the present disclosure provides a display substrate, which includes a base substrate, a plurality of functional elements and a pixel-defining pattern. The plurality of functional elements are located on the base substrate, the plurality of functional elements are configured to exit light, a functional element includes a functional layer, and the functional layer includes at least one film layer; the pixel-defining pattern includes a plurality of openings and a defining portion surrounding the plurality of openings, and the functional layer is at least partially located in the plurality of openings. The display substrate is distributed with a plurality of first regions and a plurality of second regions, the plurality of first regions respectively correspond to the plurality of openings, at least part of the plurality of second regions are covered by the defining portion, at least one film layer in the functional layer is located in at least part of at least one of the plurality of first regions and located in at least part of at least one of the plurality of second regions, the plurality of first regions are configured to exit light, and the plurality of second regions are provided with at least one light-shielding layer overlapping with the defining portion; the plurality of functional elements include functional elements for exiting light of at least two colors, the functional elements for exiting light of at least two colors include a first color functional element configured to exit first color light and a second color functional element configured to exit second color light, and an area of a light-exiting region of the first color functional element is greater than an area of a light-exiting region of the second color functional element; and the plurality of second regions include a plurality of recessed regions, the at least one film layer of the functional layer includes a portion located in at least one recessed region and a portion located in a light-exiting region adjacent to the at least one recessed region, an area of the at least one recessed region is not greater than an area of the light-exiting region adjacent to the at least one recessed region, a height of a surface, closest to the base substrate, of the least one film layer located in the recessed region relative to the base substrate is a first height, a height of a surface, closest to the base substrate, of the least one film layer located in the light-exiting region adjacent to the recessed region relative to the base substrate is a second height, and the first height is not greater than the second height.

For example, according to an embodiment of the present disclosure, the functional layer includes at least one selected from the group consisting of electroluminescence material, photoluminescence material, electrochromic material, electrowetting material, color filter material and optical medium material.

For example, according to an embodiment of the present disclosure, a maximum thickness of a portion of the functional layer located in a recessed region is greater than a maximum thickness of a portion of the functional layer located in a light-exiting region adjacent to the recessed region, or a maximum thickness of the portion of the at least one film layer in the functional layer located in a recessed region is greater than a maximum thickness of the portion of the at least one film layer in the functional layer located in a light-exiting region adjacent to the recessed region; the maximum thickness is a maximum dimension of the functional layer or the at least one film layer in the functional layer in a direction perpendicular to the base substrate; and the plurality of recessed regions at least include a first recessed region and a second recessed region, the functional layer in the first recessed region includes the same material as the functional layer in the first color functional element, the functional layer in the second recessed region includes the same material as the functional layer in the second color functional element, a distance between a center of the light-exiting region of the first color functional element and a center of the first recessed region corresponding to the first color functional element is a first distance, a distance between a center of the light-exiting region of the second color functional element and a center of the second recessed region corresponding to the second color functional element is a second distance, and the first distance is not equal to the second distance.

For example, according to an embodiment of the present disclosure, a portion, located between light-exiting regions of adjacent functional elements exiting light of a same color, in the defining portion is a first defining portion, and a distance between a center of the recessed region, located between the light-exiting regions of adjacent functional elements exiting light of a same color, and a center of the first defining portion is in a range of 5-40 microns.

For example, according to an embodiment of the present disclosure, at least two recessed regions are provided between the light-exiting regions of adjacent functional elements exiting light with the same color, and the at least two recessed regions are located on at least one side of the center of the first defining portion.

For example, according to an embodiment of the present disclosure, at least two adjacent functional elements arranged along a first direction exit light of a same color, at least two adjacent functional elements arranged along a second direction exit light of different colors, and the first direction intersects with the second direction.

For example, according to an embodiment of the present disclosure, in the first direction, a ratio of dimensions of light-exiting regions of at least two functional elements exiting light of different colors is in a range of 0.7-1.5.

For example, according to an embodiment of the present disclosure, in the second direction, a ratio of dimensions of light-exiting regions of at least two functional elements of different colors is in a range of 0.7-1.5.

For example, according to an embodiment of the present disclosure, the first color functional element is a functional element that emits blue light, and the second color functional element is a functional element that emits green light or a functional element that emits red light; and the first distance is greater than the second distance.

For example, according to an embodiment of the present disclosure, the first color functional element is a functional element that emits red light, the second color functional element is a functional element that emits green light, and the first distance is greater than the second distance; or the first color functional element is a functional element that emits green light, the second color functional element is a functional element that emits red light, and the first distance is greater than the second distance.

For example, according to an embodiment of the present disclosure, orthographic projections of some recessed regions of the plurality of recessed regions on a straight line extending in the first direction are overlapped with each other, and a distance between adjacent recessed regions of the some recessed regions is in a range of 2-50 microns.

For example, according to an embodiment of the present disclosure, an orthographic projection of at least one light-exiting region on a straight line extending in the second direction overlaps with an orthographic projection of a recessed region corresponding to the at least one light-exiting region on the straight line extending in the second direction.

For example, according to an embodiment of the present disclosure, a virtual straight line parallel to the first direction passes through a light-exiting region and a recessed region closest to the light-exiting region, edges close to each other of the light-exiting region and the recessed region intersect with the virtual straight line to form two intersection points, and a distance between the two intersection points is greater than a distance between an orthographic projection of the light-exiting region on a straight line extending in the first direction and an orthographic projection of the recessed region on the straight line extending in the first direction.

For example, according to an embodiment of the present disclosure, a nearest distance between at least two adjacent recessed regions is less than a distance from one recessed region of the at least two adjacent recessed regions to a light-exiting region close to the one recessed region.

For example, according to an embodiment of the present disclosure, a distance between the light-exiting region of the functional element and a nearest adjacent recessed region corresponding to the functional element is less than 30 microns.

For example, according to an embodiment of the present disclosure, thicknesses of two portions, of the at least one film layer on the base substrate, located in the recessed region and another region outside the recessed region are respectively a first sub-thickness and a second sub-thickness; or the at least one film layer on the base substrate includes a portion located in the light-exiting region, and the at least one film layer does not overlap with at least part of the recessed region.

For example, according to an embodiment of the present disclosure, the functional element includes a light-emitting element, the functional layer includes a light-emitting functional layer, the light-emitting element includes a first electrode, the light-emitting functional layer and a second electrode that are stacked sequentially, and the first electrode is located between the light-emitting functional layer and the base substrate; and the at least one film layer includes at least one selected from the group consisting of an insulating layer, the defining portion, and the first electrode.

For example, according to an embodiment of the present disclosure, a portion, located between light-exiting regions of adjacent functional elements exiting light of different colors, in the defining portion is a second defining portion, and a thickness of the at least one film layer in the recessed region is less than a thickness of the at least one film layer in a region where the second defining portion is located; or the at least one film layer is located in the region where the second defining portion is located, and does not overlap with at least part of the recessed region.

For example, according to an embodiment of the present disclosure, a portion, located between light-exiting regions of adjacent functional elements exiting light of different colors, in the defining portion is a second defining portion, and an extending direction of at least part of the second defining portion is identical to an arrangement direction of the adjacent functional elements exiting light of different colors; and an orthographic projection of at least part of the at least one recessed region on the base substrate overlaps with an orthographic projection of the second defining portion on the base substrate, or an orthographic projection of the at least one recessed region on the base substrate is contiguous with an orthographic projection of the second defining portion on the base substrate.

For example, according to an embodiment of the present disclosure, an orthographic projection of the at least one recessed region on the base substrate completely falls within an orthographic projection of the second defining portion on the base substrate.

For example, according to an embodiment of the present disclosure, in a direction perpendicular to the base substrate, a thickness of a portion of the second defining portion located in the recessed region is greater than a thickness of a portion of the second defining portion located in another region outside the recessed region.

For example, according to an embodiment of the present disclosure, a portion, located between light-exiting regions of adjacent functional elements exiting light of a same color, in the defining portion is a first defining portion, a portion, located between light-exiting regions of adjacent functional elements exiting light of different colors, in the defining portion is a second defining portion, and an extending direction of at least part of the second defining portion is identical to an arrangement direction of the adjacent functional elements exiting light of different colors; and a distance between the recessed region, located between light-exiting regions of the adjacent functional elements exiting light of the same color, and a center of the first defining portion is greater than a distance between the recessed region and the second defining portion.

For example, according to an embodiment of the present disclosure, the functional element includes a light-emitting element, the functional layer includes a light-emitting functional layer, the light-emitting element includes a first electrode, the light-emitting functional layer and a second electrode that are stacked sequentially, and the first electrode is located between the light-emitting functional layer and the base substrate; and a thickness of a portion of at least one film layer, on a side of the first electrode away from the base substrate, located in the recessed region is a third sub-thickness, a thickness of at least portions of the at least one film layer, on the side of the first electrode away from the base substrate, located in another region outside the recessed region is a fourth sub-thickness, and the third sub-thickness is not less than the fourth sub-thickness.

For example, according to an embodiment of the present disclosure, the at least one film layer on the side of the first electrode away from the base substrate includes at least one of an organic layer and the functional layer.

For example, according to an embodiment of the present disclosure, the at least one film layer on the side of the first electrode away from the base substrate includes the defining portion.

For example, according to an embodiment of the present disclosure, a thickness of a portion of the defining portion located in the recessed region is at least 0.2 microns thicker than a thickness of a portion of the defining portion located between light-exiting regions of adjacent functional elements exiting light of different colors.

For example, according to an embodiment of the present disclosure, a height, relative to the base substrate, of a portion of the defining portion located in the recessed region is at least 1 micron lower than a height, relative to the base substrate, of a portion of the defining portion located between light-exiting regions of adjacent functional elements exiting light of different colors.

For example, according to an embodiment of the present disclosure, lyophobicity of a portion of the defining portion located in the recessed region is not lower than lyophobicity of a portion of the defining portion located between light-exiting regions of adjacent functional elements exiting light of different colors.

For example, according to an embodiment of the present disclosure, maximum thicknesses of two portions, of the at least one film layer of the functional layer, located in the recessed region and located in a light-exiting region of a functional element corresponding to the recessed region are respectively a first maximum thickness and a second maximum thickness, and the first maximum thickness is not less than the second maximum thickness; or a maximum thickness of an entire portion, of the functional layer, located in the recessed region is not less than a maximum thickness of an entire portion, of the functional layer, located in a light-exiting region of a functional element corresponding to the recessed region.

For example, according to an embodiment of the present disclosure, a distance between a surface, of a portion of the at least one film layer of the functional layer located in the recessed region, away from the base substrate and the base substrate is a third distance, a distance between a surface, of a portion of the at least one film layer of the functional layer located in a light-exiting region of a functional element corresponding to the recessed region, away from the base substrate and the base substrate is a fourth distance, and the fourth distance is greater than the third distance.

For example, according to an embodiment of the present disclosure, a portion, located between light-exiting regions of adjacent functional elements exiting light of different colors, in the defining portion is a second defining portion, and an extending direction of at least part of the second defining portion is identical to an arrangement direction of the adjacent functional elements exiting light of different colors; and a surface of a side, of a portion of the second defining portion close to the light-exiting region, away from the base substrate includes a defining slope, a distance between a surface, of a portion of the at least one film layer of the functional layer located at the defining slope, away from the base substrate and the base substrate is a fifth distance, and the fifth distance is greater than the fourth distance.

For example, according to an embodiment of the present disclosure, a portion, located between light-exiting regions of adjacent functional elements exiting light of different colors, in the defining portion is a second defining portion, and an extending direction of at least part of the second defining portion is identical to an arrangement direction of the adjacent functional elements exiting light of different colors; and a surface of a side, of a portion of the second defining portion close to the light-exiting region, away from the base substrate includes a defining slope, a maximum thickness of a portion of the at least one film layer of the functional layer located at the defining slope is a third maximum thickness, and the third maximum thickness is less than the second maximum thickness.

For example, according to an embodiment of the present disclosure, a shape of an orthographic projection of the at least one recessed region on the base substrate is a symmetrical pattern.

For example, according to an embodiment of the present disclosure, an orthographic projection of the at least one recessed region on the base substrate includes a first orthographic projection sub-portion close to a light-exiting region of a functional element corresponding to the at least one recessed region, and a second orthographic projection sub-portion away from the light-exiting region of the functional element corresponding to the at least one recessed region; and in an arrangement direction of two adjacent functional elements exiting light of different colors, an average dimension of the first orthographic projection sub-portion is greater than an average dimension of the second orthographic projection sub-portion.

An embodiment of the present disclosure provides a display device, including the substrate as mentioned above.

### BRIEF DESCRIPTION OF DRAWINGS

In order to clearly illustrate the technical solution of the embodiments of the invention, the drawings of the embodiments will be briefly described in the following; it is obvious that the described drawings are only related to some embodiments of the present disclosure and thus are not limitative of the present disclosure.

FIG. 1 and FIG. 2A are schematic diagrams of partial planar structures of display substrates provided by the embodiments of the present disclosure;

FIG. 2B-FIG. 2G are schematic diagrams of partial planar structures of display substrates provided by different examples of the embodiments of the present disclosure;

FIG. 3A and FIG. 3B are schematic diagrams of partial cross-sectional structures along a line AA′ illustrated in FIG. 1 in different examples;

FIG. 4 is a schematic diagram of a partial cross-sectional structure along a line BB′ illustrated in FIG. 1;

FIG. 5 is a schematic diagram of a partial cross-sectional structure along a line CC′ illustrated in FIG. 1;

FIG. 6 is a schematic diagram of a partial cross-sectional structure along a line DD′ illustrated in FIG. 1;

FIG. 7 is a schematic diagram illustrating a planar relationship between a first film layer and a second film layer in a light-emitting functional layer in an example of the display substrate illustrated in FIG. 1 and FIG. 2A;

FIG. 8 is a schematic diagram illustrating a planar relationship between a first film layer and a second film layer in a light-emitting functional layer in an example of the display substrate illustrated in FIG. 1 and FIG. 2A;

FIG. 9 is a schematic diagram illustrating a planar relationship between a first region and a second region in another example of the display substrate illustrated in FIG. 1 and FIG. 2A;

FIG. 10 is a schematic diagram illustrating a planar relationship between a first region and a second region in another example of the display substrate illustrated in FIG. 1 and FIG. 2A;

FIG. 11 is a schematic diagram of a partial cross-sectional structure along a line EE′ illustrated in FIG. 10;

FIG. 12 is a schematic diagram illustrating a planar relationship between a first region and a second region in another example of the display substrate illustrated in FIG. 1 and FIG. 2A;

FIG. 13A is a schematic diagram of a partial planar structure of a color filter layer and a black matrix in the display substrate illustrated in FIG. 1;

FIG. 13B is a schematic diagram of a partial cross-sectional structure along a line FF′ illustrated in FIG. 13A;

FIG. 13C and FIG. 13D are schematic cross-sectional diagrams of different examples of the display substrate illustrated in FIG. 13A;

FIG. 14A-FIG. 14D are schematic diagrams of partial planar structures of display substrates provided by different examples of the embodiments of the present disclosure;

FIG. 15 is a schematic diagram of a cross-sectional model of a light-emitting functional layer of the display substrate illustrated in FIG. 3A;

FIG. 16 is a schematic diagram of a partial planar structure of a display substrate provided by an embodiment of the present disclosure;

FIG. 17 is a schematic diagram of a partial planar structure of a display substrate provided by another example of an embodiment of the present disclosure;

FIG. 18 and FIG. 19 are schematic diagrams of partial cross-sectional structures along a line GG′ in different examples of the display substrate illustrated in FIG. 16;

FIG. 20 is a schematic diagram of a partial cross-sectional structure along a line HH′ illustrated in FIG. 16;

FIG. 21 is a schematic diagram of a partial cross-sectional structure along a line II′ illustrated in FIG. 17;

FIG. 22A-FIG. 22J are schematic diagrams of partial planar structures of some film layers of light-emitting functional layers in display substrates provided by different examples of the embodiments of the present disclosure; and

FIG. 23 is a schematic diagram of a partial cross-sectional structure of a display substrate provided by another embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

Features such as “parallel”, “perpendicular” and “identical” used in the embodiments of the present disclosure include features such as “parallel”, “perpendicular” and “identical” in the strict sense, as well as “approximately parallel”, “approximately perpendicular” and “approximately identical” and other situations that contain certain errors. Considering the measurement and errors associated with a specific amount of measurement (that is, the limitation of the measurement system), the measurement is represented within an acceptable deviation range for specific values determined by those skilled in the art. For example, “approximately” can mean within one or more standard deviations, or within 10% or 5% of the value. In the case where the amount of a component is not specifically indicated below in the embodiments of the present disclosure, it means that the component may be one or more, or may be understood as at least one. “At least one” means one or more, and “plurality” means at least two. The “same layer” in the embodiments of the present disclosure refers to a relationship between a plurality of film layers formed of the same material after the same step (e.g., a patterning process). The “same layer” here does not always mean that thicknesses of the plurality of film layers are the same or heights of the plurality of film layers are the same in a cross-sectional view.

In an organic light-emitting diode (OLED) display, a light-emitting functional layer includes a plurality of film layers, and at least some film layers in the light-emitting functional layer need to be completed by an evaporation process. However, the process conditions of the evaporation process are demanding and difficult to achieve large area.

The embodiments of the present disclosure provide a display substrate and a display device. The display substrate includes a base substrate, and a plurality of light-emitting elements and a pixel-defining pattern located on the base substrate. The light-emitting element includes a light-emitting functional layer and a first electrode and a second electrode located on both sides of the light-emitting functional layer in a direction perpendicular to the base substrate, the first electrode is located between the light-emitting functional layer and the base substrate, and the light-emitting functional layer includes a plurality of film layers; and the plurality of light-emitting elements includes light of at least two colors-emitting elements. The pixel-defining pattern is located on a side of the first electrode away from the base substrate, the pixel-defining pattern includes a plurality of openings and a defining portion surrounding the plurality of openings, and the plurality of light-emitting elements are at least partially located in the plurality of openings. The display substrate is distributed with a plurality of first regions and a plurality of second regions, the first region corresponds to at least a portion of the opening, and at least a portion of the second region is covered by the defining portion. At least one film layer in the light-emitting functional layer is located in at least one first region and at least one second region. A region in the second region covered by the defining portion includes a sub-region, the maximum thickness of the defining portion in the sub-region is greater than the maximum thickness of the defining portion at least partially located between light-emitting elements of different colors, and the maximum thickness of, a portion of at least one film layer in the light-emitting functional layer in the sub-region is not less than the maximum thickness of, another portion of the at least one film layer in the light-emitting functional layer in the first region. In the display substrate provided by the embodiments of the present disclosure, the thickness of at least one film layer in the light-emitting functional layer in the sub-region of the second region covered by the defining portion is provided to be greater, requiring more ink during printing, which is beneficial to balance the solvent atmosphere in the case where inkjet printing forms the film layer, and improves the uniformity of the light-emitting functional layer formed by inkjet printing.

Further, the maximum thickness of the defining portion in the sub-region is greater than the maximum thickness of the defining portion at least partially located between light-emitting elements of different colors, and the total thickness of the light-emitting functional layer in the sub-region is not less than the total thickness of the light-emitting functional layer in the first region. In the display substrate provided by the embodiments of the present disclosure, the light-emitting functional layer in the sub-region and the light-emitting functional layer in the first region may include a plurality of layers, such as at least three layers. Because the organic solvent in the printing ink may be the same or may be different, the evaporation rate of the organic solvent will also be different, and there will be a certain interaction with each other, the total thickness of the light-emitting functional layer in the sub-region is not less than the total thickness of the light-emitting functional layer in the first region, and the time required for drying will generally be extended, which is also beneficial to form a more uniform light-emitting functional layer in the first region. Specifically, the thickness of the light-emitting functional layer may be the total thickness of film layers between opposite surfaces of the first electrode and the second electrode in the light-emitting element in a direction perpendicular to the base substrate, may be the total thickness of a central portion of a corresponding region, may also be the average total thickness in this region, or may be the average total thickness of some regions whose deviation from the central thickness is within 20%. Specifically, the thickness of a certain film layer in the light-emitting functional layer may be the thickness of the central portion of the corresponding region, may be the average thickness of the region, or may be the average thickness of some regions whose deviation from the central thickness is within 20%, the embodiment of the present disclosure is not limited thereto. Specifically, the thickness of a certain film layer in the light-emitting functional layer or the total thickness of the light-emitting functional layer can be measured by means of transmission electron microscopy, mass spectrometry and the like.

The display substrate and the display device provided by the embodiments of the present disclosure will be described below with reference to the drawings.

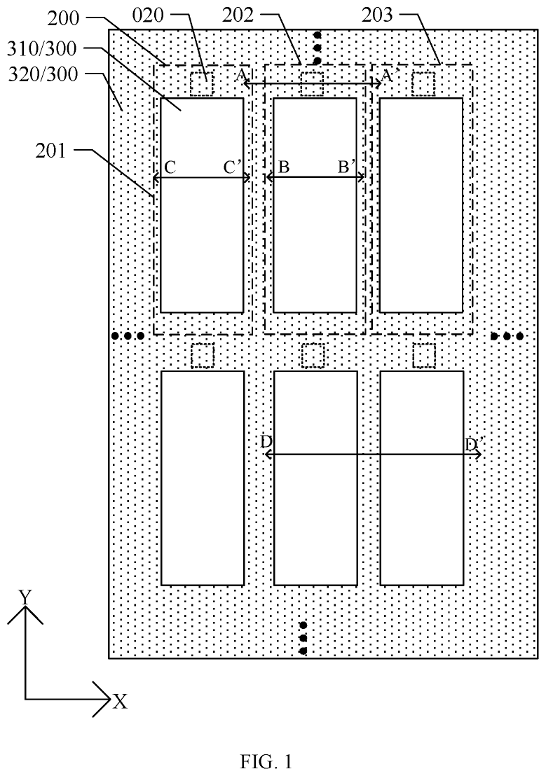

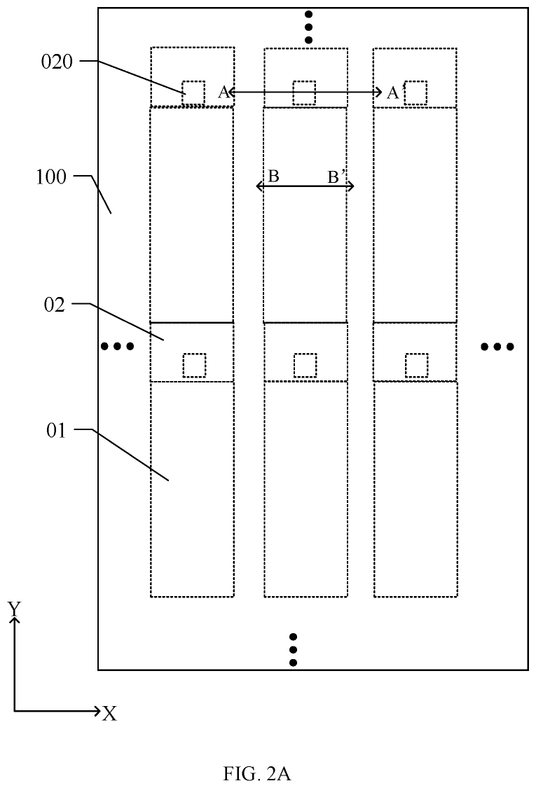

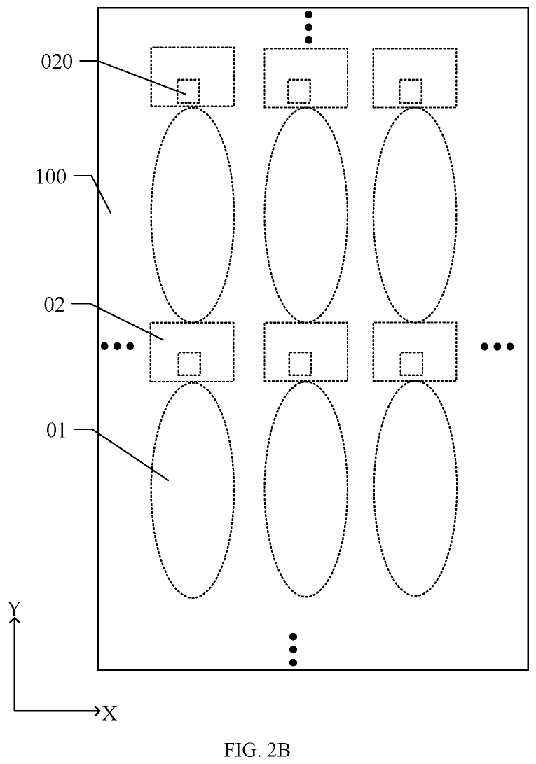

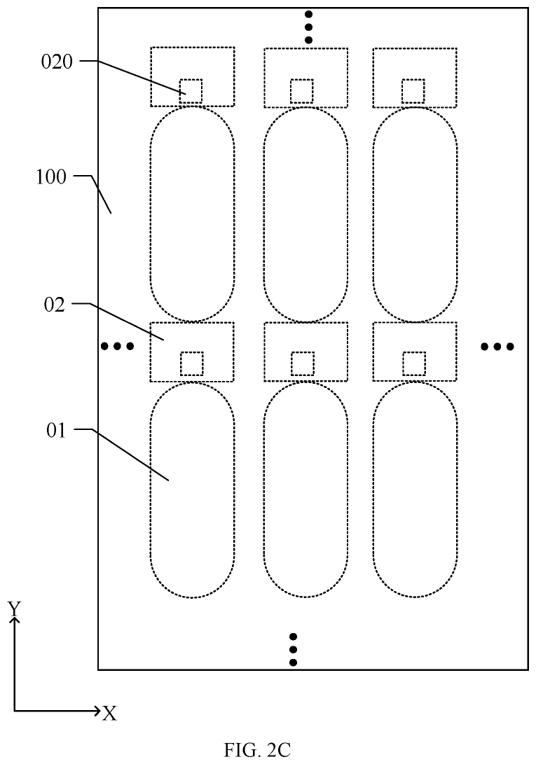

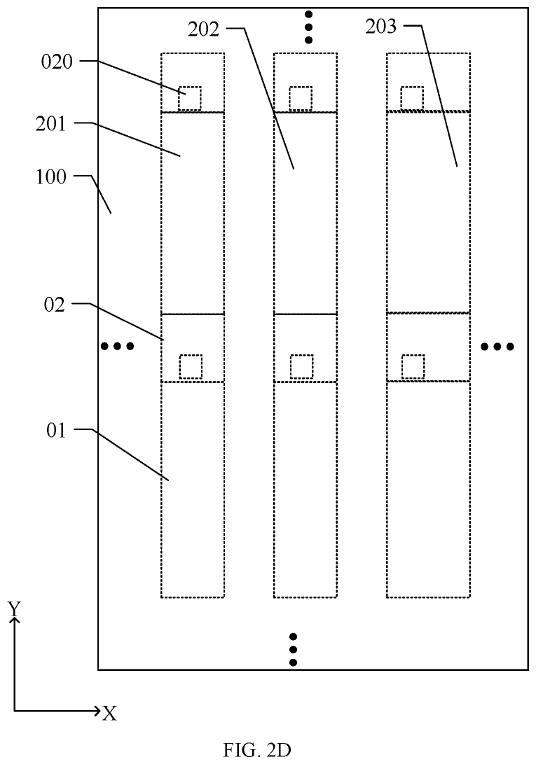

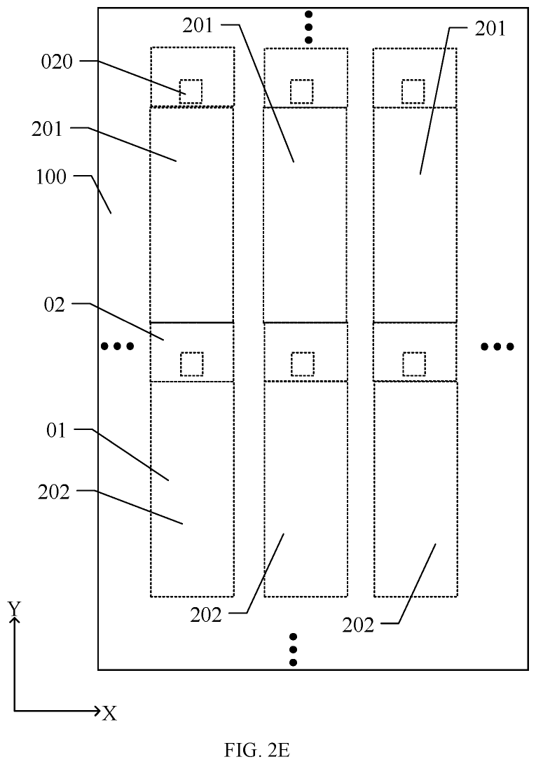

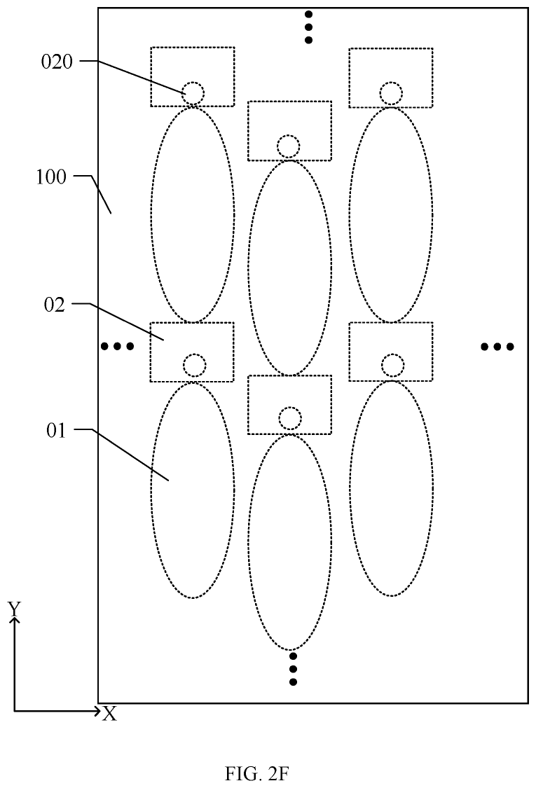

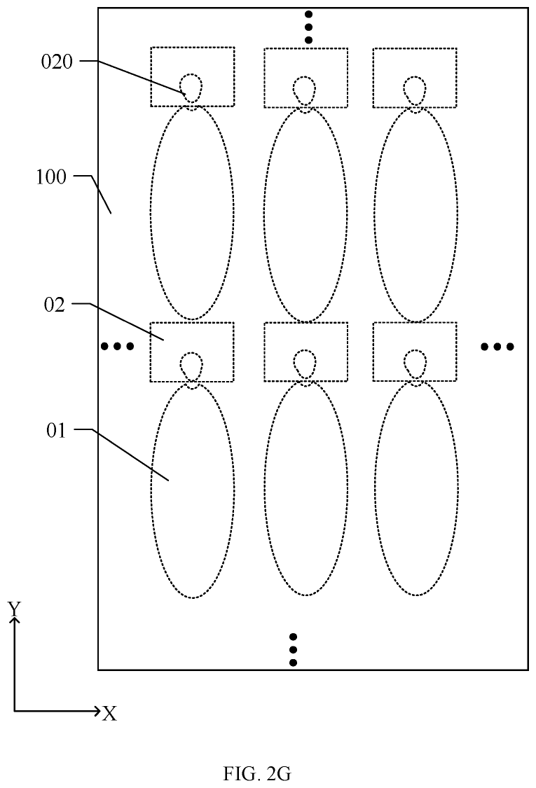

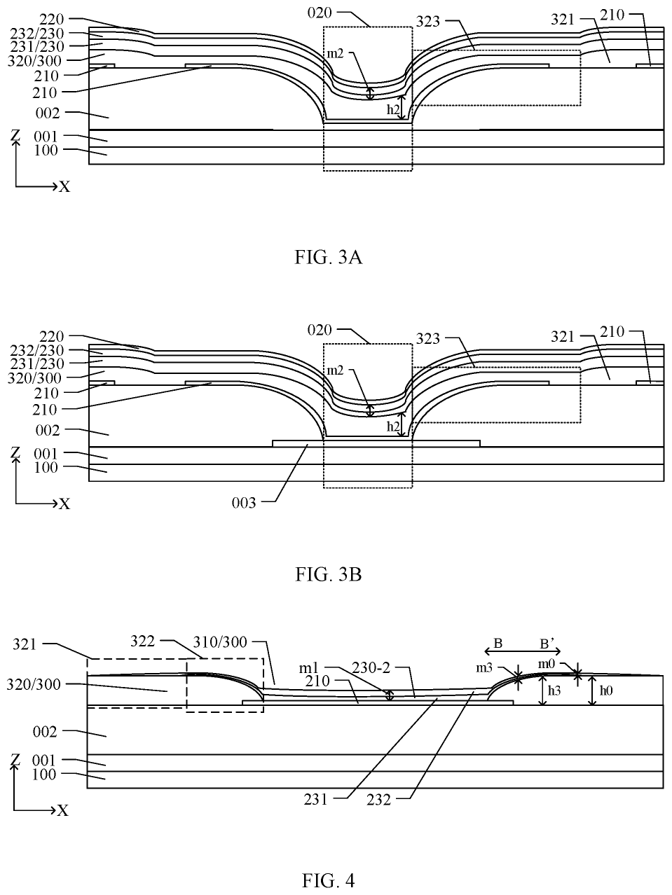

FIG. 1 and FIG. 2A are schematic diagrams of partial planar structures of display substrates provided by the embodiments of the present disclosure, FIG. 2B-FIG. 2G are schematic diagrams of partial planar structures of display substrates provided by different examples of the embodiments of the present disclosure, FIG. 3A and FIG. 3B are schematic diagrams of partial cross-sectional structures along a line AA′ illustrated in FIG. 1 in different examples, and FIG. 4 is a schematic diagram of a partial cross-sectional structure along a line BB′ illustrated in FIG. 1. As illustrated in FIG. 1-FIG. 4, the display substrate includes a base substrate 100, and a plurality of light-emitting elements 200 and a pixel-defining pattern 300 located on the base substrate 100. The light-emitting element 200 includes a light-emitting functional layer 230 and a first electrode 210 and a second electrode 220 located on both sides of the light-emitting functional layer 230 along the direction perpendicular to the base substrate 100. The first electrode 210 is located between the light-emitting functional layer 230 and the base substrate 100, and the light-emitting functional layer 230 includes a plurality of film layers.

For example, the light-emitting element 200 is an organic light-emitting diode. For example, the light-emitting element 200 is an organic light-emitting element. For example, the light-emitting element 200 is an electroluminescence element. For example, the light-emitting element 200 corresponds to a sub-pixel on the display substrate, for example, one sub-pixel includes one light-emitting element, or one sub-pixel includes two or more light-emitting elements.

For example, the plurality of film layers included in the light-emitting functional layer 230 include a hole injection layer (HIL), a hole transport layer (HTL), a light-emitting layer (EL), an electron transport layer (ETL), an electron injection layer (EIL), etc. For example, the light-emitting functional layer 230 further includes a hole blocking layer (HBL), an electron blocking layer (EBL), a microcavity regulating layer, an exciton regulating layer or other functional film layers. For example, the hole injection layer and the hole transport layer are located between the light-emitting layer and the first electrode 210, and the electron transport layer and the electron injection layer are located between the light-emitting layer and the second electrode 220. For example, the hole blocking layer is located between the light-emitting layer and the second electrode 220. For example, the electron blocking layer is located between the light-emitting layer and the first electrode 210. For example, the light-emitting functional layer further includes a plurality of stacked devices, for example, a first stacked layer includes a first light-emitting layer, a second stacked layer includes a second light-emitting layer, and the first stacked layer and the second stacked layer further include one or more layers of the hole injection layer (HIL), the hole transport layer (HTL), the light-emitting layer (EL), the electron transport layer (ETL), the electron injection layer (EIL), the hole blocking layer, the electron blocking layer, the microcavity regulating layer, the exciton regulating layer and other functional film layers. A charge generation layer (CGL) may be included between the first stacked layer and the second stacked layer, and the charge generation layer (CGL) may include an n-doped charge generation layer (CGL), and/or p-doped charge generation layer (CGL). Of course, in order to further improve the luminous efficiency, the light-emitting functional layer may also include three or more stacked layers.

For example, among the plurality of film layers included in the light-emitting functional layer 230, at least one layer includes quantum dots, for example, the light-emitting layer includes quantum dots. For example, in a light-exiting direction of the light-emitting functional layer, other functional layers may also be included, such as a quantum dot layer, a color filter layer, a lens layer, etc. For example, the light-emitting layer includes phosphorescent light-emitting material or fluorescent light-emitting material. For example, the light-emitting layer includes TADF, organometallic complexes, and the like. For example, the light-emitting layer is a single layer, or is stacked by a plurality of layers, and the plurality light-emitting layers may be made of the same material or different materials. For example, the pattern of the light-emitting layer is approximately identical to the pattern of at least one functional film layer other than the light-emitting layer, or is different from the pattern of at least one functional film layer other than the light-emitting layer. For example, at least one layer of the light-emitting functional layer is an integral layer, and at least one layer includes a plurality of patterns.

For example, at least one layer of the light-emitting functional layer 230 is manufactured by an inkjet printing process. For example, at least one or more layers of the hole injection layer, the hole transport layer and the light-emitting layer of the light-emitting functional layer 230 are manufactured by the inkjet printing process. For example, at least one layer of the light-emitting functional layer 230 is manufactured by an evaporation process. For example, at least one or more layers of the electron transport layer and the electron injection layer of the light-emitting functional layer 230 are manufactured by the evaporation process.

For example, adopting the inkjet printing process to manufacture at least some film layers of the light-emitting functional layer 230 in the light-emitting element 200 of the organic light-emitting diode display device is beneficial to reduce the production cost of the organic light-emitting diode display device. The inkjet printing process is an efficient process, compared with the method of forming all the film layers of the light-emitting functional layer by the evaporation process, the method of forming at least some film layers of the light-emitting functional layer by the inkjet printing process has less material waste and faster production speed.

For example, in the case where the inkjet printing process is adopted to form the light-emitting functional layer 230 of the light-emitting element, a solvent is used to mix organic materials to form a solution (for example, called an ink), and then the solution is directly jet-printed on a specific region on a surface of a base substrate 100 to form at least some film layers of the light-emitting functional layer 230 configured to exit light of the same color or light of different colors. The technology of inkjet printing organic light-emitting elements has obvious advantages over the evaporation technology in terms of manufacturing process, yield and cost.

For example, one or more layers of the electron transport layer and the electron injection layer included in the light-emitting functional layer 230 are common film layers of the plurality of light-emitting elements, which may be called common layers. For example, the thickness of the electron transport layer is in a range of 1-10 nm, such as a range of 2-8 nm, such as a range of 3-7 nm. For example, the thickness of the electron injection layer is in a range of 5-30 nm, such as a range of 22-28 nm, such as a range of 25-27 nm, such as a range of 5-15 nm, such as a range of 6-12 nm.

For example, the first electrode 210 is an anode, and the second electrode 220 is a cathode. For example, the cathode is made of a material with high conductivity and low work function, for example, the cathode is made of a metal material. For example, the anode is formed of a conductive material with a high work function.

For example, at least one of the first electrode 210 and the second electrode 220 includes a plurality of film layers. For example, the first electrode 210 includes three film layers, that is, a first electrode layer, a second electrode layer and a third electrode layer. For example, the first electrode 210 includes stacked layers of tungsten oxide (WO_{X}) and aluminum (Al). For example, materials of the first electrode layer and the third electrode layer include tungsten oxide (WO_{X}), and the material of the second electrode layer includes aluminum (Al).

For example, the first electrode 210 includes three stacked layers of indium tin oxide (ITO), silver (Ag), and indium tin oxide (ITO). For example, the first electrode 210 includes two stacked layers of indium tin oxide (ITO) and silver (Ag). For example, the first electrode 210 includes indium tin oxide (ITO), silver (Ag), and other metal oxide layers (e.g., WO_{X}). For example, among the two stacked layers or three stacked layers included in the first electrode, at least two layers are connected through via holes. For example, an insulating layer is between a first sub-layer and a second sub-layer which are two layers of the first electrode close to the light-emitting layer, and the first sub-layer and the second sub-layer are connected through a via hole in the insulating layer, that is, the first electrode includes the first sub-layer, the insulating layer, and the second sub-layer. For example, the first electrode includes the first sub-layer, the insulating layer, the second sub-layer, and a third sub-layer on a side of the second sub-layer away from the insulating layer. For example, the first electrode includes the first sub-layer, the second sub-layer, and the third sub-layer in a direction from a side close to the light-emitting layer to a side away from the light-emitting layer, an insulating layer is between the second sub-layer and the third sub-layer, and the second sub-layer and the third sub-layer are connected through a via hole in the insulating layer, that is, the first electrode includes the first sub-layer, the second sub-layer, the insulating layer and the third sub-layer.

For example, the thickness of the first electrode layer is in a range of 4-10 nanometers. For example, the thickness of the second electrode layer is in a range of 180-260 nanometers. For example, the thickness of the third electrode layer is in a range of 10-20 nanometers. For example, the thickness of the insulating layer is in a range of 20-150 nanometers. For example, the thickness of the first electrode layer is in a range of 5-9 nanometers. For example, the thickness of the second electrode layer is in a range of 180-210 nanometers. For example, the thickness of the second electrode layer is in a range of 190-205 nanometers. For example, the thickness of the third electrode layer is in a range of 10-19 nanometers. For example, the thickness of the third electrode layer is in a range of 11-14 nanometers. For example, the thickness of the insulating layer is in a range of 30-140 nanometers. For example, the thickness of the insulating layer is in a range of 35-130 nanometers. For example, the thickness of the insulating layer is in a range of 40-120 nanometers. For example, the thickness of the insulating layer is in a range of 45-110 nanometers. For example, the thickness of the insulating layer is in a range of 50-100 nanometers. For example, the thickness of the insulating layer is in a range of 55-90 nm.

For example, the second electrode 220 includes one or two film layers. For example, the second electrode 220 includes magnesium silver alloy. For example, the second electrode 220 includes a first electrode layer and a second electrode layer, and the first electrode layer is located on a side of the second electrode layer close to the light-emitting layer. For example, the second electrode 220 includes stacked layers of indium oxide (InO_{X}) and silver (Ag) or silver alloy. For example, the material of the first electrode layer includes indium oxide (InO_{X}), and the material of the second electrode layer includes silver (Ag) or silver alloy.

For example, the thickness of the first electrode layer is in a range of 70-100 nanometers. For example, the thickness of the first electrode layer is in a range of 75-95 nanometers. For example, the thickness of the first electrode layer is in a range of 76-85 nanometers. For example, the thickness of the second electrode layer is in a range of 10-20 nanometers. For example, the thickness of the second electrode layer is in a range of 13-17 nanometers. For example, the thickness of the second electrode layer is in a range of 12-18 nanometers. For example, the thickness of the second electrode layer is in a range of 14-19 nanometers. For example, the thickness of the first electrode layer is in a range of 10-100 nanometers. For example, the thickness of the first electrode layer is in a range of 21-30 nanometers. For example, the thickness of the first electrode layer is in a range of 18-28 nanometers. For example, the thickness of the first electrode layer is in a range of 15-30 nanometers. For example, the thickness of the first electrode layer is in a range of 24-28 nanometers. For example, the thickness of the second electrode layer is in a range of 30-100 nanometers. For example, the thickness of the second electrode layer is in a range of 35-95 nanometers. For example, the thickness of the second electrode layer is in a range of 40-90 nanometers. For example, the thickness of the second electrode layer is in a range of 45-85 nanometers. For example, the thickness of the second electrode layer is in a range of 50-88 nanometers. For example, the thickness of the second electrode layer is in a range of 55-84 nanometers. For example, the thickness of the second electrode layer is in a range of 60-82 nanometers. For example, the thickness of the second electrode layer is in a range of 65-78 nanometers. For example, the thickness of the second electrode layer is in a range of 68-75 nanometers.

For example, the second electrode layer of the second electrode is provided with a higher refractive index, which is more conducive to the emission of light and improve the light-exiting efficiency of the light-emitting element. For example, the refractive index of the second electrode layer of the second electrode is greater than the refractive index of the first electrode layer. For example, the refractive index of the second electrode layer of the second electrode is greater than 2. For example, the refractive index of the second electrode layer of the second electrode is greater than 2.1. For example, the first electrode layer of the second electrode is made of metal oxide, and the second electrode layer is made of metal or alloy. For example, the first electrode layer of the second electrode is made of metal or alloy, and the second electrode layer is made of metal oxide or other conductive compound.

For example, as illustrated in FIG. 1-FIG. 4, the plurality of light-emitting elements 200 include light-emitting elements 200 emitting light of at least two colors.

For example, the plurality of light-emitting elements 200 includes a red light-emitting element 201 configured to emit red light, a green light-emitting element 202 configured to emit green light, and a blue light-emitting element 203 configured to emit blue light. For example, the thicknesses of at least one of the electron transport layer and the electron injection layer respectively in the light-emitting elements 200 configured to emit light of different colors are the same, for example, the light-emitting elements 200 emitting light of different colors share at least one of the electron transport layer and the electron injection layer. For example, the thicknesses of the first electrodes 210 of the light-emitting elements 200 configured to emit light of different colors are the same. For example, the thicknesses of the second electrodes 220 of the light-emitting elements 200 configured to emit light of different colors are the same.

For example, the thicknesses of the first electrodes 210 of the light-emitting elements 200 configured to emit light of different colors are different. For example, the thickness of the first electrode 210 of the light-emitting element 200 that emits light with a longer wavelength is greater than the thickness of the first electrode 210 of the light-emitting element 200 that emits light with a shorter wavelength. For example, the thickness of at least one layer of the first electrode 210 of the light-emitting element 200 that emits light with a longer wavelength is greater than the thickness of the corresponding layer in the first electrode 210 of the light-emitting element 200 that emits light with a shorter wavelength.

For example, the thicknesses of the second electrodes 220 of the light-emitting elements 200 configured to emit light of different colors are different. For example, the thickness of the second electrode 220 of the light-emitting element 200 that emits light with a longer wavelength is greater than the thickness of the second electrode 220 of the light-emitting element 200 that emits light with a shorter wavelength. For example, the thickness of at least one layer of the second electrode 220 of the light-emitting element 200 that emits light with a longer wavelength is greater than the thickness of the corresponding layer in the second electrode 220 of the light-emitting element 200 that emits light with a shorter wavelength.

For example, the thickness of the first electrode or the second electrode of the red light-emitting element is greater than the thickness of the corresponding first electrode or the second electrode of the green and blue light-emitting elements. For example, the thickness of at least one layer of the first electrode of the red light-emitting element is greater than the thickness of the corresponding layer of the first electrode of the green light-emitting element and the blue light-emitting element. For example, the thickness of at least one layer of the second electrode of the red light-emitting element is greater than the thickness of the corresponding layer of the second electrode of the green light-emitting element and the blue light-emitting element.

As illustrated in FIG. 1 to FIG. 4, the pixel-defining pattern 300 is located on a side of the first electrode 210 away from the base substrate 01, the pixel-defining pattern 300 includes a plurality of openings 310 and a defining portion 320 surrounding the plurality of openings 310, and the plurality of light-emitting element 200 are at least partially located within the plurality of openings 310.

For example, the defining portion 320 is a structure defining the plurality of openings 310. For example, the material of the defining portion 320 includes polyimide, acrylic, or polyethylene terephthalate.

For example, the opening 310 of the pixel-defining pattern 300 is configured to define a light-emitting region of the light-emitting element 200. For example, the plurality of light-emitting elements 200 are provided in one-to-one correspondence with the plurality of openings 310. For example, the light-emitting element 200 includes a portion located in the opening 310 and a portion overlapping with the defining portion 320 in the direction perpendicular to the base substrate 100.

For example, at least part of the light-emitting element 200 is located in the opening 310. For example, the first electrode 210 of the light-emitting element is located on a side of the defining portion 320 close to the base substrate, the opening 310 is configured to expose the first electrode 210, and the exposed first electrode 210 is at least partially in contact with the light-emitting functional layer in the light-emitting element. For example, at least part of the first electrode 210 is located between the defining portion 320 and the base substrate 01. For example, in the case where the light-emitting functional layer 230 is located in the opening 310 of the pixel-defining pattern 300, the first electrode 210 and the second electrode 220 located on both sides of the light-emitting functional layer 230 can drive the light-emitting functional layer 230 in the opening 310 of the pixel-defining pattern 300 to emit light. For example, the above-mentioned light-emitting region may refer to an effective light-emitting region of the light-emitting element, and the shape of the light-emitting region refers to a two-dimensional shape. For example, the shape of the light-emitting region is identical to the shape of the opening 310 of the pixel-defining pattern 300. For example, the opening of the pixel-defining pattern 300 is provided with a shape with small dimension on the side close to the base substrate and large dimension on the side away from the base substrate. For example, the shape of the light-emitting region is approximately identical to the dimension and shape of the side of the opening of the pixel-defining pattern 300 close to the base substrate.

As illustrated in FIG. 1-FIG. 4, the display substrate is distributed with a plurality of first regions 01 and a plurality of second regions 02, the first region 01 corresponds to the opening 310, and at least part of the second region 02 is covered by the defining portion 320. For example, the first region 01 includes the light-emitting region, the second region 02 includes a spacing between the light-emitting regions, and the second region 02 further includes a non-light-emitting region surrounding edges of the light-emitting region and covered by the defining portion 320. For example, the first region 01 includes at least part of the light-emitting region of the light-emitting element 200. For example, the second region 02 includes at least part of the non-light-emitting region of the display substrate.

For example, the first region 01 includes the light-emitting region, and the second region 02 includes the spacing between light-emitting regions. For example, the second region 02 further includes the non-light-emitting region surrounding edges of the light-emitting region and covered by the defining portion 320. For example, one first region 01 is surrounded by a plurality of second regions 02. For example, one first region 01 is surrounded by four second regions 02 on both sides in the row direction and on both sides in the column direction. For example, the boundaries of the first region 01 and the second region 02 surrounding the first region are at least partially coincident. For example, one second region 02 is immediately adjacent to one first region 01. For example, one second region 02 is immediately adjacent to two first regions 01. For example, one second region 02 is a complete and continuous region. For example, one first region 01 is a complete and continuous region.

FIG. 2B and FIG. 2C are schematic diagrams of partial planar structures of display substrates provided by different examples of the embodiments of the present disclosure. For example, as illustrated in FIG. 2A-FIG. 2C, the shape of one first region is a regular pattern, such as including ellipse (as illustrated in FIG. 2B), pentagon, hexagon, octagon, circle, rhombus, rectangle (as illustrated in FIG. 2A), parallelogram, etc., is also various rounded polygons. For example, the plurality of first regions include different shapes. For example, the plurality of first regions are provided with the same shape. For example, the shapes of the first regions corresponding to the light-emitting elements that exit light of the same color are the same. For example, at least part of the first regions corresponding to light-emitting elements that emit light of different colors are provided with different shapes. For example, areas of the plurality of first regions are approximately equal. For example, the areas of the plurality of first regions are different, for example, areas of the first regions corresponding to the light-emitting elements that exit light of different colors are different.

FIG. 2D is a schematic diagram of a partial planar structure of a display substrate provided by an example of the embodiments of the present disclosure. For example, as illustrated in FIG. 2D, the area of the first region corresponding to the light-emitting element that emits light with a shorter wavelength (such as the blue light-emitting element 203) is greater than the area of the first region corresponding to the light-emitting element that emits light with a longer wavelength (such as the red light-emitting element 201 or the green light-emitting element 202). For example, the area of the first region corresponding to at least part of the light-emitting elements that emit blue light is greater than the area of the first region corresponding to the light-emitting element that emits red light.

FIG. 2E is a schematic diagram of a partial planar structure of a display substrate provided by another example of the embodiments of the present disclosure. For example, as illustrated in FIG. 2E, the first regions 01 corresponding to the light-emitting elements that emit light of the same color are arranged along the X direction illustrated in FIG. 2E, for example, the light-emitting elements arranged along the X direction are red light-emitting elements 201, or green light-emitting elements 202, or blue light-emitting elements 203. For example, as illustrated in FIG. 2E, the light-emitting elements arranged along the Y direction illustrated in FIG. 2E are light-emitting elements of different colors.

For example, opposite boundaries of at least part of adjacent first regions are substantially complementary, for example, parallel to each other or one is concave and the other is convex. For example, at least part of boundaries of at least part of the second regions are substantially parallel. For example, the boundaries of at least part of the first regions respectively include a portion of a curve. For example, the boundaries of at least part of the second regions respectively include a portion of a curve. For example, the shapes of two second regions at least partially located on both sides of the first region in the row direction are substantially symmetrical. For example, the shapes of two second regions at least partially located on both sides of the first region in the column direction are substantially symmetrical. For example, orthographic projections of two second regions at least partially located on both sides of the first region in the row direction on a straight line in the row direction do not overlap with an orthographic projection of the first region on the straight line in the row direction. For example, orthographic projections of two second regions at least partially located on both sides of the first region in the row direction on a straight line in the row direction is contiguous with but do not overlap with an orthographic projection of the first region on the straight line in the row direction. For example, orthographic projections of two second regions at least partially located on both sides of the first region in the column direction on a straight line in the column direction do not overlap with an orthographic projection of the first region on the straight line in the column direction. For example, orthographic projections of two second regions at least partially located on both sides of the first region in the column direction on a straight line in the column direction is contiguous with but do not overlap with an orthographic projection of the first region on the straight line in the column direction. For example, orthographic projections of two second regions at least partially located on both sides of the first region in the row direction on a straight line in the row direction overlap with an orthographic projection of the first region on the straight line in the row direction. For example, orthographic projections of two second regions at least partially located on both sides of the first region in the column direction on a straight line in the column direction overlap with an orthographic projection of the first region on the straight line in the column direction. For example, the first region does not overlap with the plurality of second regions adjacent to the first region, and the first region and the plurality of second regions adjacent to the first region are substantially combined into a rectangular region. For example, dimensions, in the row direction, of the two second regions at least partially located on both sides of the first region in the column direction are respectively not greater than the dimension of the first region in the row direction. For example, dimensions, in the column direction, of the two second regions at least partially located on both sides of the first region in the row direction are respectively not greater than the sum of dimensions, in the column direction, of the first region and two second regions adjacent to the first region in the column direction.

As illustrated in FIG. 1-FIG. 4, at least one film layer in the light-emitting functional layer 230 is located in at least one first region 01 and at least one second region 02. The region, covered by the defining portion 320, in at least one of the plurality of second regions 02 adjacent to the first region 01 includes a sub-region 020, the maximum thickness of the defining portion 320 in the sub-region 020 is not less than the maximum thickness of at least part of the defining portion 320 located between light-emitting elements 200 of different colors, and at least one layer of the light-emitting functional layers is disposed in the sub-region 020. In some embodiments, the maximum thickness of at least one film layer in the light-emitting functional layer 230 in the sub-region 020 is not less than the maximum thickness of at least one film layer in the corresponding light-emitting functional layer 230 in the first region 01. For example, a portion of at least one film layer in the light-emitting functional layer 230 located in at least one first region 01 and a portion of at least one film layer in the light-emitting functional layer 230 located in at least one second region 02 are formed to be an integral structure. In some embodiments, the overall maximum thickness of the light-emitting functional layer 230 in the sub-region 020 is not less than the overall maximum thickness of the corresponding light-emitting functional layer 230 in the first region 01.

In some embodiments, film layers of other solution processes can also adopt structures similar to the present disclosure. For example, in a quantum dot structure, a quantum dot layer can be printed to form a patterned quantum dot layer, quantum dots are at least partially located in a light-exiting region, a plurality of light-exiting regions are separated by a defining portion, the periphery of the light-exiting region is a non-light-exiting region, the non-light-exiting region is at least partially covered by the defining portion, and the thickness of at least one insulating layer in the non-light-exiting region is not less than the thickness of the defining portion located between two adjacent light-exiting regions.

In some embodiments, the thickness of at least one insulating layer in at least a partial region of the non-light-exiting region is greater than the thickness of the defining portion located between two adjacent light-exiting regions.

In some embodiments, the at least one insulating layer in at least a partial region of the non-light-exiting region includes the same material as the defining portion located between light-exiting regions.

In some embodiments, the at least one insulating layer in at least a partial region of the non-light-exiting region and the defining portion located between light-exiting regions are formed into an integral structure.

In some embodiments, the thickness of the quantum dot layer in at least a partial region of the non-light-exiting region is not less than the thickness of the quantum dot layer in the light-exiting region.

In some embodiments, the distribution of the light-exiting region and the non-light-exiting region may adopt the distribution of the first region and the second region described above, which will not be repeated here.

In some embodiments, the distribution of the light-exiting region and the non-light-exiting region may adopt the characteristics of the shapes, dimensions, areas, overlapping relationship, and symmetrical relationship of the first region and the second region, which will not be repeated here.

In some embodiments, the quantum dot layer is served as at least one layer in the light-emitting functional layer.

In some embodiments, the quantum dot layer is served as a color filter or a light conversion layer.

In some embodiments, the quantum dot layer is served as an optical functional layer, such as an optical film layer that improves light-exiting efficiency, light purity, light uniformity, or other light characteristics. In subsequent embodiments, the light-emitting functional layer can be replaced by a functional film layer including a quantum dot layer, which is fully applicable.

In the display substrate provided by the embodiments of the present disclosure, the thickness of at least one film layer in the light-emitting functional layer in the sub-region covered by the defining portion or the thickness of the entire light-emitting functional layer is provided to be greater, or the printed quantum dot layer is provided with a film layer having a certain thickness in the non-light-exiting region, which is beneficial to balance the solvent atmosphere during inkjet printing, and improves the uniformity of the light-emitting functional layer formed by inkjet printing.

For example, the thickness of at least one layer of the light-emitting functional layer 230 in the sub-region 020 except the edge part of the sub-region, for example, the part of the sub-region 020 within the area range radiating 70% from the center, may include the maximum thickness and the minimum thickness, and the ratio of the maximum thickness to the minimum thickness may be in a range of 0.01-0.9. For example, the ratio of the maximum thickness to the minimum thickness is in a range of 0.2-0.8. For example, the ratio of the maximum thickness to the minimum thickness is in a range of 0.3-0.7. For example, the thickness of at least one film layer in the corresponding light-emitting functional layer 230 in the first region 01, except the edge part of the sub-region, for example, the part of the first region within the area range radiating 70% from the center, may include the maximum thickness and the minimum thickness, and the ratio of the maximum thickness to the minimum thickness may be in a range of 0.01-0.9. For example, the ratio of the maximum thickness to the minimum thickness is in a range of 0.2-0.8. For example, the ratio of the maximum thickness to the minimum thickness is in a range of 0.3-0.7. For example, the maximum thickness of at least one film layer of the light-emitting functional layer 230 in the sub-region 020 is located in a region roughly in the center of the sub-region, and the thickness of at least one film layer of the light-emitting functional layer 230 in the sub-region 020 gradually decreases with the direction away from the center. For example, the maximum thickness of the entire light-emitting functional layer 230 in the sub-region 020 is located in the region roughly in the center of the sub-region, and the thickness of the entire film layer of the light-emitting functional layer 230 in the sub-region 020 gradually decreases with the direction away from the center.

For example, the average thickness of at least one film layer in the light-emitting functional layer 230, in the sub-region 020 is not less than that in the first region 01.

For example, in the sub-region 020, the defining portion 320 is located between the light-emitting functional layer 230 and the first electrode 210 to prevent the light-emitting functional layer 230 from contacting the first electrode 210. For example, the maximum thickness of the defining portion 320 in the sub-region 020 is greater than the thickness of at least part of the defining portion 320 located between light-emitting elements 200 of different colors, and the maximum thickness of at least one film layer in the light-emitting functional layer 230, in the sub-region 020 is greater than that in the first region 01. For example, the maximum thickness of the entire light-emitting functional layer 230, in the sub-region 020 is greater than that in the first region 01.

In the display substrate provided by the embodiments of the present disclosure, upon the thickness of at least one film layer in the light-emitting functional layer in the sub-region being provided to be greater, the thickness of the defining portion in the sub-region is also provided to be greater, which is beneficial to increase the distance between the light-emitting functional layer in the sub-region and the first electrode, so that it difficult for the display substrate to generate crosstalk and unnecessary light.

For example, at least one film layer in the above-mentioned light-emitting functional layer 230 is a film layer manufactured by the inkjet printing process, providing the thickness of the light-emitting functional layer in the sub-region covered by the defining portion to be not less than that in the first region is beneficial to improve the flatness of the light-emitting functional layer in the opening of the pixel-defining pattern, thereby reducing the probability of color shift when the light-emitting element is displayed, and further improving the display effect of the display device including the display substrate.

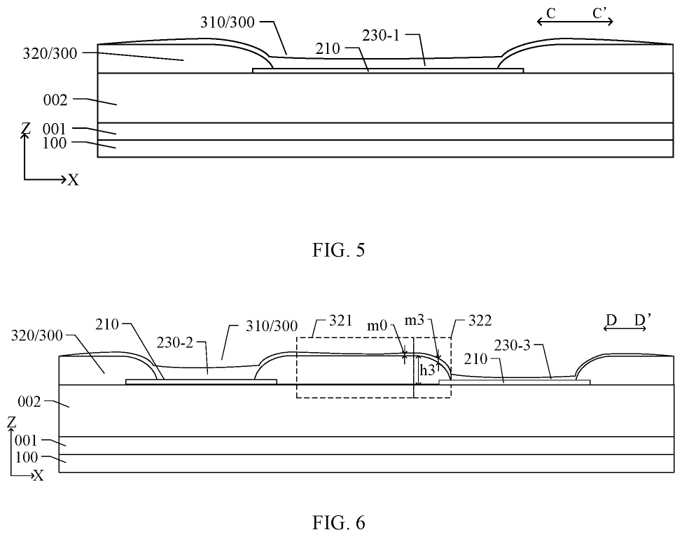

FIG. 5 is a schematic diagram of a partial cross-sectional structure along a line CC′ illustrated in FIG. 1, and FIG. 6 is a schematic diagram of a partial cross-sectional structure along a line DD′ illustrated in FIG. 1. For example, as illustrated in FIG. 5 and FIG. 6, the thickness of the light-emitting functional layer 230-1 of the red light-emitting element 201 is greater than the thickness of the light-emitting functional layer 230-2 of the green light-emitting element 202, and the thickness of the light-emitting functional layer 230-1 of the red light-emitting element 201 is greater than the thickness of the light-emitting functional layer 230-3 of the blue light-emitting element 203.

For example, the thickness of the light-emitting functional layer 230-1 of the red light-emitting element 201 is greater than the thickness of the light-emitting functional layer 230-2 of the green light-emitting element 202, and the thickness of the light-emitting functional layer 230-2 of the green light-emitting element 202 is greater than the thickness of the light-emitting functional layer 230-3 of the blue light-emitting element 203.

For example, the thicknesses of the light-emitting functional layers of the above-mentioned light-emitting elements of different colors respectively refer to the maximum thickness, or refer to the average thickness. For example, the maximum thickness of the light-emitting functional layer 230-1 of the red light-emitting element 201 is greater than the maximum thickness of the light-emitting functional layer 230-2 of the green light-emitting element 202 and the maximum thickness of the light-emitting functional layer 230-3 of the blue light-emitting element 203. For example, the thickness of the entire light-emitting functional layers of the above-mentioned light-emitting elements of different colors respectively refer to the maximum thickness, or refer to the average thickness. For example, the maximum thickness of the entire light-emitting functional layer 230-1 of the red light-emitting element 201 is greater than the maximum thickness of the entire light-emitting functional layer 230-2 of the green light-emitting element 202 and the maximum thickness of the entire light-emitting functional layer 230-3 of the blue light-emitting element 203.

For example, the average thickness of the light-emitting functional layer 230-1 of the red light-emitting element 201 is greater than the average thickness of the light-emitting functional layer 230-2 of the green light-emitting element 202 and the average thickness of the light-emitting functional layer 230-3 of the blue light-emitting element 203. For example, the maximum thickness of the light-emitting functional layer 230-1 of the red light-emitting element 201 is greater than the maximum thickness of the light-emitting functional layer 230-2 of the green light-emitting element 202, and the maximum thickness of the light-emitting functional layer 230-1 of the red light-emitting element 201 is greater than the maximum thickness of the light-emitting functional layer 230-3 of the blue light-emitting element 203. For example, the average thickness of the light-emitting functional layer 230-1 of the red light-emitting element 201 is greater than the average thickness of the light-emitting functional layer 230-2 of the green light-emitting element 202, and the average thickness of the light-emitting functional layer 230-1 of the red light-emitting element 201 is greater than the average thickness of the light-emitting functional layer 230-3 of the blue light-emitting element 203.

For example, the thicknesses of at least one of the light-emitting layer, the hole injection layer and the hole transport layer in the light-emitting functional layers of the light-emitting elements of different colors are different. For example, the thicknesses of the light-emitting layers, the hole injection layers and the hole transport layers in the light-emitting functional layers of light-emitting elements of different colors are all different. For example, the thickness of the entire light-emitting functional layers of the light-emitting elements of different colors are different.

For example, in the red light-emitting element 201, the sum of the thicknesses of the light-emitting layer and the hole transport layer is in a range of 120-140 nanometers. For example, in the red light-emitting element 201, the thickness of the hole injection layer is in a range of 40-50 nanometers. For example, in the red light-emitting element 201, the sum of the thicknesses of the light-emitting layer and the hole transport layer is in a range of 127-135 nanometers. For example, in the red light-emitting element 201, the thickness of the hole injection layer is in a range of 42-46 nanometers.

For example, in the green light-emitting element 202, the thickness of the light-emitting layer is in a range of 80-90 nanometers. For example, in the green light-emitting element 202, the thickness of the hole transport layer is in a range of 10-20 nanometers. For example, in the green light-emitting element 202, the thickness of the hole injection layer is in a range of 10-20 nanometers. For example, in the green light-emitting element 202, the thickness of the light-emitting layer is in a range of 81-86 nanometers. For example, in the green light-emitting element 202, the thickness of the hole transport layer is in a range of 12-15 nanometers. For example, in the green light-emitting element 202, the thickness of the hole injection layer is in a range of 12-17 nanometers.

For example, in the blue light-emitting element 203, the sum of the thicknesses of the light-emitting layer and the hole transport layer is in a range of 40-60 nanometers. For example, in the blue light-emitting element 203, the thickness of the hole injection layer is in a range of 10-20 nanometers. For example, in the blue light-emitting element 203, the sum of the thicknesses of the light-emitting layer and the hole transport layer is in a range of 42-55 nanometers. For example, in the blue light-emitting element 203, the thickness of the hole injection layer is in a range of 12-17 nanometers.

For example, different thicknesses of the light-emitting functional layers of the light-emitting elements of different colors can be achieved by two printing methods. For example, the thicknesses of the light-emitting functional layers of the light-emitting elements of different colors obtained by printing being different are achieved by adopting different concentrations of printing inks or different printing volumes of the light-emitting elements of different colors. For example, the ink concentration of at least one layer in the light-emitting functional layer of the red light-emitting element is provided to be higher than the ink concentration of a corresponding layer in the light-emitting functional layer of light-emitting elements of other colors (such as green or blue). For example, the amounts of printing ink per unit area of the light-emitting functional layers of different light-emitting elements are different. For example, the amounts of printing ink per unit area of at least one layer of the light-emitting functional layers of different light-emitting elements are different. For example, the amount of printing ink per unit area of a light-emitting element that emits light with a longer wavelength is greater than the amount of printing ink per unit area of a light-emitting element that emits light with a shorter wavelength. For example, the amount of printing ink per unit area of the red light-emitting element is greater than the amount of printing ink per unit area of the light-emitting element of other colors. For example, the ink volumes per unit area of at least one layer in the light-emitting functional layer of different light-emitting elements are different.

For example, the light-emitting elements of different colors are provided with different lifetimes. For example, the lifetime of the red light-emitting element is greater than the lifetime of the blue light-emitting element. For example, the lifetime of the red light-emitting element is greater than the lifetime of the green light-emitting element. For example, the areas of light-emitting regions of the light-emitting elements of different colors are different. For example, the area of the light-emitting region of the red light-emitting element is smaller than the area of the light-emitting region of the blue light-emitting element, and the area of the light-emitting region of the red light-emitting element is smaller than the area of the light-emitting region of the green light-emitting element. For example, the amounts of the light-emitting elements of different colors are different. For example, the amount of blue light-emitting elements and the amount of green light-emitting elements are both greater than the amount of red light-emitting elements.

For example, the light-emitting elements of different colors are provided with different light-exiting efficiencies. For example, the light-emitting element emits light through optical film layers (such as a color filter layer, a light conversion layer, a transmissive layer, etc.), and the transmittances of the optical film layers corresponding to the light-emitting elements of different color are different. For example, the area of the light-emitting region corresponding to the optical film layer with higher transmittance, of the light-emitting element is smaller, and the area of the light-emitting region corresponding to the optical film layer with lower transmittance, of the light-emitting element is larger. For example, the area of the light-emitting region corresponding to the light-emitting element with fewer optical film layers is smaller, and the area of the light-emitting region corresponding to the light-emitting element with more optical film layers is larger. For example, the transmittance of the optical film layer in the light-emitting region corresponding to the red light-emitting element is less than the transmittance of the optical film layer in the light-emitting region corresponding to the blue light-emitting element, and the area of the light-emitting region corresponding to the red light-emitting element is not smaller than the area of the light-emitting region corresponding to the blue light-emitting element. For example, the amount of optical film layers in the light-emitting region corresponding to the red light-emitting element is greater than the amount of optical film layers in the light-emitting region corresponding to the blue light-emitting element, and the area of the light-emitting region corresponding to the red light-emitting element is not smaller than the area of the light-emitting region corresponding to the blue light-emitting element. For example, the total amount of printing ink in the light-emitting region corresponding to the red light-emitting element is greater than the total amount of printing ink in the light-emitting region corresponding to the blue light-emitting element. For example, the transmittance of the optical film layer in the light-emitting region corresponding to the green light-emitting element is less than the transmittance of the optical film layer in the light-emitting region of the blue light-emitting element, and the area of the light-emitting region corresponding to the green light-emitting element is not smaller than the area of the light-emitting region corresponding to the blue light-emitting element. For example, the amount of optical film layers in the light-emitting region corresponding to the green light-emitting element is greater than the amount of optical film layers in the light-emitting region corresponding to the blue light-emitting element, and the area of the light-emitting region corresponding to the green light-emitting element is not smaller than the area of the light-emitting region corresponding to the blue light-emitting element. For example, the total amount of printing ink in the light-emitting region corresponding to the green light-emitting element is greater than the total amount of printing ink in the light-emitting region corresponding to the blue light-emitting element.

For example, as illustrated in FIG. 1 to FIG. 6, at least two adjacent light-emitting elements 200 arranged in the first direction are provided with the same light-emitting color, at least two adjacent light-emitting elements 200 arranged in the second direction are provided with different light-emitting colors, and the first direction intersects with the second direction. For example, the first direction is the Y direction, and the second direction is the X direction. For example, the first direction is perpendicular to the second direction. But not limited thereto, the first direction may not be perpendicular to the second direction, for example, the included angle between the first direction and the second direction is in a range of 30-60 degrees. For example, the first direction and the second direction may be interchanged. For example, the length direction of the first region is in the first direction. For example, the length direction of the first region is in the second direction.

For example, as illustrated in FIG. 1 and FIG. 2A, a column of light-emitting elements 200 arranged in the first direction are provided with the same light-emitting color, and the light-emitting elements 200 arranged in the second direction include the red light-emitting element 201, the green light-emitting element 202, and the blue light-emitting element 203 that are arranged sequentially.

For example, as illustrated in FIG. 1-FIG. 6, the maximum thickness of the defining portion 320 located between the light-emitting elements 200 of different colors is h0, and the maximum thickness of the defining portion 320 in the sub-region 020 is h2.

For example, the maximum thicknesses of the defining portions 320 respectively located between adjacent light-emitting elements 200 of different colors are approximately equal, for example, the ratio of the maximum thicknesses of two defining portions between light-emitting elements of different colors is in a range of 0.7-1.5, further, is in a range of 0.8-1.2. For example, the maximum thickness of the defining portion 320 between the red light-emitting element 201 and the green light-emitting element 202, the maximum thickness of the defining portion 320 between the red light-emitting element 201 and the blue light-emitting element 203, and the maximum thickness of the defining portion 320 between the green light-emitting element 202 and the blue light-emitting element 203 are all (0.7-1.5)*h0.

For example, the maximum thickness of the defining portion 320 between the red light-emitting element 201 and the green light-emitting element 202, the maximum thickness of the defining portion 320 between the red light-emitting element 201 and the blue light-emitting element 203, and the maximum thickness of the defining portion 320 between the green light-emitting element 202 and the blue light-emitting element 203 are all approximately h0±0.2 microns. For example, the maximum thickness of the defining portion 320 between the red light-emitting element 201 and the green light-emitting element 202, the maximum thickness of the defining portion 320 between the red light-emitting element 201 and the blue light-emitting element 203, and the maximum thickness of the defining portion 320 between the green light-emitting element 202 and the blue light-emitting element 203 are all approximately h0±0.1 microns.

For example, a light-emitting functional layer is formed on the defining portion between light-emitting elements of the same color. For example, a light-emitting functional layer is formed on the defining portion between light-emitting elements of different colors. For example, the total thickness of the light-emitting functional layer on the defining portion between the light-emitting elements of the same color is greater than the total thickness of the light-emitting functional layer on the defining portion between the light-emitting elements of different colors. For example, the total amount of light-emitting functional layers on the defining portion between the light-emitting elements of the same color is greater than the total amount of light-emitting functional layers on the defining portion between the light-emitting elements of different colors.

For example, as illustrated in FIG. 1-FIG. 6, the maximum thickness of the light-emitting functional layer 230 in the first region 01 is m1, the maximum thickness of the light-emitting functional layer 230 on the defining portion 320 between the light-emitting elements 200 of different colors is m0, and the maximum thickness of the light-emitting functional layer 230 in the sub-region 020 is m2, then h0, h2, m0 and m2 satisfy the relationship: h2/h0<m2/m0.

Because the heights of the defining portions in different regions are different, it is possible to block light emission to a certain extent or cause color shift due to insufficient flatness of the light-emitting functional layer. Therefore, the height difference of the defining portions should not be too large. For example, it should be at least less than the thickness difference of the corresponding light-emitting functional layers in different regions. For example, the height ratio of the defining portions in different regions is less than the thickness ratio of the corresponding light-emitting functional layers in different regions.

For example, the distance between the light-emitting functional layer and the first electrode (such as the anode) in the first region is h1. For example, h1 is in a range of 0-0.1 microns. For example, h1 is 0 micron. For example, h1 is greater than 0 micron, and a microcavity regulating layer is included between the light-emitting functional layer and the anode, which is, for example, made of metal, metal oxide, inorganic non-metal, or the like. For example, oxide or nitride of silicon (Si) is included between the light-emitting functional layer and the anode. For example, the microcavity regulating layer has carrier transport capability. For example, the microcavity regulating layer has hole transport capability. For example, the microcavity regulating layer has electron transport capability. For example, the anode includes a multilayer structure, including a transmissive layer and a reflective layer, the transmissive layer is located between the reflective layer and the light-emitting functional layer, and the microcavity regulating layer is located between the transmissive layer and the reflective layer. For example, the microcavity regulating layer is an insulating layer, and the transmissive layer and the reflective layer of the anode are connected through via holes in the microcavity regulating layer. For example, the microcavity regulating layer is a transparent layer.

For example, the range of the maximum thickness h0 of the defining portion 320 between the light-emitting elements 200 of different colors includes 0.7-1.2 microns. For example, the range of h0 includes 0.8-1.1 microns. For example, the range of h0 includes 1-1.1 microns. For example, the range of h0 includes 0.9-1 microns.

For example, the range of the maximum thickness h2 of the defining portion 320 in the sub-region 020 includes 1-4 microns. For example, the range of h2 includes 1-3.5 microns. For example, the range of h2 includes 1.5-3 microns. For example, the range of h2 includes 1.6-2.9 microns. For example, the range of h2 includes 1.7-2.8 microns. For example, the range of h2 includes 1.8-2.7 microns. For example, the range of h2 includes 1.9-2.6 microns. For example, the range of h2 includes 2-2.5 microns.

For example, the range of h2/h0 is 1-5. For example, the range of h2/h0 is 1.2-4.5. For example, the range of h2/h0 is 1.3-4. For example, the range of h2/h0 is 1.4-3.5. For example, the range of h2/h0 is 1.5-3. For example, the range of h2/h0 is 1.6-2.8. For example, the range of h2/h0 is 1.7-2.7. For example, the range of h2/h0 is 1.8-2.6. For example, the range of h2/h0 is 1.9-2.5. For example, the range of h2/h0 is 2-2.4. For example, the range of h2/h0 is 2.1-2.5. For example, the range of h2/h0 is 2.2-2.3.

For example, the range of the maximum thickness m0 of the light-emitting functional layer 230 on the defining portion 320 between the light-emitting elements 200 of different colors includes 0.01-0.2 microns. For example, the range of m0 includes 0.01-0.1 microns. For example, the range of m0 includes 0.02-0.08 microns. For example, the range of m0 includes 0.02-0.5 microns. For example, the range of m0 includes 0.01-0.05 microns. For example, the range of m0 includes 0.02-0.04 microns. For example, the range of m0 includes 0.02-0.03 microns. For example, the range of m0 includes 0.01-0.015. For example, the range of m0 includes 0.012-0.018. For example, the range of m0 includes 0.02-0.04. For example, the range of m0 includes 0.025-0.035.

For example, the range of the maximum thickness m2 of the light-emitting functional layer 230 in the sub-region 020 includes 0.1-0.6 microns. For example, the range of m2 includes 0.15-0.5 microns. For example, the range of m2 includes 0.2-0.55 microns. For example, the range of m2 includes 0.25-0.5 microns. For example, the range of m2 includes 0.3-0.5 microns. For example, the range of m2 includes 0.35-0.49 microns. For example, the range of m2 includes 0.4-0.45 microns. For example, the range of m2 includes 0.42-0.48 microns. For example, the range of m2 includes 0.41-0.47 microns. For example, the range of m2 includes 0.25-0.4 microns. For example, the range of m2 includes 0.2-0.47 microns. For example, the range of m2 includes 0.25-0.45 microns.

For example, the range of the maximum thickness m1 of the light-emitting functional layer in the light-emitting element includes 0.05-0.5 microns. For example, the range of the maximum thickness m1 of the light-emitting functional layer in the light-emitting element includes 0.06-0.4 microns. For example, the range of the maximum thickness m1 of the light-emitting functional layer in the light-emitting element includes 0.07-0.3 microns. For example, the range of the maximum thickness m1 of the light-emitting functional layer in the light-emitting element includes 0.08-0.25 microns. For example, the range of the maximum thickness m1 of the light-emitting functional layer in the light-emitting element includes 0.05-0.16 microns. For example, the range of the maximum thickness m1 of the light-emitting functional layer in the light-emitting element includes 0.06-0.15 microns. For example, the range of the maximum thickness m1 of the light-emitting functional layer in the light-emitting element includes 0.09-0.22 microns.

For example, the thicknesses of the light-emitting functional layers of the light-emitting elements of different colors are different. For example, the maximum thickness of the light-emitting functional layer of the red light-emitting element is greater than the maximum thickness of the light-emitting functional layer of the green light-emitting element and the maximum thickness of the light-emitting functional layer of the blue light-emitting element. For example, the maximum thickness of the light-emitting functional layer of the green light-emitting element is greater than the maximum thickness of the light-emitting functional layer of the blue light-emitting element. For example, the maximum thickness of the light-emitting functional layer of the blue light-emitting element is greater than the maximum thickness of the light-emitting functional layer of the green light-emitting element. For example, the maximum thickness of the light-emitting functional layer of the green light-emitting element is greater than the maximum thickness of the light-emitting functional layer of the red light-emitting element and the maximum thickness of the light-emitting functional layer of the blue light-emitting element. For example, the maximum thickness of the light-emitting functional layer of the blue light-emitting element is greater than the maximum thickness of the light-emitting functional layer of the red light-emitting element and the maximum thickness of the light-emitting functional layer of the green light-emitting element.

In some embodiments, the distance between a surface on a side of the first electrode facing the second electrode in the light-emitting elements of different colors (for example, the reflective anode, for example, the anode includes a plurality of layers, and a reflective interface facing the cathode is the surface) and a surface on a side of the second electrode (for example, the cathode) facing the first electrode is the microcavity length of each light-emitting element. For example, the microcavity length of the red light-emitting element is longer than the microcavity length of the green light-emitting element and the microcavity length of the blue light-emitting element. For example, the microcavity length of the green light-emitting element is longer than the microcavity length of the blue light-emitting element. For example, the microcavity length of the blue light-emitting element is longer than the microcavity length of the green light-emitting element. For example, the microcavity length of the green light-emitting element and the microcavity length of the blue light-emitting element are both longer than the microcavity length of the red light-emitting element. The microcavity length of each light-emitting element needs to be determined according to the corresponding product design requirements and process conditions to effectively adjust the gain peak of the corresponding OLED and enhance the light emission of the OLED.

Generally, the gain of the light emitted by the OLED light-emitting layer needs to satisfy the following formula:

φ1+φ2+2×(2×π/λ)×n×L×cos θ=2×k×π;

φ1 and φ2 are reflection phase shifts respectively corresponding to an interface of the first electrode and an interface of the second electrode of the light-emitting element; λ is the wavelength of the light emitted by the light-emitting element; n is the refractive index of the film layer passing through by the light emitted by the light-emitting element, θ is the included angle between the light-exiting direction and the normal line of the mirror surface, L is the microcavity length of the light-emitting element, k is the multiple of the microcavity length, and k is an integer.

In some embodiments, the k values corresponding to the microcavity length of the red light-emitting element, the microcavity length of the green light-emitting element, and the microcavity length of the blue light-emitting element are consistent, for example, the k values are all 1, or are all 2, or are all 3.

For example, the wavelength of red light is 615-620 nm, the wavelength of green light is 530-540 nm, and the wavelength of blue light is 460-480 nm.

In some embodiments, the k values corresponding to the microcavity length of the red light-emitting element, the microcavity length of the green light-emitting element, and the microcavity length of the blue light-emitting element are different, for example, some of the k values are 1, some of the k values are 2 or 3. For example, the k value corresponding to the microcavity length of the red light-emitting element is 1, and the k values corresponding to the microcavity length of the blue light-emitting element and the microcavity length of the green light-emitting element are 2 or 3. For example, the k values corresponding to the microcavity length of the red light-emitting element and the microcavity length of the green light-emitting element are 1, and the k value corresponding to the microcavity length of the blue light-emitting element is 2 or 3.

In some embodiments, the k value corresponding to the microcavity length of the light-emitting element (such as the red light-emitting element) with a longer light-emitting wavelength is less than the k value corresponding to the microcavity length of the light-emitting element (such as the blue light-emitting element) with a shorter light-emitting wavelength. For example, the k value of the red light-emitting element is 1, and the k value of the blue light-emitting element is 2. For example, the k value of the red light-emitting element is 1, and the k value of the green light-emitting element is 2.

For printing OLED light-emitting elements, the uniformity of the film layer is affected by the thickness of the film layer. Generally, the greater the film thickness, the more beneficial to the improvement of the uniformity of the film layer; and under the same microcavity condition of k value, the shorter the wavelength of light emitted by the light-emitting element, the less the thickness of the light-emitting functional layer, and the more difficult it is to improve the quality of the film layer; therefore, different k values can be provided, for example, the k value of the element with a shorter light-emitting wavelength is increased to increase the thickness of the film layer and further improve the process stability and the uniformity of the film layer.

In some embodiments, the microcavity lengths of different light-emitting elements being different is achieved only through the thicknesses of one or some layers in the light-emitting functional layer being different. In some embodiments, the thicknesses of the light-emitting functional layers of different light-emitting elements being different is easier to be achieved by adjusting the thicknesses of the printed film layers, such as one or more layers of the hole transport layer, the hole injection layer and the light-emitting layer. For example, the thickness of at least one layer of the hole transport layer, the hole injection layer and the light-emitting layer in the light-emitting functional layer of the red light-emitting element is greater than the thickness of a corresponding layer of the hole transport layer, the hole injection layer and the light-emitting layer in the light-emitting functional layer of the green light-emitting element or in the light-emitting functional layer of the blue light-emitting element. For example, the thickness of at least one layer of the hole transport layer, the hole injection layer and the light-emitting layer in the light-emitting functional layer of the green light-emitting element is greater than the thickness of a corresponding layer of the hole transport layer, the hole injection layer and the light-emitting layer in the light-emitting functional layer of the red light-emitting element or in the light-emitting functional layer of the blue light-emitting element. For example, the thickness of at least one layer of the hole transport layer, the hole injection layer and the light-emitting layer in the light-emitting functional layer of the blue light-emitting element is greater than the thickness of a corresponding layer of the hole transport layer, the hole injection layer and the light-emitting layer in the light-emitting functional layer of the green light-emitting element or in the light-emitting functional layer of the red light-emitting element.

In some embodiments, the microcavity lengths of respective light-emitting elements being different is also achieved through thicknesses of other film layers being different. For example, other microcavity regulating layers are provided between the printed film layer and the anode, and the thicknesses of microcavity regulating layers of respective light-emitting elements being different is achieved by a photolithography process, for example, metal (such as indium, tungsten, tin, etc.), metal oxide (such as oxides of indium, tungsten, tin, etc.), or inorganic non-metal (such as oxide, or nitride, or oxynitride of Si) is served as the microcavity regulating layer. For example, the microcavity lengths of respective light-emitting elements being different is also achieved through thicknesses of evaporated film layers being different, for example, the thicknesses of evaporated film layers being different is achieved by FMM (fine metal mask), for example, at least one layer of the electron injection layer, electron transport layer, and the hole blocking layer is provided with a different thickness. For example, the microcavity regulating layer is also added between the light-emitting layer and the cathode, for example, metal (such as indium, tungsten, tin, etc.), metal oxide (such as oxides of indium, tungsten, tin, etc.), or inorganic non-metal (such as oxide, or nitride, or oxynitride of Si) is served as the microcavity regulating layer. For example, the thicknesses of microcavity regulating layers of respective light-emitting elements being different is also achieved by setting the anode and the cathode to have different thicknesses. For example, the thickness of a reflective electrode in the anode is different from the thickness of a transmissive electrode in the light-emitting layer. For example, the thicknesses of the cathodes are different, or materials of the cathodes are different. The above can be designed according to actual requirements, and various methods can also be used in combination at will.

For example, the thickness of the light-emitting functional layer 230 of the red light-emitting element is in a range of 0.1-0.5 microns. For example, the thickness of the light-emitting functional layer 230 of the green light-emitting element is in a range of 0.1-0.4 microns. For example, the thickness of the light-emitting functional layer 230 of the blue light-emitting element is in a range of 0.01-0.3 microns. For example, the thickness of the light-emitting functional layer 230 of the red light-emitting element is in a range of 0.15-0.4 microns. For example, the thickness of the light-emitting functional layer 230 of the green light-emitting element is in a range of 0.1-0.3 microns. For example, the thickness of the light-emitting functional layer 230 of the blue light-emitting element is in a range of 0.01-0.25 microns. For example, the thickness of the light-emitting functional layer 230 of the red light-emitting element is in a range of 0.15-0.3 microns. For example, the thickness of the light-emitting functional layer 230 of the green light-emitting element is in a range of 0.1-0.25 microns. For example, the thickness of the light-emitting functional layer 230 of the blue light-emitting element is in a range of 0.05-0.15 microns. For example, the thickness of the light-emitting functional layer 230 of the red light-emitting element is in a range of 0.1-0.2 microns. For example, the thickness of the light-emitting functional layer 230 of the green light-emitting element is in a range of 0.08-0.15 microns. For example, the thickness of the light-emitting functional layer 230 of the blue light-emitting element is in a range of 0.05-0.12 microns. For example, the thickness of the light-emitting functional layer 230 of the red light-emitting element is in a range of 0.1-0.5 microns. For example, the thickness of the light-emitting functional layer 230 of the green light-emitting element is in a range of 0.09-0.13 microns. For example, the thickness of the light-emitting functional layer 230 of the blue light-emitting element is in a range of 0.06-0.09 microns. For example, the thickness of the light-emitting functional layer 230 of the red light-emitting element is in a range of 0.2-0.3 microns, the thickness of the light-emitting functional layer 230 of the green light-emitting element is in a range of 0.14-0.18 microns, and the thickness of the light-emitting functional layer 230 of the blue light-emitting element is in a range of 0.09-0.12 microns.

For example, the maximum thickness m0 of the light-emitting functional layer 230 on the defining portion 320 located between the light-emitting elements 200 of different colors, the maximum thickness m1 of the light-emitting functional layer 230 in the first region 01, and the maximum thickness m2 of the light-emitting functional layer 230 in the sub-region 020 satisfy the relationship: m0<m1≤m2.

In the display substrate provided by the embodiments of the present disclosure, the amount of light-emitting functional layers provided in the sub-region is greater, for example, the amount of ink stored in the sub-region is greater, which can continuously balance the drying speed of the ink. The thickness of the defining portion in the sub-region is not provided too thick or the gap between the defining portion and other portions is too large, which can prevent the unevenness of the defining portion in the sub-region from affecting the ink leveling, and can reduce the color shift caused by the change of the light-exiting direction caused by the unevenness.

For example, as illustrated in FIG. 1-FIG. 6, the defining portion 320 located between openings 310 corresponding to adjacent light-emitting elements of different colors includes a first sub-defining portion 321, and the first sub-defining portion 321 extends in the first direction. The defining portion 320 between two adjacent first sub-defining portions 321 includes a second sub-defining portion 322, a surface of the second sub-defining portion 322 away from the base substrate 100 includes a slope, and the maximum thickness of the first sub-defining portion 321 is not less than the maximum thickness of the second sub-defining portion 322.

For example, the defining portion 320 located between adjacent openings 310 includes a first sub-defining portion 321 and second sub-defining portions 322 located on both sides of the first sub-defining portion 321, a surface of the second sub-defining portion 322 away from the base substrate 100 includes a slope, and the average thickness of the first sub-defining portion 321 is greater than the average thickness of the second sub-defining portion 322. For example, the defining portion 320 located between adjacent light-emitting elements 200 of different colors includes a first sub-defining portion 321 and a second sub-defining portion 322. For example, the maximum thickness of the first sub-defining portion 321 is h0. For example, the maximum height of the first sub-defining portion 321 relative to a surface of a corresponding anode close to the base substrate or a surface of a flat portion of a planarization layer is h0. For example, the maximum height of the first sub-defining portion 321 relative to a surface of the corresponding anode away from the base substrate or an exposed anode surface in the opening of the pixel-defining pattern is h0.

For example, as illustrated in FIG. 1-FIG. 6, a surface of the first sub-defining portion 321 away from the base substrate 100 includes a surface approximately parallel to the base substrate 100. For example, in some embodiments, the surface on the side of the first sub-defining portion 321 away from the base substrate 100 includes a surface that is relatively high in the middle and relatively low on both sides, and the relatively low surfaces on both sides are surfaces close to the opening of the pixel-defining pattern.

For example, the slope angle of the slope formed on the surface of the side of the second sub-defining portion 322 away from the base substrate 100 is in a range of 30-70 degrees. For example, the slope angle of the slope formed on the surface of the side of the second sub-defining portion 322 away from the base substrate 100 is in a range of 40-60 degrees. For example, the slope angle of the slope formed on the surface of the side of the second sub-defining portion 322 away from the base substrate 100 is in a range of 45-50 degrees. For example, the slope angle of the slope formed on the surface of the side of the second sub-defining portion 322 away from the base substrate 100 is in a range of 42 degrees. For example, the slope angle of the slope formed on the surface of the side of the second sub-defining portion 322 away from the base substrate 100 is an angle between a part of the surface of the second sub-defining portion close to the base substrate and the plane of the base substrate.

The above-mentioned slope angle of the second sub-defining portion 322 may refer to an included angle between a tangent line at an intersection point, being contact with the first electrode 210, of a curve of the slope cut by the XZ plane and the X direction. But not limited thereto, for example, the above-mentioned slope angle of the second sub-defining portion 322 may refer to an included angle between a tangent line, at a midpoint of the curve of the slope cut by the XZ plane, and the X direction.

For example, as illustrated in FIG. 1-FIG. 6, the maximum thickness of the light-emitting function layer 230 on the second sub-defining portion 322 is m3, then the maximum thickness m0 of the light-emitting function layer 230 on the first sub-defining portion 321 located between the light-emitting elements 200 of different colors, the maximum thickness m1 of the light-emitting functional layer 230 in the first region 01, the maximum thickness m2 of the light-emitting functional layer 230 in the sub-region 020, and the maximum thickness m3 of the light-emitting functional layer 230 on the second sub-defining portion 322 satisfy the relationship: m0≤m3<m1≤m2.

For example, the second sub-defining portion includes a defining portion between the light-emitting elements of the same color. For example, the first sub-defining portion includes a defining portion between the light-emitting elements of different colors.

For example, the maximum thickness m2 of a portion of the light-emitting functional layer located in the sub-region 020, the maximum thickness m1 of a portion of the light-emitting functional layer located in the first region 01, the maximum thickness m0 of a portion of the light-emitting functional layer located on the first sub-defining portion 321, and the maximum thickness m3 of a portion of the light-emitting functional layer located on the second sub-defining portion 322 satisfy the above relationship: m0≤m3<m1≤m2.

For example, as illustrated in FIG. 1-FIG. 6, the maximum thickness of the second sub-defining portion 322 is h3, and the maximum thickness h0 of the first sub-defining portion 321 located between light-emitting elements 200 of different colors, the maximum thickness h2 of the defining portion 320 in the sub-region 020, and the maximum thickness h3 of the second sub-defining portion 322 satisfy the relationship: h3<h0≤h2.

For example, the maximum thickness h0 of the first sub-defining portion 321 located between the light-emitting elements 200 of different colors and the maximum thickness h2 of the defining portion 320 in the sub-region 020 satisfy the relationship: 1<h2/h0<4.5.

For example, the maximum thickness h0 of the first sub-defining portion 321 located between the light-emitting elements 200 of different colors and the maximum thickness h2 of the defining portion 320 in the sub-region 020 satisfy the relationship: 2<h2/h0<4.

For example, the maximum thickness h0 of the first sub-defining portion 321 located between the light-emitting elements 200 of different colors and the maximum thickness h2 of the defining portion 320 in the sub-region 020 satisfy the relationship: 2.5<h2/h0<3.5.

For example, the maximum thickness m1 of the light-emitting functional layer 230 in the first region 01 and the maximum thickness m2 of the light-emitting functional layer 230 in the sub-region 020 satisfy the relationship: 1≤m2/m1≤3. For example, the maximum thickness m1 of the light-emitting functional layer 230 in the first region 01 and the maximum thickness m2 of the light-emitting functional layer 230 in the sub-region 020 satisfy the relationship: 2≤m2/m1≤2.5.

For example, as illustrated in FIG. 1-FIG. 6, a contact angle of at least one film layer of the light-emitting functional layer 230 on the first sub-defining portion 321 is greater than a contact angle of at least one film layer of the light-emitting functional layer 230 on the second sub-defining portion 322. For example, the contact angle of at least one film layer of the light-emitting functional layer 230 on the first sub-defining portion 321 is greater than 90 degrees, and the contact angle of at least one film layer of the light-emitting functional layer 230 on the second sub-defining portion 322 is less than 90 degrees. For example, the contact angle of at least one film layer of the light-emitting functional layer 230 on the second sub-defining portion 322 is less than 80 degrees. For example, the contact angle of at least one film layer of the light-emitting functional layer 230 on the second sub-defining portion 322 is less than 70 degrees. For example, the contact angle of at least one film layer of the light-emitting functional layer 230 on the second sub-defining portion 322 is less than 60 degrees. For example, the contact angle of at least one film layer of the light-emitting functional layer 230 on the second sub-defining portion 322 is less than 50 degrees. For example, the contact angle of at least one film layer of the light-emitting functional layer 230 on the second sub-defining portion 322 is less than 45 degrees. For example, the contact angle of at least one film layer of the light-emitting functional layer 230 on the second sub-defining portion 322 is less than 30 degrees.

For example, a contact angle of a film layer formed by the inkjet printing process in the light-emitting functional layer 230, on the first sub-defining portion 321 is greater than that on the second sub-defining portion 322. The at least one film layer of the above-mentioned light-emitting functional layer may be a film layer formed by the inkjet printing process.

For example, a contact angle of at least one film layer of the light-emitting functional layer 230 on the defining portion 320 immediately adjacent to the periphery of the first region 01 is greater than that on the defining portion 320 immediately adjacent to the periphery of the sub-region 020. For example, the defining portion 320 located at the periphery of the first region 01 is a lyophobic region for at least one film layer of the light-emitting functional layer 230, and the defining portion 320 located at the periphery of the sub-region 020 is a lyophilic region for at least one film layer of the light-emitting functional layer 230. Adjusting the contact angle of at least one film layer of the light-emitting functional layer on defining portions at different positions is beneficial to the diffusion of at least one film layer (such as ink) of the light-emitting functional layer and balance the evaporation rate of the ink.

For example, a contact angle of a film layer formed by the inkjet printing process in the light-emitting functional layer 230 on the defining portion 320 immediately adjacent to the periphery of the first region 01 is greater than that on the defining portion 320 immediately adjacent to the periphery of the sub-region 020. For example, the above-mentioned “immediately adjacent to” includes a region within 1 micron from the boundary. For example, the above-mentioned “immediately adjacent to” includes a region within 2 microns from the boundary. The at least one film layer of the above-mentioned light-emitting functional layer may be a film layer formed by the inkjet printing process.

For example, the fluorine content of the surface of the defining portion 320 immediately adjacent to the periphery of the first region 01 is greater than the fluorine content of the surface of the defining portion 320 immediately adjacent to the periphery of the sub-region 020. For example, the defining portion 320 located at the periphery of the first region 01 is a lyophobic region for at least one film layer of the light-emitting functional layer 230, and the defining portion 320 located at the periphery of the sub-region 020 is a lyophilic region for at least one film layer of the light-emitting functional layer 230. Adjusting the fluorine contents of the surfaces of defining portions at different positions is beneficial to the diffusion of at least one film layer (such as ink) of the light-emitting functional layer and balance the evaporation rate of the ink.

For example, the fluorine content of the surface of the defining portion is the fluorine content within a range of 0.1 microns or 0.2 microns from the surface. For example, the above-mentioned “immediately adjacent to” includes a region within 1 micron from the boundary. For example, the above-mentioned “immediately adjacent to” includes a region within 2 microns from the boundary. For example, the mass percentage of fluorine of the surface of the defining portion 320 located immediately adjacent to the periphery of the first region 01 is greater than 5%. The mass percentage of fluorine of the surface of the defining portion 320 located immediately adjacent to the periphery of the sub-region 020 is less than 5%. For example, the mass percentage of fluorine of the surface of the defining portion 320 located immediately adjacent to the periphery of the first region 01 is greater than 5.5%. The mass percentage of fluorine of the surface of the defining portion 320 located immediately adjacent to the periphery of the sub-region 020 is less than 4.5%.

For example, as illustrated in FIG. 1-FIG. 6, the defining portion 320 covering the second region 02 further includes a third sub-defining portion 323 surrounding the sub-region 020, and a surface of a side of the third sub-defining portion 323 away from the base substrate 100 includes a slope. For example, a slope angle of a portion, close to a side of the base substrate, of a slope on a surface of a side of the third sub-defining portion 323 away from the base substrate 100 is less than a slope angle of a portion, close to a side of the base substrate, of a slope formed on a surface of a side of the second sub-defining portion 322 away from the base substrate 100. For example, the range of the slope angle of the portion, close to a side of the base substrate, of the slope on the surface of the side of the third sub-defining portion 323 away from the base substrate 100 includes 5°-70°. For example, the range of the slope angle of the portion, close to a side of the base substrate, of the slope on the surface of the side of the third sub-defining portion 323 away from the base substrate 100 includes 5°-35°. For example, the range of the slope angle of the portion, close to a side of the base substrate, of the slope on the surface of the side of the third sub-defining portion 323 away from the base substrate 100 includes 10°-30°. For example, the range of the slope angle of the portion, close to a side of the base substrate, of the slope on the surface of the side of the third sub-defining portion 323 away from the base substrate 100 includes 15°-45°. For example, the range of the slope angle of the portion, close to a side of the base substrate, of the slope on the surface of the side of the third sub-defining portion 323 away from the base substrate 100 includes 40°-60°. For example, the range of the slope angle of the portion, close to a side of the base substrate, of the slope on the surface of the side of the third sub-defining portion 323 away from the base substrate 100 includes 45°-50°.

The above-mentioned slope angle of the third sub-defining portion 323 may refer to an included angle between a tangent line at an intersection point, being contact with a structure 003, of a curve of the slope cut by the XZ plane and the X direction. But not limited thereto, for example, the above-mentioned slope angle of the third sub-defining portion 323 may refer to an included angle between a tangent line, at a midpoint of the curve of the slope cut by the XZ plane, and the X direction.

For example, the average thickness of the third sub-defining portion 323 is in a range of 0.11-10 microns. For example, the average thickness of the third sub-defining portion 323 is in a range of 0.2-7 microns. For example, the average thickness of the third sub-defining portion 323 is less than 6 micrometers. For example, the average thickness of the third sub-defining portion 323 is less than 3 micrometers. For example, the average thickness of the third sub-defining portion 323 is smaller than the average thickness of the defining portion in the sub-region. For example, in a direction extending from the sub-region to the third sub-defining portion, the thickness of the defining portion gradually decreases.

For example, the maximum dimension of the sub-region on a plane parallel to the surface of the base substrate is less than 15 microns. The maximum dimension is, for example, the diameter of a circle, or the long side dimension of a rectangle, or the long axis dimension of an ellipse, or the farthest distance between a pair of opposite sides of a hexagon, or the farthest distance between a pair of opposite sides of an octagon, or the like. For example, the maximum dimension of the sub-region on the plane parallel to the surface of the base substrate is less than 10 microns. For example, the maximum dimension of the sub-region on the plane parallel to the surface of the base substrate is less than 8 microns. For example, the maximum dimension of the sub-region on the plane parallel to the surface of the base substrate is less than a dimension of the third sub-defining portion in a direction parallel to a line connecting the corresponding sub-region and a center of the adjacent light-emitting region. For example, the maximum dimension of the sub-region on the plane parallel to the surface of the base substrate is greater than the dimension of the third sub-defining portion in the direction parallel to the line connecting the corresponding sub-region and the center of the adjacent light-emitting region. For example, the range of the ratio of the maximum dimension of the sub-region on the plane parallel to the surface of the base substrate to the dimension of the third sub-defining portion in the direction parallel to the line connecting the corresponding sub-region and the center of the adjacent light-emitting region includes 0.2-5. For example, the range of the ratio of the maximum dimension of the sub-region on the plane parallel to the surface of the base substrate to the dimension of the third sub-defining portion in the direction parallel to the line connecting the corresponding sub-region and the center of the adjacent light-emitting region includes 0.1-10. For example, the range of the ratio of the maximum dimension of the sub-region on the plane parallel to the surface of the base substrate to the dimension of the third sub-defining portion in the direction parallel to the line connecting the corresponding sub-region and the center of the adjacent light-emitting region includes 0.2-5. For example, the range of the ratio of the maximum dimension of the sub-region on the plane parallel to the surface of the base substrate to the dimension of the third sub-defining portion in the direction parallel to the line connecting the corresponding sub-region and the center of the adjacent light-emitting region includes 0.3-3.

For example, the thickness of the third sub-defining portion 323 is different from the thickness of the first sub-defining portion 321, the junction of the third sub-defining portion 323 and the first sub-defining portion 321 is a smooth surface in a shape of “˜”, such as a wave shape with a low degree of undulation, the height difference of surfaces of the third sub-defining portion 323 and the first sub-defining portion 321 is in a range of 0.1-1 micron, and the first sub-defining portion and the third sub-defining portion can be formed by patterning the same material by using a half-tone mask process. For example, the thickness of the third sub-defining portion 323 is different from the thickness of the first sub-defining portion 321, and the height difference of surfaces of the third sub-defining portion 323 and the first sub-defining portion 321 is in a range of 0.2-0.9 microns. For example, the thickness of the third sub-defining portion 323 is different from the thickness of the first sub-defining portion 321, and the height difference of surfaces of the third sub-defining portion 323 and the first sub-defining portion 321 is in a range of 0.3-0.8 microns. For example, the thickness of the third sub-defining portion 323 is different from the thickness of the first sub-defining portion 321, and the height difference of surfaces of the third sub-defining portion 323 and the first sub-defining portion 321 is in a range of 0.4-0.9 microns. For example, the thickness of the third sub-defining portion 323 is different from the thickness of the first sub-defining portion 321, and the height difference of surfaces of the third sub-defining portion 323 and the first sub-defining portion 321 is in a range of 0.3-0.75 microns.

For example, as illustrated in FIG. 1-FIG. 6, the average thickness of the light-emitting functional layer 230 on the second sub-defining portion 322 and the average thickness of the light-emitting functional layer 230 on the third sub-defining portion 323 are both less than the average thickness of the light-emitting functional layer 230 in the sub-region 020. For example, the average thicknesses of the light-emitting functional layers 230 in regions of the second region 02 except for the sub-region 020 are all less than the average thickness of the light-emitting functional layer 230 in the sub-region 020. For example, the thicknesses of the defining portions at positions other than the third sub-defining portion among the defining portions between light-emitting elements emitting light of the same color are in a range of 0.1-1 micron, or in a range of 0.2-0.8 microns, or in a range of 0.25-0.7 microns.

For example, as illustrated in FIG. 1-FIG. 6, the average thickness of the second sub-defining portion 322 and the average thickness of the third sub-defining portion 323 are both less than the average thickness of the defining portion 320 in the sub-region 020. For example, the average thicknesses of the defining portions 320 in regions of the second region 02 except for the sub-region 020 are all less than the average thickness of the defining portion 320 in the sub-region 020.

For example, as illustrated in FIG. 1-FIG. 6, the shortest distance from the boundary of the sub-region to the boundary of the first sub-defining portion or the boundary of the second sub-defining portion is in a range of 1-20 microns, or in a range of 2-18 microns, or in a range of 3-16 microns, or in a range of 5-15 microns, or in a range of 7-13 microns, or in a range of 10-12 microns. Adjusting the distance between the sub-region and the first sub-defining portion and the distance between the sub-region and the second sub-defining portion can allocate the required amount of ink and solvent atmosphere, which is beneficial to providing a suitable area and depth of the sub-region.

For example, as illustrated in FIG. 1-FIG. 6, the dimension of the second sub-defining portion 322 in the first direction is in a range of 30-40 microns, and the dimension of the second sub-defining portion 322 in the second direction is in a range of 28-32 microns. For example, the dimension of the second sub-defining portion 322 in the first direction is in a range of 10-50 microns. For example, the dimension of the second sub-defining portion 322 in the second direction is in a range of 25-35 microns. For example, the dimension of the second sub-defining portion 322 in the first direction is in a range of 25-45 microns. For example, the dimension of the second sub-defining portion 322 in the second direction is in a range of 20-40 microns.

For example, as illustrated in FIG. 1-FIG. 6, the width of the first sub-defining portion 321 in the second direction is in a range of 5-300 microns. For example, the width of the first sub-defining portion 321 in the second direction is in a range of 10-30 microns. For example, the width of the first sub-defining portion 321 in the second direction is in a range of 6-20 microns. For example, the width of the first sub-defining portion 321 in the second direction is in a range of 7-18 microns. For example, the width of the first sub-defining portion 321 in the second direction is in a range of 8-16 microns. For example, the width of the first sub-defining portion 321 in the second direction is in a range of 9-15 microns. For example, the width of the first sub-defining portion 321 in the second direction is in a range of 12-28 microns. For example, the width of the first sub-defining portion 321 in the second direction is in a range of 11-25 microns. For example, the width of the first sub-defining portion 321 in the second direction is in a range of 13-20 microns. For example, the width of the first sub-defining portion 321 in the second direction is in a range of 14-18 microns. For example, the width of the first sub-defining portion 321 in the second direction is in a range of 14-16 microns. For example, the width of the first sub-defining portion 321 in the second direction is in a range of 15-17 microns.

The position where the thickness of the defining portion is greater (such as the position where the first sub-defining portion is located) is configured to reduce the cross-color caused by ink overflow between the light-emitting elements of different colors, so the width of the first sub-defining portion cannot be provided too less; however, in order to increase the aperture ratio of the light-emitting element, the width of the second sub-defining portion in each direction can be reduced to improve the aperture ratio and overall brightness as much as possible.

For example, as illustrated in FIG. 1-FIG. 6, a planarization layer 002 is provided on the base substrate 100. For example, the material of the planarization layer 002 includes one or a combination of resin, acrylic, polyethylene terephthalate, polyimide, polyamide, polycarbonate, epoxy resin, and the like.

For example, as illustrated in FIG. 1-FIG. 6, other film layer 001 is further provided between the planarization layer 002 and the base substrate 100. For example, the film layer 001 includes one or more layers of a light-shielding layer, a gate insulating layer, an interlayer insulating layer, a signal line layer, and the like.

For example, as illustrated in FIG. 1-FIG. 6, the display substrate further includes a pixel circuit 003 (such as including thin film transistors, storage capacitors, electrodes and other structures), and the first electrode 210 of the light-emitting element 200 is electrically connected to the pixel circuit 003. For example, the display substrate includes a semiconductor layer, a gate insulating layer, a first conductive layer, an interlayer insulating layer, a second conductive layer, and the like. For example, the active semiconductor layer of each thin film transistor and the corresponding connection electrode structure or capacitor electrode are formed in the semiconductor layer, and the connection electrode structure or capacitor electrode are formed by doping and conducting the semiconductor layer, or formed to be an integral structure with the active semiconductor layer. For example, the gate insulating layer is formed on a side of the semiconductor layer away from the base substrate, and via holes are formed in the gate insulating layer for connecting the semiconductor layer to the first conductive layer or the second conductive layer. For example, the first conductive layer is formed on a side of the gate insulating layer away from the base substrate, and the first conductive layer is formed with a gate electrode of each thin film transistor, some signal lines, and some connection electrodes or capacitor electrodes. The some signal lines are configured to transmit one or more of the gate signal, data signal, reset signal, reset control signal, etc.; the connection electrodes are configured to connect the interlayer patterns, or connect the second conductive layer upwards and the semiconductor layer downwards; and the capacitor electrodes are configured to form capacitors with the pattern of the semiconductor layer and/or the pattern of the second conductive layer. For example, the interlayer insulating layer is formed on a side of the first conductive layer away from the base substrate, and the interlayer insulating layer is formed with via holes for connecting patterns in the semiconductor layer, the first conductive layer, and the second conductive layer. For example, the second conductive layer is formed on a side of the interlayer insulating layer away from the base substrate, and the second conductive layer is formed with source and drain electrodes of each thin film transistor, some signal lines, and some connection electrodes or capacitor electrodes. The some signal lines are configured to transmit one or more of the gate signal, data signal, reset signal, reset control signal, etc.; and the connection electrodes are configured to connect the interlayer patterns, such as connect the electrode of the light-emitting element upwards and the pattern of the first conductive layer or the pattern of the semiconductor layer downwards. For example, the display substrate further includes a third conductive layer, the third conductive layer is located between the second conductive layer and the light-emitting element, the third conductive layer is configured to connect the second conductive layer and the light-emitting element, and the pattern of the third conductive layer is also connected with the pattern of the first conductive layer and the pattern of the semiconductor layer. By providing one more layer of conductive layer, not only can the resistance be reduced in parallel with the second conductive layer or the first conductive layer, but also the flatness can be further improved through a first planarization layer provided between the second conductive layer and the third conductive layer and a second planarization layer provided between the third conductive layer and the light-emitting element, thereby further improving the process stability of the light-emitting element, reducing the color shift and improving the display quality.

For example, as illustrated in FIG. 3A, the portion of the planarization layer 002 corresponding to the sub-region 020 in the second region 02 includes a recessed portion, that is, the surface of the planarization layer includes a portion, closer to the base substrate, of a surface that is away from the substrate than the main body of the planarization layer. In some embodiments, part of the electrodes may partially overlap with the recessed portion of the planarization layer (or the portion corresponding to the sub-region). For example, the anode of the light-emitting element located on a side of the planarization layer away from the base substrate partially overlaps with the recessed portion of the planarization layer, or the anode completely covers the recessed portion of the planarization layer or covers more than 80% of the recessed portion of the planarization layer.

For example, in some embodiments, the display substrate includes a plurality of planarization layers, the surface of at least one planarization layer away from the base substrate is provided with a recessed portion, and the orthographic projection of at least one electrode or wire on the base substrate overlaps with the orthographic projection of the recessed portion of the planarization layer on the base substrate. In some embodiments, the first planarization layer is provided between the second conductive layer and the third conductive layer, the second planarization layer is provided between the third conductive layer and the light-emitting element, the surface of the second planarization layer away from the base substrate is provided with a recessed portion, and the orthographic projection of the anode of the light-emitting element on the base substrate at least partially overlaps with the orthographic projection of the recessed portion on the base substrate. In some embodiments, the first planarization layer is provided between the second conductive layer and the third conductive layer, the second planarization layer is provided between the third conductive layer and the light-emitting element, the surface of the second planarization layer away from the base substrate is provided with a recessed portion, and the orthographic projection of the anode of the light-emitting element on the base substrate completely covers the orthographic projection of at least one recessed portion on the base substrate. In some embodiments, the first planarization layer is provided between the second conductive layer and the third conductive layer, the second planarization layer is provided between the third conductive layer and the light-emitting element, the surface of the first planarization layer away from the base substrate is provided with a recessed portion, and the orthographic projection of the pattern of the third conductive layer on the base substrate at least partially overlaps with the orthographic projection of the recessed portion on the base substrate. In some embodiments, the first planarization layer is provided between the second conductive layer and the third conductive layer, the second planarization layer is provided between the third conductive layer and the light-emitting element, the surface of the first planarization layer away from the base substrate is provided with a recessed portion, and the orthographic projection of the pattern of the third conductive layer on the base substrate completely covers the orthographic projection of at least one recessed portion on the base substrate. In some embodiments, the recessed portion of the first planarization layer causes the corresponding position of the second planarization layer to also be provided with a recessed portion, so that the corresponding defining portion is also provided with a recessed portion, which can also be served as a sub-region for storing ink.

In some embodiments, a surface, away from the base substrate, of a portion of the defining portion corresponding to the sub-region is provided with a recessed portion. For example, at least one electrode or wire overlaps with the recessed portion of the defining portion. The recessed portion provided in at least part of the defining portion can be used to store ink and balance the solvent atmosphere during drying.

In some embodiments, because the sub-region is located in the non-light-emitting region, for the convenience of the layout of the pixel circuit or to save more space, the pattern of the anode or the third conductive layer overlapping with the recessed portion (or the overlapping portion of the defining portion, or the corresponding portion of the sub-region) of the planarization layer (or the first planarization layer, or the second planarization layer) can also be used as a connection structure; that is, the recessed portion of the planarization layer (or the first planarization layer, or the second planarization layer) or the recessed portion of the defining portion can be formed as a through hole (as illustrated in FIG. 3B), and the pattern of the anode or the third conductive layer located in this region is connected with the conductive pattern of another layer (such as the first conductive layer, the second conductive layer, the anode layer or the cathode layer) through the through hole. In some embodiments, the portion of the planarization layer corresponding to the sub-region is formed with a through hole, and the dimension of the through hole on the side away from the base substrate is greater than that on the side close to the base substrate. In some embodiments, the portion of the planarization layer corresponding to the sub-region includes a non-through hole, and the dimension of the non-through hole on the side away from the base substrate is greater than that on the side close to the base substrate. In some embodiments, the portion of the defining portion corresponding to the sub-region is formed with a through hole, and the dimension of the through hole on the side away from the base substrate is greater than the dimension on the side close to the base substrate. In some embodiments, the portion of the defining portion corresponding to the sub-region includes a non-through hole, and the dimension of the non-through hole on the side away from the base substrate is greater than that on the side close to the base substrate.

The dimension and area of the sub-region away from the base substrate are provided to be larger which can better match the evaporation rate of the ink; usually, when the ink starts to evaporate, the concentration of the solvent atmosphere is greater, and the portion outside the light-emitting region needs more solvent evaporation to balance the solvent atmosphere everywhere; as the drying progresses, the concentration of the solvent atmosphere becomes less and less, and the required solvent in the sub-region is also less and less, therefore, the dimension of the sub-region also changes with the progress of the evaporative drying process, and the closer to the substrate, the dimension gradually decreases.

Because the thickness of the layer where the planarization layer or the defining portion is located is usually thicker than other film layers, it is easier to achieve the case that a recess is provided on the layer where the planarization layer or the defining portion is located to form a sub-region for storing ink. For example, in some embodiments, the thickness of the planarization layer is in the range of 2-6 microns. For example, the thickness of the layer where the defining portion is located is in the range of 0.5-2 microns. For example, the depth of the recess in the planarization layer (as illustrated in FIG. 3A) accounts for 10%-100% of the thickness of the planarization layer. For example, the depth of the recess formed in the layer where the defining portion is located accounts for 10%-100% of the thickness of the layer where the defining portion is located. In some embodiments, the sub-region may also be formed in other conductive layers or insulating layers, or formed in cooperation with the layer where the planarization layer or the defining portion is located. For example, the thickness of at least one conductive layer or insulating layer corresponding to the sub-region is made less than that corresponding to a region other than the sub-region. For example, the amount of conductive layers or insulating layers in the sub-region may be made less than the amount of conductive layers or insulating layers in a region other than the sub-region. For example, the amount of conductive layers or insulating layers in the sub-region is at least one less. For example, the amount of conductive layers or insulating layers in the sub-region is at least two less.

For example, the first electrode 210 in the light-emitting element 200 is electrically connected to the pixel circuit 003 through a through hole (as illustrated in FIG. 3B) formed in the recessed portion of the planarization layer 002. For example, the pixel circuit 003 includes a thin film transistor, and the first electrode 210 in the light-emitting element 200 is electrically connected to one of a source electrode and a drain electrode of the thin film transistor through a through hole in the planarization layer 002.

For example, the thickness of the planarization layer 002 is in a range of 2-7 microns. For example, the thickness of the planarization layer 002 is in a range of 2.5-6.5 microns. For example, the thickness of the planarization layer 002 is in a range of 3-6 microns. For example, the thickness of the planarization layer 002 is in a range of 3.5-5.5 microns. For example, the thickness of the planarization layer 002 is in a range of 4-5 microns.

For example, the portion of the planarization layer corresponding to the sub-region include a through hole or a non-through hole or a groove formed on a side of the planarization layer away from the base substrate. For example, after filling the through hole or the non-through hole or the groove with a pixel-defining pattern and/or a light-emitting functional layer provided at the through hole or the non-through hole or the groove of the planarization layer, a recessed region can still be formed, and the depth of the recessed region is in a range of 0.5-4 microns. For example, after filling the through hole or the non-through hole or the groove with a pixel-defining pattern and/or a light-emitting functional layer provided at the through hole or the non-through hole or the groove of the planarization layer, a recessed region can still be formed, and the depth of the recessed region is in a range of 0.8-3 microns. For example, after filling the through hole or the non-through hole or the groove with a pixel-defining pattern and/or a light-emitting functional layer provided at the through hole or the non-through hole or the groove of the planarization layer, a recessed region can still be formed, and the depth of the recessed region is in a range of 1-2 microns.

For example, as illustrated in FIG. 1-FIG. 6, the orthographic projection of at least one sub-region 020 on the base substrate 100 falls within the orthographic projection of the first electrode 210 on the base substrate 100. For example, the orthographic projection of at least one through hole or non-through hole or groove in the planarization layer 002 or the pixel-defining pattern (defining portion) on the base substrate 100 falls within the orthographic projection of the first electrode 210 on the base substrate 100.

For example, as illustrated in FIG. 1-FIG. 6, the orthographic projection of at least one sub-region 020 on the base substrate 100 overlaps with a part of the orthographic projection of the first electrode 210 on the base substrate 100. For example, the orthographic projection of at least one through hole or non-through hole or groove in the planarization layer 002 or the pixel-defining pattern (defining portion) on the base substrate 100 overlaps with the orthographic projection of the first electrode 210 on the base substrate 100.

For example, as illustrated in FIG. 1-FIG. 6, the amount of a plurality of film layers included in the light-emitting functional layer 230 located in the first region 01 is identical to the amount of a plurality of film layers included in the light-emitting functional layer 230 located in the second region 02. For example, the light-emitting functional layers 230 located in the first region 01 and the second region 02 each includes a hole injection layer (HIL), a hole transport layer (HTL), a light-emitting layer (EL), an electron transport layer (ETL), an electron injection layer (EIL) and other film layers. For example, the light-emitting functional layer 230 further includes a hole blocking layer (HBL), an electron blocking layer (EBL), a microcavity regulating layer, an exciton regulating layer or other functional film layers. For example, the hole blocking layer is located between the light-emitting layer and the second electrode 220. For example, the electron blocking layer is located between the light-emitting layer and the first electrode 210. For example, the light-emitting functional layer further includes a plurality of stacked layer, for example, a first stacked layer includes a first light-emitting layer, a second stacked layer includes a second light-emitting layer, and the first stacked layer and the second stacked layer further include one or more layers of the hole injection layer (HIL), the hole transport layer (HTL), the light-emitting layer (EL), the electron transport layer (ETL), the electron injection layer (EIL), the hole blocking layer, the electron blocking layer, the microcavity regulating layer, the exciton regulating layer and other functional film layers. A charge generation layer (CGL) may be included between the first stacked layer and the second stacked layer, and the charge generation layer (CGL) may include an n-doped charge generation layer (CGL), and/or p-doped charge generation layer (CGL). Of course, in order to further improve the luminous efficiency, the light-emitting functional layer may also include three or more stacked layers.

For example, among the plurality of film layers included in the light-emitting functional layer 230, at least one layer includes quantum dots, for example, the light-emitting layer includes quantum dots. For example, in a light-exiting direction of the light-emitting functional layer, other functional layers may also be included, such as a quantum dot layer, a color filter layer, a lens layer, etc. For example, the light-emitting layer is made of phosphorescent light-emitting material or fluorescent light-emitting material. For example, the light-emitting layer includes TADF, organometallic complexes, and the like. For example, the light-emitting layer is a single layer, or is stacked by a plurality of layers, and the light-emitting layer stacked by a plurality of layers is made of the same material or different materials. For example, the pattern of the light-emitting layer is approximately identical to the pattern of at least one functional film layer other than the light-emitting layer, or is different from the pattern of at least one functional film layer other than the light-emitting layer. For example, at least one layer of the light-emitting functional layer is an integral layer, and at least one layer includes a plurality of patterns.

For example, the ratio of the area of one sub-region 020 to the area of one first region 01 is 0.5%-10%. For example, the ratio of the area of one sub-region 020 to the area of one first region 01 is 1%-9%. The ratio of the area of one sub-region 020 to the area of one first region 01 is 2%-8%. The ratio of the area of one sub-region 020 to the area of one first region 01 is 3%-7%. The ratio of the area of one sub-region 020 to the area of one first region 01 is 5%-6%.

For example, the area of one sub-region 020 is smaller than the area of one first region 01. For example, the ratio of the area of one sub-region 020 (through hole or non-through hole or groove) to the area of one first region 01 is 0.01-1. For example, the ratio of the area of one sub-region 020 (through hole or non-through hole or groove) to the area of one first region 01 is 0.02-0.9. For example, the ratio of the area of one sub-region 020 (through hole or non-through hole or groove) to the area of one first region 01 is 0.05-0.8. For example, the ratio of the area of one sub-region 020 (through hole or non-through hole or groove) to the area of one first region 01 is 0.1-0.7. For example, the ratio of the area of one sub-region 020 (through hole or non-through hole or groove) to the area of one first region 01 is 0.15-0.6. By setting the area ratio between the sub-region and the first region, the magnitude relationship between the ink evaporation rate of the sub-region and the ink evaporation rate of the first region can be determined, and a more suitable ink volume ratio can be obtained by combining parameters such as distance and depth, so as to better balance the ink evaporation rate, but not waste more ink and reduce costs.

For example, as illustrated in FIG. 1-FIG. 6, the amount of the plurality of film layers included in the light-emitting functional layer 230 located in the first region 01 is greater than the amount of the plurality of film layers included in the light-emitting functional layer 230 in at least partial region where the thickness of the defining portion 320 located between the light-emitting elements 200 emitting light of different colors is maximum. For example, the position where the thickness of the defining portion 320 is maximum is provided with the first sub-defining portion 321, and the amount of layers of the light-emitting functional layer 230 on at least partial region of the first sub-defining portion 321 is at least one layer less than the amount of layers of the light-emitting functional layer 230 in the opening 310. For example, the amount of layers of the light-emitting functional layer 230 in the second region 02 is greater than the amount of layers of the light-emitting functional layer 230 on at least partial region of the first sub-defining portion 321. For example, the amount of layers of the light-emitting functional layer 230 on at least partial region of the first sub-defining portion 321 is greater than the amount of layers of the light-emitting functional layer 230 on at least partial region of the second sub-defining portion 322. For example, the amount of layers of the light-emitting functional layer 230 on at least partial region of the second sub-defining portion 322 is identical to the amount of layers of the light-emitting functional layer 230 in the first region (or the opening 310).

For example, as illustrated in FIG. 1-FIG. 6, the area of the orthographic projection of the sub-region 020 on the base substrate 100 is smaller than the area of the orthographic projection of the first region 01 on the base substrate 100. For example, the ratio of the area of the sub-region 020 to the area of the first region 01 is 1%-10%. The area of the above-mentioned sub-region 020 may refer to the area of the orthographic projection of the through hole or the non-through hole or the groove in the planarization layer or the defining portion on the base substrate 100. The above-mentioned area of the first region 01 may refer to the area of the orthographic projection of the opening 310 on the base substrate 100. For example, the ratio of the area of the through hole or the non-through hole or the groove of the planarization layer or the defining portion to the area of the opening 310 is 1%-10%. For example, the ratio of the area of the sub-region 020 to the area of the first region 01 is not greater than 4%. For example, the ratio of the area of the sub-region 020 to the area of the first region 01 is 2%-4%. For example, the ratio of the area of the sub-region 020 to the area of the first region 01 is 1%-3%. For example, the ratio of the area of the sub-region 020 to the area of the first region 01 may be 3-5%.

For example, the area of the sub-region 020 is in a range from 5 μm×5 μm to 10 μm×10 μm. For example, the area of the sub-region 020 is 6 μm×6 μm. For example, the area of the sub-region 020 is 7 μm×7 μm. For example, the area of the sub-region 020 is 8 μm×8 μm. For example, the area of the sub-region 020 is 9 μm×9 μm. For example, the area of the sub-region 020 is (3˜20) μm×(10˜50) μm. For example, the area of the sub-region 020 is (3˜15) μm×(15˜45) μm. For example, the area of the sub-region 020 is (2˜18) μm×(10˜100) μm. For example, the area of the sub-region 020 is (3˜15) μm×(20˜90) μm. For example, the area of the sub-region 020 is (4˜13) μm×(20˜80) μm. For example, the area of the opening 310 is in a range from 20 μm×50 μm to 40 μm×100 μm. For example, the area of the opening 310 is 30 μm×60 μm. For example, the area of the opening 310 is 25 μm×70 μm. For example, the area of the opening 310 is 35 μm×80 μm. For example, the area of the opening 310 is 28 μm×94 μm. For example, the area of the opening 310 is (10˜50) μm×(20˜100) μm. For example, the area of the opening 310 is (15˜45) μm×(25˜95) μm. For example, the area of the opening 310 is (10˜40) μm×(23˜80) μm.

For example, the increase in the dimension of the opening 310 is beneficial to improve the printing accuracy of at least part of the film layers of the light-emitting functional layer formed by inkjet printing. For example, the width of the opening 310 is 25-30 microns, for example, the shape of the opening 310 is approximately a rectangle, or an ellipse, or a strip with arcs at both ends, or a polygon, etc.

For example, the maximum dimension of the orthographic projection of the light-emitting functional layer 230 or the defining portion 320 in the sub-region 020 on the base substrate 100 is greater than the spacing between the first electrodes 210 of adjacent light-emitting elements 200. For example, the distance between the first electrodes 210 of adjacent light-emitting elements 200 is 4-5 microns. For example, the distance between the first electrodes 210 of adjacent light-emitting elements 200 is 4.2-4.8 microns. For example, the distance between the first electrodes 210 of adjacent light-emitting elements 200 is 4.4-4.6 microns. For example, the distance between the first electrodes 210 of adjacent light-emitting elements 200 is 4.3-4.5 microns.

For example, the shape of the sub-region 020 is a rectangle, but is not limited thereto, and is also other polygons such as a triangle, a pentagon, or the like.

An example of the embodiments of the present disclosure can reduce the dimension of the defining portion in the direction parallel to the base substrate by reducing the area of the sub-region, which is beneficial to reduce the distance between the light-emitting regions of the light-emitting elements. In addition, reducing the region of the sub-region is also beneficial to reduce the consumption of a certain light-emitting functional layer formed by ink, thereby improving the effect of balancing the solvent atmosphere. The evaporative solvent atmosphere can be balanced with less ink by reducing the area of a single sub-region, and the duration of the balancing action can be extended by increasing the depth of the sub-region.

For example, as illustrated in FIG. 1-FIG. 2F, the ratio of the amount of the second regions 02 to the amount of the first regions 01 is 0.8-1.2. For example, the ratio of the amount of the second regions 02 to the amount of the first regions 01 is 0.9-1.1. For example, the ratio of the amount of the second regions 02 to the amount of the first regions 01 is close to 1. For example, the plurality of first regions 01 and the plurality of second regions 02 on the display substrate are arranged alternately in the first direction.

For example, in the second direction (such as the row direction), the first regions 01 are arranged in a row, and the second regions 02 are arranged in a row (as illustrated in FIG. 2A-FIG. 2E). But not limited thereto, as illustrated in FIG. 2F, two adjacent columns of first regions 01 may be arranged in a shifted manner. For example, the shape of the first region 01 is an ellipse, but not limited thereto, and is also other shapes such as a hexagon with a wide middle and narrow two edges, so as to increase the aperture ratio. For example, as illustrated in FIG. 2F, the shape of the sub-region 020 is a circle, but not limited thereto, and is also an ellipse, or an irregular pattern, and sides of the pattern include a curved side. The embodiments of the present disclosure do not limit the shape of the sub-region.

For example, as illustrated in FIG. 2G, the side at a position of the first region 01 corresponding to the sub-region 020 is concave, and the side at a position of the sub-region 020 corresponding to the first region 01 is convex, and the patterns at the opposite positions of the first region 01 and the sub-region 020 are complementary. For example, the distance between the opposite edges of the sub-region 020 and the first region 01 is smaller than the width of the defining portion at other positions.

For example, as illustrated in FIG. 1 to FIG. 6, the light-emitting functional layer 230 at least includes a first film layer 231 and a second film layer 232, the maximum thickness of the first film layer 231 in the sub-region 020 is greater than the maximum thickness of the first film layer 231 in the first region 01, and the ratio of the maximum thickness of the second film layer 232 in the sub-region 020 to the maximum thickness of the second film layer 232 in the first region 01 is in a range of 0.8-1.2. For example, the ratio of the maximum thickness of the second film layer 232 in the sub-region 020 to the maximum thickness of the second film layer 232 in the first region 01 is in a range of 0.9-1.1.

For example, the light-emitting functional layer 230 at least includes a first film layer 231 and a second film layer 232, the maximum thickness of the first film layer 231 in the sub-region 020 is greater than the maximum thickness of the first film layer 231 in the first region 01, and the maximum thickness of the second film layer 232 in the sub-region 020 is equal to the maximum thickness of the second film layer 232 in the first region 01. For example, the average thickness of the first film layer 231 in the sub-region 020 is greater than the average thickness of the first film layer 231 in the first region 01, and the average thickness of the second film layer 232 in the sub-region 020 is equal to the average thickness of the second film layer 232 in the first region 01. For example, the first film layer and the second film layer are manufactured by the same process, for example, are both manufactured by the printing process or the evaporation process. For example, the first film layer and the second film layer are manufactured by different processes, for example, one of the first film layer and the second film layer is manufactured by the printing process, and the other of the first film layer and the second film layer is manufactured by the evaporation process.

For example, the first film layer 231 is a multilayer structure, the second film layer 232 is also a multilayer structure, the boundary of each layer in the first film layer 231 is approximately the same, and the boundary of each layer in the second film layer 232 is approximately the same.

For example, the first film layer 231 includes a hole injection layer, a hole transport layer, a light-emitting layer, and may also include other functional layers, which may be two layers, three layers or four layers. For example, at least one layer of the first film layer 231 includes a crosslinkable compound. For example, the layer farthest away from the base substrate in the first film layer 231 does not include a crosslinkable compound. For example, the layer farthest away from the base substrate includes one material or two materials, and may also include three materials. For example, the layer farthest away from the base substrate includes organic substances, inorganic substances, two or three organic substances, or at least one inorganic substance, for example, includes organic polymers, small organic molecules, quantum dots or others.

For example, the second film layer 232 includes an electron transport layer and an electron injection layer, and may also include other functional layers.

In some embodiments, among the layers included in the first film layer 231, the boundary of a film layer closest to the base substrate slightly exceeds the boundary of a film layer away from the base substrate.

In some embodiments, the boundary of the second film layer 232 is approximately identical to the boundary of the second electrode.

In some embodiments, the boundary of the electron injection layer or the electron transport layer slightly exceeds the boundary of the second electrode.

The boundary of one layer exceeding the boundary of the other layer describe above may mean that the boundary of the orthographic projection of one layer on the base substrate exceeds the boundary of the orthographic projection of the other layer on the base substrate, or may mean that the boundaries of the two layers are different because of different climbing heights on the slope of the pixel-defining pattern.

For example, the first film layer 231 is any one of film layers such as the hole injection layer, the hole transport layer, the light-emitting layer, etc., and the first film layer 231 is a film layer manufactured by the inkjet printing process. For example, the second film layer 232 is any one of the film layers such as the electron transport layer, the electron injection layer, etc., and the second film layer 232 is a film layer formed by the evaporation process. In the light-emitting functional layer in the sub-region and the light-emitting functional layer in the first region, the thicknesses of the film layers formed by the evaporation process are identical to each other, and the thicknesses of the film layers formed by the inkjet printing process are different from each other. The thickness of the ink formed by the inkjet printing process in the sub-region is provided to be greater than the thickness of the ink formed by the inkjet printing process in the first region, so as to beneficial to slow down the evaporation rate of the ink, thereby improving the effect of balancing the solvent atmosphere.

For example, as illustrated in FIG. 1-FIG. 6, the first film layer 231 is located between the second film layer 232 and the base substrate 100.

For example, as illustrated in FIG. 3A and FIG. 6, the maximum dimension of the orthographic projection of the light-emitting functional layer 230 in the sub-region 020 on the base substrate 100 is greater than the distance between the first electrodes 210 of the adjacent light-emitting elements 200 arranged in the first direction or the second direction. For example, the distance between the first electrodes 210 of adjacent light-emitting elements 200 is 4-5 microns. For example, the maximum dimension of the orthographic projection of the light-emitting functional layer 230 in the sub-region 020 on the base substrate 100 is greater than 4 micrometers. Providing the dimension of the light-emitting functional layer in the sub-region in the direction parallel to the base substrate to be greater than the distance between the first electrodes of adjacent light-emitting elements is beneficial to better balance the solvent atmosphere, and the efficiency is higher.

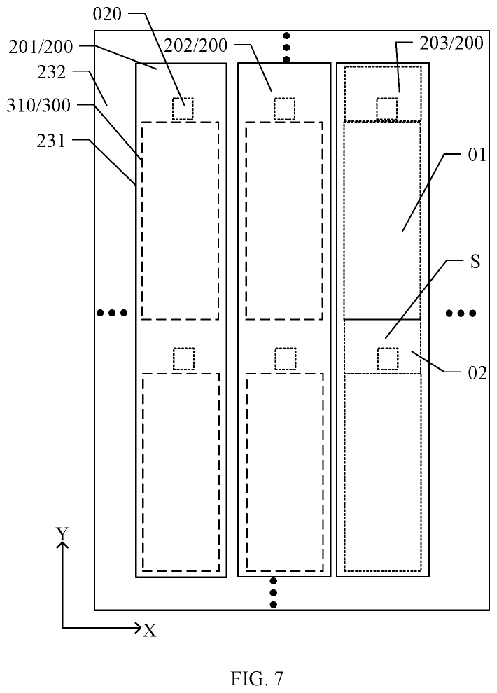

FIG. 7 is a schematic diagram illustrating a planar relationship between a first film layer and a second film layer of a light-emitting functional layer in an example of the display substrate illustrated in FIG. 1 and FIG. 2A. For example, as illustrated in FIG. 7, the area of the first film layer 231 is smaller than the area of the second film layer 232. For example, the second film layer 232 is a common film layer shared by a plurality of light-emitting elements 200, the first film layer 231 is a film layer shared by the light-emitting elements 200 emitting light of the same color, or a film layer independently included in each light-emitting element 200, and the first film layers 231 of the light-emitting elements 200 emitting light of different colors are each not a common film layer. For example, light-emitting elements 200, in a column, arranged along the Y direction are light-emitting elements that emit light of the same color, and light-emitting elements 200, in a column, arranged along the Y direction can share the first film layer 231. However, two adjacent light-emitting elements arranged along the X direction 200 are light-emitting elements 200 that emit light of different colors, and the first film layers 231 of the two adjacent light-emitting elements 200 are independent film layers. For example, the first film layers 231 of two adjacent light-emitting elements 200 arranged along the X direction may be arranged at intervals, or stacked, or contiguous with each other, and the embodiments of the present disclosure are not limited thereto.

For example, as illustrated in FIG. 1-FIG. 7, the orthographic projection of the first film layer 231 on the base substrate 100 falls within the orthographic projection of the second film layer 232 on the base substrate 100. For example, the boundary of the first film layer 231 is at least partially located within the range of the second film layer 232.

For example, as illustrated in FIG. 1-FIG. 7, the first film layer 231 at least covers two adjacent first regions 01 arranged in the first direction (the Y direction) and the defining portion between the two first regions 01, such as a spacing S. For example, the first film layer 231 covers the gap between the openings 310 corresponding to two adjacent light-emitting elements 200 arranged in the first direction that emit light of the same color. For example, the first film layer 231 of one light-emitting element 200 covers a portion of the gap between the openings 310 corresponding to two light-emitting elements 200 arranged in the second direction that emit light of different colors. For example, the first film layer 231 of one light-emitting element 200 covers all the gap between the openings 310 corresponding to two light-emitting elements 200 arranged in the second direction that emit light of different colors.

For example, as illustrated in FIG. 1-FIG. 7, the second film layer 232 at least covers two adjacent first regions 01 arranged along any direction of the first direction and the second direction, and a circle of defining portion surrounding any one of the two adjacent first regions 01. For example, the second film layer 232 at least covers two adjacent first regions 01 arranged along any direction of the first direction and the second direction and a complete circle of spacing surrounding any one of the two adjacent first regions 01.

For example, as illustrated in FIG. 1-FIG. 7, the amount of first regions 01 covered by at least one layer of the first film layer 231 arranged continuously is less than the amount of first regions 01 covered by at least one layer of the second film layer 232 arranged continuously. For example, the layer of first film layer 231 arranged continuously only covers the first regions 01 corresponding to the light-emitting elements 200 that exit light of the same color, and the layer of second film layer 232 arranged continuously can not only cover the first regions 01 corresponding to the light-emitting elements 200 that exit light of the same color, but also cover the first regions 01 corresponding to the light-emitting elements 200 that exit light of different colors.

For example, as illustrated in FIG. 1-FIG. 7, the average thicknesses of the first film layers 231 of two adjacent light-emitting elements 200 arranged in the second direction are different. For example, the maximum thicknesses of the first film layers 231 of two adjacent light-emitting elements 200 arranged in the second direction are different. For example, the average thicknesses of the first film layers 231 in the first regions 01 corresponding to two adjacent light-emitting elements 200 arranged in the second direction are different. For example, the average thicknesses of the first film layers 231 in the sub-regions 020 corresponding to two adjacent light-emitting elements 200 arranged in the second direction are different.

For example, in two adjacent light-emitting elements 200 arranged in the second direction, the ratio, of the average thickness of the first film layer 231 located in the sub-region 020 to the average thickness of the first film layer 231 located in the first region 01, of one light-emitting element 200 is different from that of the other one light-emitting element 200.

For example, in two adjacent light-emitting elements 200 arranged in the second direction, the average thicknesses, of the light-emitting functional layer of one light-emitting element 200 respectively in the sub-region 020 and in the first region 01, are both different from the average thicknesses, of the light-emitting functional layer of the other one light-emitting element 200 respectively in the sub-region 020 and in the first region 01. For example, in two adjacent light-emitting elements 200 arranged in the second direction, the maximum thickness of the light-emitting functional layer, in the sub-region 020, of one light-emitting element 200 is different from that of the other light-emitting element 200, and the maximum thickness of the light-emitting functional layer, in the first region 01, of one light-emitting element 200 is different from that of the other light-emitting element 200.

For example, the average thicknesses of the first film layers 231 in the light-emitting elements 200 of different colors are different, and the average thicknesses of the second film layers 232 in the light-emitting elements 200 of different colors are different.

For example, the average thickness of the first film layer 231 of the red light-emitting element 201 is greater than the average thickness of the first film layer 231 of the green light-emitting element 202, and the average thickness of the first film layer 231 of the green light-emitting element 202 is greater than the average thickness of the first film layer 231 of the blue light-emitting element 203.

For example, the thickness of the entire light-emitting functional layer of the red light-emitting element 201 is greater than the thickness of the entire light-emitting functional layer of the green light-emitting element 202, and the thickness of the entire light-emitting functional layer of the green light-emitting element 202 is greater than the thickness of the entire light-emitting functional layer of the blue light-emitting element 203.

For example, as illustrated in FIG. 1-FIG. 7, in two adjacent light-emitting elements 200 arranged in the second direction, the average thicknesses of the light-emitting functional layers 230 in the first regions 01 respectively corresponding to different light-emitting elements 200 are different.

For example, as illustrated in FIG. 1-FIG. 7, in two adjacent light-emitting elements 200 arranged in the second direction, the average thicknesses of the light-emitting functional layers 230 in the second regions 02 respectively corresponding to different light-emitting elements 200 are different. For example, in two adjacent light-emitting elements 200 arranged in the second direction, the ratio, of the average thickness of the light-emitting functional layer 230 in the second region 02 to the average thickness of the light-emitting functional layer 230 in the first region 01, of one light-emitting element 200 is different from that of the other one light-emitting element 200. For example, in two adjacent light-emitting elements 200 arranged in the second direction, the ratio, of the maximum thickness of the light-emitting functional layer 230 in the first region 01 to the maximum thickness of the light-emitting functional layer 230 in the second region 02, of one light-emitting element 200 is different from that of the other one light-emitting element 200.

For example, as illustrated in FIG. 1-FIG. 7, the first film layer 231 in the first region 01 is continuous with the first film layer 231 in the second region 02 adjacent to the first region 01. In the embodiments of the present disclosure, the film layers located in different regions are continuous means that the film layers located in different regions are a continuous film layer. For example, the continuous film layer is provided with substantially the same thickness, or provided with different thicknesses. For example, the thicknesses of different positions of the continuous film layer are different, for example, the thickness of the light-emitting functional layer in at least part of the second region is less than the thickness of the light-emitting functional layer in at least a central portion of the first region.

For example, as illustrated in FIG. 1-FIG. 7, in the light-emitting element 200 that emits light of one color, the first film layer 231 in the first region 01 is continuous with the first film layer 231 in the second region 02 located on both sides of the first region 01 in the first direction and immediately adjacent to the first region 01. The second region being located on both sides of the first region in the first direction and immediately adjacent to the first region mentioned above means that there is no other first region or second region between the first region and the second region. For example, in the light-emitting element 200 that emits light of one color, the first film layer 231 in the first region 01 and the first film layer 231 in the second region 02, which is located on both sides of the first region 01 in the first direction and immediately adjacent to the first region 01, are a continuous film layer.

For example, as illustrated in FIG. 1-FIG. 7, the first film layer 231 in a column of the first region 01 arranged in the first direction is continuous with the first film layer 231 in a column of the second region 02 arranged in the first direction. For example, the first film layer 231 in the first region 01 and the second region 02 arranged in a column along the first direction is a continuous film layer.

For example, as illustrated in FIG. 1-FIG. 7, the first film layer 231 located in the sub-region 020 is continuous with the first film layer 231 located in the light-emitting region of the light-emitting element 200, which can make the solvent atmosphere of the ink more uniform, and the flatness of the light-emitting functional layer in the light-emitting region is better.

For example, as illustrated in FIG. 1-FIG. 7, the first film layer 231 in a column of the first region 01 arranged in the first direction is continuous. For example, the first film layer 231 in a column of the second region 02 arranged in the first direction is continuous. For example, the first film layer 231 in the light-emitting region is continuous with the first film layer 231 in the sub-regions 020 located on both sides of the light-emitting region in the first direction.

For example, in the light-emitting elements 200 of different colors, the first film layer 231 in the light-emitting region of the light-emitting element 200 of at least one color is continuous with the first film layer 231 in the second regions 02 located on both sides of the light-emitting region in the first direction. For example, in the light-emitting element 200 with a thinner first film layer 231, the first film layer 231 in the light-emitting region is continuous with the first film layer 231 in the second regions 02 located on both sides of the light-emitting region in the first direction, so that the drying speed of the first film layer 231 in the light-emitting region can be slowed down, which is beneficial to improve the uniformity of the first film layer in the light-emitting region. For example, in the light-emitting element 200 with a thicker first film layer 231, the first film layer 231 in the light-emitting region is not continuous with the first film layer 231 in the second regions 02 located on both sides of the light-emitting region in the first direction.

For example, the first film layer 231 in the light-emitting regions of two adjacent light-emitting elements 200 arranged in the first direction is continuous. For example, the first film layer 231 in the light-emitting regions of two adjacent light-emitting elements 200 arranged in the first direction is a continuous film layer.

For example, as illustrated in FIG. 1-FIG. 7, at least one film layer in the light-emitting functional layer 230 includes a first portion located in the first region 01, a second portion located in the second region 02, and a third portion connecting the first portion and the second portion, and the thicknesses of the first portion, the second portion and the third portion are all different. For example, the above-mentioned at least one film layer is a film layer formed by the inkjet printing process. For example, the above-mentioned at least one film layer is any one of the hole injection layer, the hole transport layer and the light-emitting layer. For example, in the above-mentioned at least one film layer, the maximum thickness of the second portion is greater than the maximum thickness of the first portion, and the maximum thickness of the first portion is greater than the maximum thickness of the third portion. For example, the thicknesses of the first portions of the at least one film layer in different light-emitting elements are identical to or different from each other. For example, the thicknesses of the second portions of the at least one film layer in different light-emitting elements are identical to or different from each other. For example, the thicknesses of the third portions of the at least one film layer in different light-emitting elements are identical to or different from each other.

For example, as illustrated in FIG. 1-FIG. 7, the total thickness of the plurality of film layers included in the light-emitting functional layer 230 overlapping with the defining portion 320 is different from the total thickness of the plurality of film layers included in the light-emitting functional layer 230 in the opening 310. For example, the total thickness of the plurality of film layers included in the light-emitting functional layer 230 overlapping with the defining portion 320 is less than the total thickness of the plurality of film layers included in the light-emitting functional layer 230 in the opening 310. For example, the total thickness of the plurality of film layers included in the light-emitting functional layer 230 overlapping with the first sub-defining portion 321 is different from the total thickness of the plurality of film layers included in the light-emitting functional layer 230 in the opening 310. For example, the total thickness of the plurality of film layers included in the light-emitting functional layer 230 overlapping with the second sub-defining portion 322 is different from the total thickness of the plurality of film layers included in the light-emitting functional layer 230 in the opening 310.

For example, as illustrated in FIG. 1-FIG. 7, the proportion of the portion within 20% of the thickness deviation of the light-emitting functional layer 230 in the first region 01 is greater than the proportion of the portion within 20% of the thickness deviation of the light-emitting functional layer 230 in the second region 02. Thus, the light-emitting functional layer in the first region is provided with a higher flatness. Based on the thickness of the central portion of the light-emitting functional layer located in each region, the above-mentioned thickness deviation refers to the ratio of the difference from the thickness of the central portion to the thickness of the central portion. For example, the proportion of the portion within 10% of the thickness deviation of the light-emitting functional layer 230 in the first region 01 is greater than the proportion of the portion within 10% of the thickness deviation of the light-emitting functional layer 230 in the second region 02. For example, the proportion of the portion within 5% of the thickness deviation of the light-emitting functional layer 230 in the first region 01 is greater than the proportion of the portion within 5% of the thickness deviation of the light-emitting functional layer 230 in the second region 02.

For example, some dummy pixels are provided around the display region, and these dummy pixels are also provided with a complete structure, respectively. The light-emitting elements in the dummy pixels have the same characteristics as the light-emitting elements of other pixels, but there is no pixel circuit between the first electrode of the light-emitting element of the dummy pixel and the substrate, and the first electrode of the light-emitting element of the dummy pixel is not electrically connected with any pixel circuit.

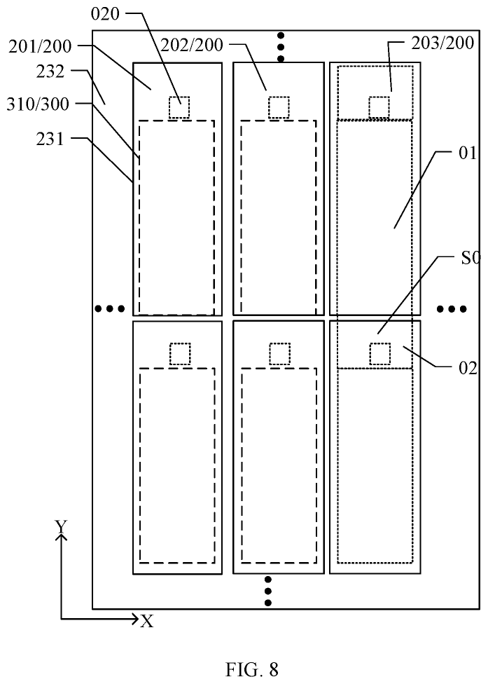

FIG. 8 is a schematic diagram illustrating a planar relationship between a first film layer and a second film layer in a light-emitting functional layer in an example of the display substrate illustrated in FIG. 1 and FIG. 2A. For example, the difference between the example illustrated in FIG. 8 and the example illustrated in FIG. 7 is that the first film layer 231 in the first region 01 is continuous with the first film layer 231 in the second region 02 located on a side of the first region 01 in the first direction and immediately adjacent to the first region 01 (for example, it may also be referred to as interconnected). The second region being located on a side of the first region in the first direction and immediately adjacent to the first region mentioned above means that there is no other first region or second region between the first region and the second region. For example, the first film layer 231 in the first region 01 is continuous with the first film layer 231 in the second region 02 located on a side of the first region 01 in the first direction and immediately adjacent to the first region 01.

For example, the amount of first regions with the continuous first film layer is greater than 10 and less than 10,000. For example, the amount of first regions with the continuous first film layer is greater than 50 and less than 9000. For example, the amount of first regions with the continuous first film layer is greater than 100 and less than 8000. For example, the amount of first regions with the continuous first film layer is greater than 500 and less than 5000. For example, the amount of first regions with the continuous first film layer is greater than 1000 and less than 3000.

For example, the first film layer in the column of the first region arranged in the first direction is continuous with the first film layer in the column of the second region arranged in the first direction. For example, the thickness of the first film layer in the first region and the thickness of the first film layer in the second region are different, such as a first thickness and a second thickness respectively, and the first thickness and the second thickness may be arranged alternately.

For example, as illustrated in FIG. 8, the first film layer 231 located in the sub-region 020 is continuous with the first film layer 231 located in the light-emitting region of the light-emitting element 200, which can make the solvent atmosphere of the ink more uniform, and the flatness of the light-emitting functional layer in the light-emitting region is better.

For example, in the light-emitting elements 200 of different colors, the first film layer 231 in the light-emitting region of the light-emitting element 200 of at least one color is continuous with the first film layer 231 in the second region 02 located on a side of the light-emitting region in the first direction. For example, in the light-emitting element 200 with a thinner first film layer 231, the first film layer 231 in the light-emitting region is continuous with the first film layer 231 in the second region 02 located on a side of the light-emitting region in the first direction, so that the drying speed of the first film layer 231 in the light-emitting region can be slowed down, which is beneficial to improve the uniformity of the first film layer in the light-emitting region. For example, in the light-emitting element 200 with a thicker first film layer 231, the first film layer 231 in the light-emitting region is not continuous with the first film layer 231 in the second region 02 located on a side of the light-emitting region in the first direction.

For example, as illustrated in FIG. 8, at least part of the first regions 01 are provided with sub-regions 020 on both sides in the first direction, and the distance between edges, which are close to each other, of the sub-region and the opening 310 corresponding to the first region 01 is less the dimension of the opening 310 in the first direction and the dimension of the opening 310 in the second direction. For example, in the sub-regions 020 located on both sides of the opening 310 in the first direction, the distance between edges, which are close to each other, of the sub-region 020 that is closer to the opening 310 and the opening 310 is 4-5 microns, and the distance between edges, which are close to each other, of the sub-region 020 that is farther away from the opening 310 and the opening 310 is 10-12 microns; the dimension of the opening 310 in the first direction is 90-100 microns, such as 92-98 microns, such as 94-97 microns; and the dimension of the opening 310 in the second direction is 20-35 microns, such as 22-30 microns, such as 25-28 microns.

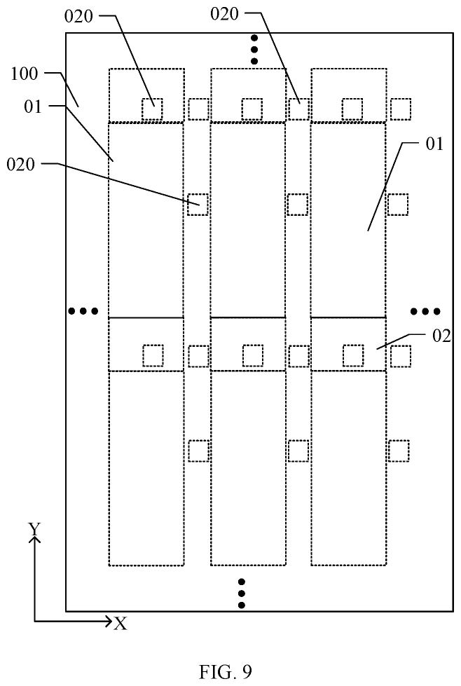

FIG. 9 is a schematic diagram illustrating a planar relationship between a first region and a second region in another example of the display substrate illustrated in FIG. 1 and FIG. 2A. The difference between the display substrate illustrated in FIG. 9 and the display substrate illustrated in FIG. 8 is that at least one of the two sides of at least part of the first regions 01 in the second direction is provided with a sub-region 020. The structures of the first region, the pixel-defining pattern and the light-emitting element in the display substrate illustrated in FIG. 9 may have the same characteristics as the structures of the first region, the pixel-defining pattern and the light-emitting element in the display substrate illustrated in FIG. 8, which will not be repeated here.

For example, the sub-region 020 in the display substrate illustrated in FIG. 9 may include a via hole, or may be a groove provided in the planarization layer. This example does not limit the shape of the sub-region, as long as the maximum thickness of the defining portion in the sub-region in this example is greater than the maximum thickness of at least part of the defining portions between the light-emitting elements of different colors, and the maximum thickness of at least one film layer in the light-emitting functional layer, in the sub-region is not less than that in the first region.

For example, FIG. 9 schematically illustrates that the second region 02 and regions other than the second region 02 include a sub-region 020, for example, the sub-region 020 is also provided between the first sub-defining portion and the third sub-defining portion. For example, the amount of sub-regions 020 provided in regions other than the second region 02 is set according to product requirements, and the sub-regions 020 provided in regions other than the second region 02 are provided in one-to-one correspondence with the second regions 02, or the sub-region 020 is only provided at the corresponding position of the regions other than part of the second regions 02. For example, the sub-region 020 is provided in a region of at least part of the defining portions of the light-emitting elements of different colors. Because the thickness of the defining portion where the sub-region is provided is higher than the height of the defining portion where the sub-region is not provided, the lyophobicity of the surface of the region away from the base substrate is higher, and the sub-region is preferably provided at the position where the ink drops or where the ink is easy to overflow. For example, the position in the middle of the length direction of the light-emitting region is served as the position where ink drops, and the sub-region is located near the middle of the length direction of the light-emitting region. For example, in the defining portion between light-emitting elements of different colors, a portion that intersects with the extension of the defining portion between the light-emitting elements of the same color is served as the position for providing the sub-region. Because the height of the defining portion between the light-emitting elements of different colors is higher than the height of the defining portion between the light-emitting elements of the same color, and the two defining portions are integrated, at the intersection position, because the segment difference between the high and low defining portions is less than the segment difference between the light emitting region and the defining portion located between the light-emitting elements of different colors, the overflow is more likely to occur at the intersection position of the high and low defining portions. By providing the sub-region in the intersection region, the lyophobicity of the surface of the region away from the base substrate is improved, and the overflow is better reduced. For example, in the defining portion located between the light-emitting elements of different colors, a portion connecting two third sub-defining portions is served as the position for providing the sub-region.

For example, as illustrated in FIG. 9, the first film layer (manufactured by the inkjet printing process) in the sub-region 020 located at least one side of the first region 01 in the second direction is continuous with the first film layer located in the first region 01.

For example, the first film layer (manufactured by the inkjet printing process) in the sub-region 020 located at least one side of the first region 01 in the second direction is continuous with the first film layer located in the light-emitting region.

For example, the first regions 01 and the sub-regions 020 are arranged alternately in the second direction, and the first film layer in one row of first regions 01 arranged in the second direction is continuous with the first film layer in one row of sub-regions 020 arranged in the second direction. For example, the first film layer in one row of light-emitting regions arranged in the second direction is continuous with the first film layer in one row of sub-regions 020 arranged in the second direction. It should be noted that, the continuous first film layer in the light-emitting elements of different colors may be a film layer other than the light-emitting layer.

For example, the distances from the sub-region 020 disposed between two adjacent light-emitting regions arranged in the second direction respectively to the two adjacent light-emitting regions are different, and the first film layer in the sub-region 020 is continuous with the first film layer in the light-emitting region of the two adjacent light-emitting regions closest to the sub-region 020.

For example, in the direction perpendicular to the base substrate 100, the sub-region 020 located on a side of the first region 01 in the second direction overlaps with the first electrode of a certain light-emitting element 200, and the first film layer in the sub-region 020 is continuous with the first film layer in the light-emitting region of the light-emitting element 200 having the first electrode overlapping with the sub-region, so as to reduce the drying speed of the first film layer in the light-emitting region.

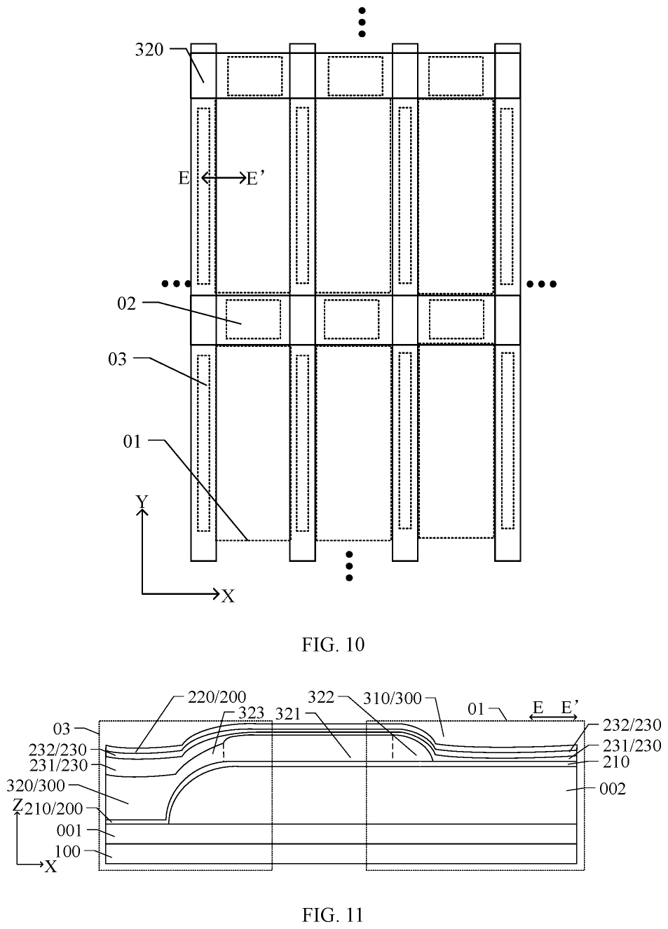

FIG. 10 is a schematic diagram illustrating a planar relationship between a first region and a second region in another example of the display substrate illustrated in FIG. 1 and FIG. 2A, and FIG. 11 is a schematic diagram of a partial cross-sectional structure along a line EE′ illustrated in FIG. 10. The difference between the display substrate illustrated in FIG. 10 and the display substrate illustrated in FIG. 8 is that at least one defining portion 320 extending in the first direction covers a plurality of third regions 03. The structures such as the first region and the light-emitting element in the display substrate illustrated in FIG. 10 may have the same characteristics as the structures such as the first region and the light-emitting element in the display substrate illustrated in FIG. 1-FIG. 8.

As illustrated in FIG. 10 and FIG. 11, the display substrate includes a base substrate 100 and a plurality of light-emitting elements 200 and a pixel-defining pattern 300 located on the base substrate 100. The light-emitting element 200 includes a light-emitting functional layer 230 and a first electrode 210 and a second electrode 220 located on both sides of the light-emitting functional layer 230 along a direction perpendicular to the base substrate 100, the first electrode 210 is located between the light-emitting functional layer 230 and the base substrate 100, and the light-emitting functional layer 230 includes a plurality of film layers.

For example, the light-emitting element 200 is an organic light-emitting diode. For example, the light-emitting element 200 is an organic light-emitting element. For example, the light-emitting element 200 is a sub-pixel on the display substrate.

For example, the plurality of film layers included in the light-emitting functional layer 230 include a hole injection layer (HIL), a hole transport layer (HTL), a light-emitting layer (EL), an electron transport layer (ETL), an electron injection layer (EIL), etc. For example, the hole injection layer and the hole transport layer are located between the light-emitting layer and the first electrode, and the electron transport layer and the electron injection layer are located between the light-emitting layer and the second electrode.

For example, one or more layers of the electron transport layer and the electron injection layer included in the light-emitting functional layer 230 are common film layers of the plurality of light-emitting elements, which may be called common layers.

For example, the first electrode 210 is an anode, and the second electrode 220 is a cathode. For example, the cathode is made of a material with high conductivity and low work function, for example, the cathode is made of a metal material. For example, the anode is formed of a conductive material with a high work function.

For example, the plurality of light-emitting elements 200 include light-emitting elements 200 emitting light of at least two colors.

For example, the plurality of light-emitting elements 200 include a red light-emitting element configured to emit red light, a green light-emitting element configured to emit green light, and a blue light-emitting element configured to emit blue light. For example, the thicknesses of at least one of the electron transport layer and the electron injection layer respectively in the light-emitting elements 200 configured to emit light of different colors are the same, for example, the light-emitting elements 200 emitting light of different colors share at least one of the electron transport layer and the electron injection layer. For example, the thicknesses of the first electrodes 210 of the light-emitting elements 200 configured to emit light of different colors are the same. For example, the thicknesses of the second electrodes 220 of the light-emitting elements 200 configured to emit light of different colors are the same.

For example, the pixel-defining pattern 300 is located on a side of the first electrode 210 away from the base substrate 100, the pixel-defining pattern 300 includes a plurality of openings 310 and a defining portion 320 surrounding the plurality of openings 310, and the plurality of light-emitting element 200 are at least partially located within the plurality of openings 310. For example, the defining portion 320 is a structure defining the openings 310.

For example, the opening 310 of the pixel-defining pattern 300 is configured to define a light-emitting region of the light-emitting element 200. For example, the plurality of light-emitting elements 200 are provided in one-to-one correspondence with the plurality of openings 310. For example, the light-emitting element 200 includes a portion located in the opening 310 and a portion overlapping with the defining portion 320 in the direction perpendicular to the base substrate 100.

For example, at least part of the light-emitting element 200 is located in the opening 310, and the opening 310 is configured to expose the first electrode 210. For example, at least part of the first electrode 210 is located between the defining portion 320 and the base substrate 01. For example, in the case where the light-emitting functional layer 230 is formed in the opening 310 of the pixel-defining pattern 300, the first electrode 210 and the second electrode 220 located on both sides of the light-emitting functional layer 230 can drive the light-emitting functional layer 230 in the opening 310 of the pixel-defining pattern 300 to emit light. For example, the above-mentioned light-emitting region may refer to an effective light-emitting region of the light-emitting element, and the shape of the light-emitting region refers to a two-dimensional shape. For example, the shape of the light-emitting region is identical to the shape of the opening 310 of the pixel-defining pattern 300.

The display substrate illustrated in FIG. 10 and FIG. 11 is distributed with a plurality of first regions 01, a plurality of second regions 02, and a plurality of third regions 03, the first region 01 corresponds to the opening 310, and at least part of the second region 02 and at least part of the third region 03 are covered by the defining portion 320.

For example, the first region 01 of each light-emitting element 200 corresponds to one second region 02 and one third region 03. For example, the first region 01 includes at least part of the light-emitting region of the light-emitting element 200. For example, the second region 02 and the third region 03 include a portion of the non-light-emitting region of the display substrate.

In the display substrate illustrated in FIG. 10 and FIG. 11, at least one film layer in the light-emitting functional layer 230 is located in at least one first region 01, at least one second region 02 and at least one third region 03. The region covered by the defining portion 320 in the second region 02 includes a sub-region 020, the maximum thickness of the defining portion 320 in the sub-region 020 is greater than the maximum thickness of at least part of the defining portion 320 between the light-emitting elements 200 of different colors, the maximum thickness of at least one film layer in the light-emitting functional layer 230, in the sub-region 020, is not less than that in the first region 01. At least one defining portion 320 extending in the first direction (the Y direction as illustrated in FIG. 10 and FIG. 11) covers a plurality of third regions 03, and the maximum thickness of at least one film layer in the light-emitting functional layer 230 in at least partial region of the third region 03 is greater than the maximum thickness of at least one film layer in the light-emitting functional layer 230 in the first region 01. For example, portions, of at least one film layer in the light-emitting functional layer 230, located in at least one first region 01, located in at least one second region 02, and located in at least one third region 03 are formed to be an integral structure.

In the display substrate provided by the embodiments of the present disclosure, the thickness of at least one film layer in the light-emitting functional layer in the sub-region covered by the defining portion is provided to be greater, which is beneficial to balance the solvent atmosphere during inkjet printing, and improves the uniformity of the light-emitting functional layer formed by inkjet printing.

For example, the maximum thickness of the defining portion 320 in at least partial region of the third region 03 is greater than the maximum thickness of at least part of the defining portion 320 located between the light-emitting elements 200 of different colors. For example, the ratio of the maximum thickness of the defining portion 320 in at least partial region of the third region 03 to the maximum thickness of the defining portion 320 in the sub-region 020 is 0.8-1.2. For example, the ratio of the maximum thickness of the defining portion 320 in at least partial region of the third region 03 to the maximum thickness of the defining portion 320 in the sub-region 020 is 0.9-1.1. For example, the maximum thickness of the defining portion 320 in at least partial region of the third region 03 is substantially equal to the maximum thickness of the defining portion 320 in the sub-region 020.

For example, the average thickness of at least one film layer in the light-emitting functional layer 230 in the sub-region 020 is not less than that in the first region 01. For example, the average thickness of at least one film layer in the light-emitting functional layer 230 in at least partial region of the third region 03 is not less than that in the first region 01.

For example, in at least one of the sub-region 020 and at least partial region of the third region 03, the defining portion 320 is located between the light-emitting functional layer 230 and the first electrode 210 to prevent the light-emitting functional layer 230 from contacting the first electrode 210. For example, the maximum thickness of the defining portion 320 in the sub-region 020 is greater than the thickness of at least part of the defining portion 320 located between light-emitting elements 200 of different colors, and the maximum thickness of at least one film layer of the light-emitting functional layer 230 in the sub-region 020 is greater than that in the first region 01. For example, the maximum thickness of the defining portion 320 of at least partial region of the third region 03 is greater than the thickness of at least part of the defining portion 320 between the light-emitting elements 200 of different colors, and the maximum thickness of at least one film layer in the light-emitting functional layer 230 of at least partial region of the third region 03 is greater than that in the first region 01.

In the display substrate provided by the embodiments of the present disclosure, in the case where the thickness of at least one film layer of the light-emitting functional layer in at least one of the sub-region and the third region is provided to be greater, the thickness of the defining portion in at least one of the sub-region and the third region is also provided to be greater, which is beneficial to increase the distance between the light-emitting functional layer in at least one of the sub-region and the third region and the first electrode, so that it difficult for the display substrate to generate crosstalk and unnecessary light.

For example, at least one film layer in the above-mentioned light-emitting functional layer 230 is a film layer manufactured by the inkjet printing process, providing the thickness of the light-emitting functional layer, in at least one of the sub-region and the third region, covered by the defining portion to be not less than the thickness of the corresponding light-emitting functional layer in the first region is beneficial to improve the flatness of the light-emitting functional layer in the opening of the pixel-defining pattern, thereby reducing the probability of color shift when the light-emitting element is displayed, and further improving the display effect of the display device including the display substrate.

For example, the thickness of the light-emitting functional layer of the red light-emitting element is greater than the thickness of the light-emitting functional layer of the green light-emitting element, and the thickness of the light-emitting functional layer of the red light-emitting element is greater than the thickness of the light-emitting functional layer of the blue light-emitting element.

For example, the thickness of the light-emitting functional layer of the red light-emitting element is greater than the thickness of the light-emitting functional layer of the green light-emitting element, and the thickness of the light-emitting functional layer of the green light-emitting element is greater than the thickness of the light-emitting functional layer of the blue light-emitting element.

For example, the thicknesses of at least one of the light-emitting layer, the hole injection layer and the hole transport layer in the light-emitting functional layers of the light-emitting elements of different colors are different. For example, the thicknesses of the light-emitting layers in the light-emitting functional layers of light-emitting elements of different colors are all different, the thicknesses of the hole injection layers in the light-emitting functional layers of light-emitting elements of different colors are all different, the thicknesses of the hole transport layers in the light-emitting functional layers of light-emitting elements of different colors are all different.

For example, different thicknesses of the light-emitting functional layers of the light-emitting elements of different colors can be achieved by two printing methods. For example, the ink concentration of at least one layer in the light-emitting functional layer of the red light-emitting element is set to the maximum, or the ink concentrations of at least one layer in the light-emitting functional layer of different light-emitting elements are similar, but the ink volume of the at least one layer of the red light-emitting element is maximum.

For example, the red light-emitting element is provided with the longest lifetime among the light-emitting elements of different colors. For example, the areas of light-emitting regions of the light-emitting elements of different colors are different. For example, the area of the light-emitting region of the red light-emitting element is smaller than the area of the light-emitting region of the blue light-emitting element, and the area of the light-emitting region of the red light-emitting element is smaller than the area of the light-emitting region of the green light-emitting element. For example, the amounts of the light-emitting elements of different colors are different. For example, the amount of blue light-emitting elements and the amount of green light-emitting elements are both greater than the amount of red light-emitting elements.

For example, the maximum thicknesses of the defining portions 320 respectively located between two adjacent light-emitting elements 200 of different colors are approximately equal, for example, the ratio of the maximum thicknesses of two defining portions between light-emitting elements of different colors is in a range of 0.7-1.5, further, is 0.8-1.2. For example, the maximum thickness of the defining portion 320 between the red light-emitting element 201 and the green light-emitting element 202, the maximum thickness of the defining portion 320 between the red light-emitting element 201 and the blue light-emitting element 203, and the maximum thickness of the defining portion 320 between the green light-emitting element 202 and the blue light-emitting element 203 are all (0.7-1.5)*h0. For example, the maximum thickness of the defining portion 320 between the red light-emitting element 201 and the green light-emitting element 202, the maximum thickness of the defining portion 320 between the red light-emitting element 201 and the blue light-emitting element 203, and the maximum thickness of the defining portion 320 between the green light-emitting element 202 and the blue light-emitting element 203 are all approximately h0±0.2 microns. For example, the maximum thickness of the defining portion 320 between the red light-emitting element 201 and the green light-emitting element 202, the maximum thickness of the defining portion 320 between the red light-emitting element 201 and the blue light-emitting element 203, and the maximum thickness of the defining portion 320 between the green light-emitting element 202 and the blue light-emitting element 203 are all approximately h0±0.1 microns.

For example, the light-emitting functional layer is formed on the defining portion between light-emitting elements of the same color. For example, the light-emitting functional layer is formed on the defining portion between light-emitting elements of different colors. For example, the total thickness of the light-emitting functional layer on the defining portion between the light-emitting elements of the same color is greater than the total thickness of the light-emitting functional layer on the defining portion between the light-emitting elements of different colors. For example, the total amount of light-emitting functional layers on the defining portion between the light-emitting elements of the same color is greater than the total amount of light-emitting functional layers on the defining portion between the light-emitting elements of different colors.

For example, the maximum thickness of the light-emitting functional layer 230 in the first region 01 is m1, the maximum thickness of the light-emitting functional layer 230 on the defining portion 320 between the light-emitting elements 200 of different colors is m0, and the maximum thickness of the light-emitting functional layer 230 in at least one of the sub-region 020 and the third region 03 is m2, then h0, h2, m0 and m2 satisfy the relationship: h2/h0<m2/m0.

For example, the maximum thickness m0 of the light-emitting functional layer 230 on the defining portion 320 located between the light-emitting elements 200 of different colors, the maximum thickness m1 of the light-emitting functional layer 230 in the first region 01, and the maximum thickness m2 of the light-emitting functional layer 230 in at least one of the sub-region 020 and the third region 03 satisfy the relationship: m0<m1≤m2.

In the display substrate provided by the embodiments of the present disclosure, the amount of light-emitting functional layers provided in at least one of the sub-region and the third region is greater, for example, the amount of ink stored in at least one of the sub-region and the third region is greater, which can continuously balance the drying speed of the ink. The thickness of the defining portion in at least one of the sub-region and the third region is not provided too thick, which can prevent the unevenness of the defining portion in the sub-region from affecting the ink leveling, and can reduce the color shift caused by the change of the light-exiting direction caused by the unevenness.

For example, as illustrated in FIG. 10 and FIG. 11, the defining portion 320 located between adjacent openings 310 includes a first sub-defining portion 321 and a second sub-defining portion 322 located on at least one side of the first sub-defining portion 321, a surface of a side of the second sub-defining portion 322 away from the base substrate 100 includes a slope, and the average thickness of the first sub-defining portion 321 is greater than the average thickness of the second sub-defining portion 322. For example, the defining portion 320 located between adjacent light-emitting elements 200 of different colors includes a first sub-defining portion 321 and a second sub-defining portion 322. For example, the maximum thickness of the first sub-defining portion 321 is h0. For example, the maximum height of the first sub-defining portion 321 relative to a surface of a corresponding anode close to the base substrate or a surface of a flat portion of a planarization layer is h0. For example, the maximum height of the first sub-defining portion 321 relative to a surface of the corresponding anode away from the base substrate or an exposed anode surface in the opening of the pixel-defining pattern is h0.

For example, as illustrated in FIG. 10 and FIG. 11, a surface on a side of the first sub-defining portion 321 away from the base substrate 100 includes a surface approximately parallel to the base substrate 100. For example, in some embodiments, the surface on the side of the first sub-defining portion 321 away from the base substrate 100 includes a surface that is relatively high in the middle and relatively low on both sides close to the opening of the pixel-defining pattern.

For example, the slope angle of the slope formed on the surface of the side of the second sub-defining portion 322 away from the base substrate 100 is 30-70 degrees. For example, the slope angle of the slope formed on the surface of the side of the second sub-defining portion 322 away from the base substrate 100 is 40-60 degrees. For example, the slope angle of the slope formed on the surface of the side of the second sub-defining portion 322 away from the base substrate 100 is 45-50 degrees. For example, the slope angle of the slope formed on the surface of the side of the second sub-defining portion 322 away from the base substrate 100 is 42 degrees. For example, the slope angle of the slope formed on the surface of the side of the second sub-defining portion 322 away from the base substrate 100 is an angle between a part of the surface of the second sub-defining portion close to the base substrate and the plane of the base substrate.

For example, as illustrated in FIG. 10 and FIG. 11, the maximum thickness of the light-emitting function layer 230 on the second sub-defining portion 322 is m3, then the maximum thickness m0 of the light-emitting function layer 230 on the first sub-defining portion 321 located between the light-emitting elements 200 of different colors, the maximum thickness m1 of the light-emitting functional layer 230 in the first region 01, the maximum thickness m2 of the light-emitting functional layer 230 in at least one of the sub-region 020 and the third region 03, and the maximum thickness m3 of the light-emitting functional layer 230 on the second sub-defining portion 322 satisfy the relationship: m0<m3<m1≤m2.

For example, in the light-emitting elements of the same color, the maximum thickness m2 of a portion of the light-emitting functional layer located in at least one of the sub-region 020 and the third region 03, the maximum thickness m1 of a portion of the light-emitting functional layer located in the first region 01, the maximum thickness m0 of a portion of the light-emitting functional layer located on the first sub-defining portion 321, and the maximum thickness m3 of a portion of the light-emitting functional layer located on the second sub-defining portion 322 satisfy the above relationship: m0<m3<m1≤m2.

For example, the second sub-defining portion includes a defining portion between the light-emitting elements emitting light of the same color. For example, the first sub-defining portion includes a defining portion between the light-emitting elements emitting light of different colors.

For example, as illustrated in FIG. 10 and FIG. 11, the maximum thickness of the second sub-defining portion 322 is h3, and the maximum thickness h0 of the first sub-defining portion 321 located between light-emitting elements 200 of different colors, the maximum thickness h2 of the defining portion 320 in at least one of the sub-region 020 and the third region 03, and the maximum thickness h3 of the second sub-defining portion 322 satisfy the relationship: h3<h0≤h2.

For example, the maximum thickness h0 of the first sub-defining portion 321 located between the light-emitting elements 200 of different colors and the maximum thickness h2 of the defining portion 320 in at least one of the sub-region 020 and the third region 03 satisfy the relationship: 2<h2/h0<4. For example, the maximum thickness h0 of the first sub-defining portion 321 located between the light-emitting elements 200 of different colors and the maximum thickness h2 of the defining portion 320 in at least one of the sub-region 020 and the third region 03 satisfy the relationship: 1<h2/h0<4.5.

For example, the maximum thickness h0 of the first sub-defining portion 321 located between the light-emitting elements 200 of different colors and the maximum thickness h2 of the defining portion 320 in the sub-region 020 satisfy the relationship: 2<h2/h0<4.

For example, the maximum thickness m1 of the light-emitting functional layer 230 in the first region 01 and the maximum thickness m2 of the light-emitting functional layer 230 in at least one of the sub-region 020 and the third region 03 satisfy the relationship: 1≤m2/m1≤3. For example, the maximum thickness m1 of the light-emitting functional layer 230 in the first region 01 and the maximum thickness m2 of the light-emitting functional layer 230 in at least one of the sub-region 020 and the third region 03 satisfy the relationship: 2≤m2/m1≤2.5.

For example, as illustrated in FIG. 10 and FIG. 11, a contact angle of at least one film layer of the light-emitting functional layer 230 on the first sub-defining portion 321 is greater than that on the second sub-defining portion 322. For example, the contact angle of at least one film layer of the light-emitting functional layer 230 on the first sub-defining portion 321 is greater than 90 degrees, and the contact angle of the at least one film layer of the light-emitting functional layer 230 on the second sub-defining portion 322 is less than 90 degrees. For example, the contact angle of at least one film layer of the light-emitting functional layer 230 on the second sub-defining portion 322 is less than 80 degrees. For example, the contact angle of at least one film layer of the light-emitting functional layer 230 on the second sub-defining portion 322 is less than 70 degrees. For example, the contact angle of at least one film layer of the light-emitting functional layer 230 on the second sub-defining portion 322 is less than 60 degrees. For example, the contact angle of at least one film layer of the light-emitting functional layer 230 on the second sub-defining portion 322 is less than 50 degrees. For example, the contact angle of at least one film layer of the light-emitting functional layer 230 on the second sub-defining portion 322 is less than 45 degrees. For example, the contact angle of at least one film layer of the light-emitting functional layer 230 on the second sub-defining portion 322 is less than 30 degrees.

For example, a contact angle of at least one film layer of the light-emitting functional layer 230 on the defining portion 320 immediately adjacent to the periphery of the first region 01 is greater than that on the defining portion 320 immediately adjacent to the periphery of at least one of the sub-region 020 and the third region 03. For example, the defining portion 320 located at the periphery of the first region 01 is a lyophobic region for the at least one film layer of the light-emitting functional layer 230, and the defining portion 320 located at the periphery of at least one of the sub-region 020 and the third region 03 is a lyophilic region for the at least one film layer of the light-emitting functional layer 230. By adjusting the contact angle of at least one film layer of the light-emitting functional layer on defining portions at different positions is beneficial to the diffusion of at least one film layer (such as ink) of the light-emitting functional layer and balance the evaporation rate of the ink.

For example, as illustrated in FIG. 10 and FIG. 11, the defining portion 320 covering the second region 02 further includes a third sub-defining portion 323 surrounding at least one of the sub-region 020 and the third region 03, and a surface of a side of the third sub-defining portion 323 away from the base substrate 100 includes a slope. For example, a slope angle of a portion, close to a side of the base substrate, of a slope on a surface of a side of the third sub-defining portion 323 away from the base substrate 100 is less than a slope angle of a portion, close to a side of the base substrate, of a slope formed on a surface of a side of the second sub-defining portion 322 away from the base substrate 100. For example, the range of the slope angle of the portion, close to a side of the base substrate, of the slope on the surface of the side of the third sub-defining portion 323 away from the base substrate 100 includes 5°-70°. For example, the range of the slope angle of the portion, close to a side of the base substrate, of the slope on the surface of the side of the third sub-defining portion 323 away from the base substrate 100 includes 5°-35°. For example, the range of the slope angle of the portion, close to a side of the base substrate, of the slope on the surface of the side of the third sub-defining portion 323 away from the base substrate 100 includes 10°-30°. For example, the range of the slope angle of the portion, close to a side of the base substrate, of the slope on the surface of the side of the third sub-defining portion 323 away from the base substrate 100 includes 15°-45°. For example, the range of the slope angle of the portion, close to a side of the base substrate, of the slope on the surface of the side of the third sub-defining portion 323 away from the base substrate 100 includes 40°-60°. For example, the range of the slope angle of the portion, close to a side of the base substrate, of the slope on the surface of the side of the third sub-defining portion 323 away from the base substrate 100 includes 45°-50°.

For example, the slope angle of the slope formed on the surface of the side of the third sub-defining portion 323 away from the base substrate 100 is 30-70 degrees. For example, the slope angle of the slope formed on the surface of the side of the third sub-defining portion 323 away from the base substrate 100 is 40-60 degrees. For example, the slope angle of the slope formed on the surface of the side of the third sub-defining portion 323 away from the base substrate 100 is 45-50 degrees.

For example, the thickness of the third sub-defining portion 323 is different from the thickness of the first sub-defining portion 321, the junction of the third sub-defining portion 323 and the first sub-defining portion 321 is a smooth surface in a shape of “˜”, the height difference of surfaces of the third sub-defining portion 323 and the first sub-defining portion 321 is in a range of 0.1-1 micron, and the first sub-defining portion and the third sub-defining portion can be formed by patterning the same material by using a half-tone mask process. For example, the thickness of the third sub-defining portion 323 is different from the thickness of the first sub-defining portion 321, and the height difference of surfaces of the third sub-defining portion 323 and the first sub-defining portion 321 is in a range of 0.2-0.9 microns. For example, the thickness of the third sub-defining portion 323 is different from the thickness of the first sub-defining portion 321, and the height difference of surfaces of the third sub-defining portion 323 and the first sub-defining portion 321 is in a range of 0.3-0.8 microns. For example, the thickness of the third sub-defining portion 323 is different from the thickness of the first sub-defining portion 321, and the height difference of surfaces of the third sub-defining portion 323 and the first sub-defining portion 321 is in a range of 0.4-0.9 microns. For example, the thickness of the third sub-defining portion 323 is different from the thickness of the first sub-defining portion 321, and the height difference of surfaces of the third sub-defining portion 323 and the first sub-defining portion 321 is in a range of 0.3-0.75 microns.

For example, as illustrated in FIG. 10 and FIG. 11, the average thickness of the light-emitting functional layer 230 on the second sub-defining portion 322 and the average thickness of the light-emitting functional layer 230 on the third sub-defining portion 323 are both less than the average thickness of the light-emitting functional layer 230 in at least one of the sub-region 020 and the third region 03. For example, the average thicknesses of the light-emitting functional layers 230 in regions of the second region 02 except for the sub-region 020 are all less than the average thickness of the light-emitting functional layer 230 in the sub-region 020.

For example, as illustrated in FIG. 10 and FIG. 11, the average thickness of the second sub-defining portion 322 and the average thickness of the third sub-defining portion 323 are both less than the average thickness of the defining portion 320 in at least one of the sub-region 020 and the third region 03.

For example, as illustrated in FIG. 10-FIG. 11, a planarization layer 002 is provided on the base substrate 100. For example, the material of the planarization layer 002 includes one or a combination of resin, acrylic, polyethylene terephthalate, polyimide, polyamide, polycarbonate, epoxy resin, and the like.

For example, other film layer 001 is further provided between the planarization layer 002 and the base substrate 100. For example, the film layer 001 includes one or more layers of a light-shielding layer, a gate insulating layer, an interlayer insulating layer, a signal line layer, and the like. For example, the display substrate further includes a pixel circuit (such as including thin film transistors, storage capacitors, electrodes and other structures), and the first electrode 210 of the light-emitting element 200 is electrically connected to the pixel circuit. For example, the display substrate includes a semiconductor layer, a gate insulating layer, a first conductive layer, an interlayer insulating layer, a second conductive layer, and the like. For example, the active semiconductor layer of each thin film transistor and the corresponding connection electrode structure or capacitor electrode are formed in the semiconductor layer, and the connection electrode structure or capacitor electrode are formed by doping and conducting the semiconductor layer, or formed to be an integral structure with the active semiconductor layer. For example, the gate insulating layer is formed on a side of the semiconductor layer away from the base substrate, and via holes are formed in the gate insulating layer for connecting the semiconductor layer to the first conductive layer or the second conductive layer. For example, the first conductive layer is formed on a side of the gate insulating layer away from the base substrate, and the first conductive layer is formed with a gate electrode of each thin film transistor, some signal lines, and some connection electrodes or capacitor electrodes. The some signal lines are configured to transmit one or more of the gate signal, data signal, reset signal, reset control signal, etc.; the connection electrodes are configured to connect the interlayer patterns, or connect the second conductive layer upwards and the semiconductor layer downwards; and the capacitor electrodes are configured to form capacitors with the pattern of the semiconductor layer and/or the pattern of the second conductive layer. For example, the interlayer insulating layer is formed on a side of the first conductive layer away from the base substrate, and the interlayer insulating layer is formed with via holes for connecting patterns in the semiconductor layer, the first conductive layer, and the second conductive layer. For example, the second conductive layer is formed on a side of the interlayer insulating layer away from the base substrate, and the second conductive layer is formed with source and drain electrodes of each thin film transistor, some signal lines, and some connection electrodes or capacitor electrodes. The some signal lines are configured to transmit one or more of the gate signal, data signal, reset signal, reset control signal, etc.; and the connection electrodes are configured to connect the interlayer patterns, such as connect the electrode of the light-emitting element upwards and the pattern of the first conductive layer or the pattern of the semiconductor layer downwards. For example, the display substrate further includes a third conductive layer, the third conductive layer is located between the second conductive layer and the light-emitting element, the third conductive layer is configured to connect the second conductive layer and the light-emitting element, and the pattern of the third conductive layer is also connected with the pattern of the first conductive layer and the pattern of the semiconductor layer. By providing one more layer of conductive layer, not only can the resistance be reduced in parallel with the second conductive layer or the first conductive layer, but also the flatness can be further improved through a first planarization layer provided between the second conductive layer and the third conductive layer and a second planarization layer provided between the third conductive layer and the light-emitting element, thereby further improving the process stability of the light-emitting element, reducing the color shift and improving the display quality.

For example, the portion of the planarization layer 002 corresponding to the sub-region 020 in the second region 02 includes a recessed portion, that is, the surface of the planarization layer includes a portion, closer to the base substrate, of a surface that is away from the substrate than the main body of the planarization layer. In some embodiments, part of the electrodes may partially overlap with the recessed portion of the planarization layer (or the portion corresponding to the sub-region). For example, the anode of the light-emitting element located on a side of the planarization layer away from the base substrate partially overlaps with the recessed portion of the planarization layer, or the anode completely covers the recessed portion of the planarization layer or covers more than 80% of the recessed portion of the planarization layer.

For example, in some embodiments, the display substrate includes a plurality of planarization layers, the surface of at least one planarization layer away from the base substrate is provided with a recessed portion, and the orthographic projection of at least one electrode or wire on the base substrate overlaps with the orthographic projection of the recessed portion of the planarization layer on the base substrate. In some embodiments, the first planarization layer is provided between the second conductive layer and the third conductive layer, the second planarization layer is provided between the third conductive layer and the light-emitting element, the surface of the second planarization layer away from the base substrate is provided with a recessed portion, and the orthographic projection of the anode of the light-emitting element on the base substrate at least partially overlaps with the orthographic projection of the recessed portion on the base substrate. In some embodiments, the first planarization layer is provided between the second conductive layer and the third conductive layer, the second planarization layer is provided between the third conductive layer and the light-emitting element, the surface of the second planarization layer away from the base substrate is provided with a recessed portion, and the orthographic projection of the anode of the light-emitting element on the base substrate completely covers the orthographic projection of at least one recessed portion on the base substrate. In some embodiments, the first planarization layer is provided between the second conductive layer and the third conductive layer, the second planarization layer is provided between the third conductive layer and the light-emitting element, the surface of the first planarization layer away from the base substrate is provided with a recessed portion, and the orthographic projection of the pattern of the third conductive layer on the base substrate at least partially overlaps with the orthographic projection of the recessed portion on the base substrate. In some embodiments, the first planarization layer is provided between the second conductive layer and the third conductive layer, the second planarization layer is provided between the third conductive layer and the light-emitting element, the surface of the first planarization layer away from the base substrate is provided with a recessed portion, and the orthographic projection of the pattern of the third conductive layer on the base substrate completely covers the orthographic projection of at least one recessed portion on the base substrate. In some embodiments, the recessed portion of the first planarization layer causes the corresponding position of the second planarization layer to also be provided with a recessed portion, so that the corresponding defining portion is also provided with a recessed portion, which can also be served as a sub-region for storing ink.

In some embodiments, a surface, away from the base substrate, of a portion of the defining portion corresponding to the sub-region is provided with a recessed portion. For example, at least one electrode or wire overlaps with the recessed portion of the defining portion. The recessed portion provided in at least part of the defining portion can be used to store ink and balance the solvent atmosphere during drying.

In some embodiments, because the sub-region is located in the non-light-emitting region, for the convenience of the layout of the pixel circuit or to save more space, the pattern of the anode or the third conductive layer overlapping with the recessed portion (or the overlapping portion of the defining portion, or the corresponding portion of the sub-region) of the planarization layer (or the first planarization layer, or the second planarization layer) can also be used as a connection structure; that is, the recessed portion of the planarization layer (or the first planarization layer, or the second planarization layer) or the recessed portion of the defining portion can be formed as a through hole (as illustrated in FIG. 3B), and the pattern of the anode or the third conductive layer located in this region is connected with the conductive pattern of another layer (such as the first conductive layer, the second conductive layer, the anode layer or the cathode layer) through the through hole. In some embodiments, the portion of the planarization layer corresponding to the sub-region is formed with a through hole, and the dimension of the through hole on the side away from the base substrate is greater than that on the side close to the base substrate. In some embodiments, the portion of the planarization layer corresponding to the sub-region includes a non-through hole, and the dimension of the non-through hole on the side away from the base substrate is greater than that on the side close to the base substrate. In some embodiments, the portion of the defining portion corresponding to the sub-region is formed with a through hole, and the dimension of the through hole on the side away from the base substrate is greater than the dimension on the side close to the base substrate. In some embodiments, the portion of the defining portion corresponding to the sub-region includes a non-through hole, and the dimension of the non-through hole on the side away from the base substrate is greater than that on the side close to the base substrate.

The dimension and area of the sub-region away from the base substrate are provided to be larger which can better match the evaporation rate of the ink; usually, when the ink starts to evaporate, the concentration of the solvent atmosphere is greater, and the portion outside the light-emitting region needs more solvent evaporation to balance the solvent atmosphere everywhere; as the drying progresses, the concentration of the solvent atmosphere becomes less and less, and the required solvent in the sub-region is also less and less, therefore, the dimension of the sub-region also changes with the progress of the evaporative drying process, and the closer to the substrate, the dimension gradually decreases.

For example, the orthographic projection of the sub-region 020 on the base substrate 100 falls within the orthographic projection of the first electrode 210 on the base substrate 100. For example, the orthographic projection of the via hole in the planarization layer 002 on the base substrate 100 falls within the orthographic projection of the first electrode 210 on the base substrate 100.

For example, the orthographic projection of the sub-region 020 on the base substrate 100 overlaps with a part of the orthographic projection of the first electrode 210 on the base substrate 100. For example, the orthographic projection of the via hole in the planarization layer 002 on the base substrate 100 overlaps with the orthographic projection of the first electrode 210 on the base substrate 100.

For example, at least partial region of the third region 03 include via holes or grooves provided in the planarization layer 002.

For example, as illustrated in FIG. 11, the surface of the light-emitting functional layer 230 in at least one of the sub-region 020 and at least partial region of the third region 03 away from the base substrate 100 is flush with the surface of the light-emitting functional layer 230 in the first region 01 away from the base substrate 100.

For example, as illustrated in FIG. 11, at least partial region of the third region 03 overlap with the first electrode 210 of the light-emitting element 200. For example, the orthographic projection of at least partial region of the third region 03 on the base substrate 100 completely falls within the orthographic projection of the first electrode 210 on the base substrate 100. For example, along the direction perpendicular to the base substrate 100, a portion of at least partial region of the third region 03 overlaps with the first electrode 210, and the other portion of at least partial region of the third region 03 does not overlap with the first electrode 210.

For example, as illustrated in FIG. 11, the amount of a plurality of film layers included in the light-emitting functional layer 230 located in the first region 01, the amount of a plurality of film layers included in the light-emitting functional layer 230 located in the second region 02, and the amount of a plurality of film layers included in the light-emitting functional layer 230 located in the third region 03 are identical to each other. For example, for at least one light-emitting element, the area of a sub-region nearest to the light-emitting element is smaller than the area of a first region corresponding to the light-emitting element. For example, the first region corresponding to the light-emitting element refers to at least one first region covered by the light-emitting element.

For example, the light-emitting functional layers 230 located in the first region 01, the second region 02 and the third region 03 each includes a hole injection layer (HIL), a hole transport layer (HTL), a light-emitting layer (EL), an electron transport layer (ETL), an electron injection layer (EIL) and other film layers. For example, the light-emitting functional layer 230 further includes a hole blocking layer (HBL), an electron blocking layer (EBL), a microcavity regulating layer, an exciton regulating layer or other functional film layers.

For example, the area of one sub-region 020 is smaller than the area of one first region 01. For example, the ratio of the area of one sub-region 020 (through hole or non-through hole or groove) to the area of one first region 01 is 0.01-1. For example, the ratio of the area of one sub-region 020 (through hole or non-through hole or groove) to the area of one first region 01 is 0.02-0.9. For example, the ratio of the area of one sub-region 020 (through hole or non-through hole or groove) to the area of one first region 01 is 0.05-0.8. For example, the ratio of the area of one sub-region 020 (through hole or non-through hole or groove) to the area of one first region 01 is 0.1-0.7. For example, the ratio of the area of one sub-region 020 (through hole or non-through hole or groove) to the area of one first region 01 is 0.15-0.6. By setting the area ratio between the sub-region and the first region, the magnitude relationship between the ink evaporation rate of the sub-region and the ink evaporation rate of the first region can be determined, and a more suitable ink volume ratio can be obtained by combining parameters such as distance and depth, so as to better balance the ink evaporation rate, but not waste more ink and reduce costs.

For example, the amount of the plurality of film layers included in the light-emitting functional layer 230 located in the first region 01 is greater than the amount of the plurality of film layers included in the light-emitting functional layer 230 in at least partial region where the thickness of the defining portion 320 located between the light-emitting elements 200 emitting light of different colors is maximum. For example, the position where the thickness of the defining portion 320 is maximum is provided with the first sub-defining portion 321, and the amount of layers of the light-emitting functional layer 230 on at least partial region of the first sub-defining portion 321 is at least one layer less than the amount of layers of the light-emitting functional layer 230 in the opening 310. For example, the amount of layers of the light-emitting functional layer 230 in the second region 02 is greater than the amount of layers of the light-emitting functional layer 230 on at least partial region of the first sub-defining portion 321. For example, the amount of layers of the light-emitting functional layer 230 on at least partial region of the first sub-defining portion 321 is greater than the amount of layers of the light-emitting functional layer 230 on at least partial region of the second sub-defining portion 322. For example, the amount of layers of the light-emitting functional layer 230 on at least partial region of the second sub-defining portion 322 is identical to the amount of layers of the light-emitting functional layer 230 in the first region (or the opening 310).

For example, as illustrated in FIG. 10 and FIG. 11, the light-emitting functional layer 230 at least includes a first film layer 231 and a second film layer 232, the maximum thickness of the first film layer 231 in at least one of the sub-region 020 and the third region 03 is greater than the maximum thickness of the first film layer 231 in the first region 01, and the maximum thickness of the second film layer 232 in at least one of the sub-region 020 and the third region 03 is equal to the maximum thickness of the second film layer 232 in the first region 01. For example, the first film layer and the second film layer are manufactured by the same process, for example, are both manufactured by the printing process or the evaporation process. For example, the first film layer and the second film layer are manufactured by different processes, for example, one is manufactured by the printing process, and the other is manufactured by the evaporation process.

For example, the first film layer 231 is any one of film layers such as the hole injection layer, the hole transport layer, the light-emitting layer, etc., and the first film layer 231 is a film layer manufactured by the inkjet printing process. For example, the second film layer 232 is any one of the film layers such as the electron transport layer, the electron injection layer, etc., and the second film layer 232 is a film layer formed by the evaporation process. The film layer formed by the evaporation process has the same thickness in the light-emitting functional layers in the sub-region, the third region and the first region, and the film layer formed by the inkjet printing process has different thicknesses in the sub-region, the third region and the first region. By providing the thickness of the ink formed by the inkjet printing process in at least one of the sub-region and the third region to be greater than the thickness of the ink formed by the inkjet printing process in the first region is beneficial to better balance the solvent atmosphere, and the efficiency is higher.

For example, as illustrated in FIG. 10 and FIG. 11, the first film layer 231 is located between the second film layer 232 and the base substrate 100.

For example, as illustrated in FIG. 7, the area of the first film layer 231 is smaller than the area of the second film layer 232. For example, the second film layer 232 is a common film layer shared by a plurality of light-emitting elements 200, the first film layer 231 is a film layer shared by the light-emitting elements 200 emitting light of the same color, or a film layer independently included in each light-emitting element 200, and the first film layers 231 of the light-emitting elements 200 emitting light of different colors are each not a common film layer. For example, light-emitting elements 200, in a column, arranged along the Y direction are light-emitting elements that exit light of the same color, and light-emitting elements 200, in a column, arranged along the Y direction can share the first film layer 231. However, two adjacent light-emitting elements arranged along the X direction 200 are light-emitting elements 200 that exit light of different colors, and the first film layers 231 of the two adjacent light-emitting elements 200 are independent film layers. For example, the first film layers 231 of two adjacent light-emitting elements 200 arranged along the X direction may be arranged at intervals, or stacked, or contiguous with each other, and the embodiments of the present disclosure are not limited thereto.

For example, the orthographic projection of the first film layer 231 on the base substrate 100 falls within the orthographic projection of the second film layer 232 on the base substrate 100. For example, the boundary of the first film layer 231 is at least partially located within the range of the second film layer 232.

For example, the first film layer 231 at least covers two adjacent first regions 01 arranged in the first direction and the defining portion between the two first regions 01. For example, the first film layer 231 covers the gap between the openings 310 corresponding to two adjacent light-emitting elements 200 arranged in the first direction that emit light of the same color. For example, the first film layer 231 of one light-emitting element 200 covers a portion of the gap between the openings 310 corresponding to two light-emitting elements 200 arranged in the second direction that emit light of different colors. For example, the first film layer 231 of one light-emitting element 200 covers all the gap between the openings 310 corresponding to two light-emitting elements 200 arranged in the second direction that emit light of different colors.

For example, the second film layer 232 covers two adjacent first regions 01 arranged along any direction of the first direction and the second direction and a complete circle of spacing surrounding any one of the two adjacent first regions 01.

For example, the amount of first regions 01 covered by at least one layer of the first film layer 231 arranged continuously is less than the amount of first regions 01 covered by at least one layer of the second film layer 232 arranged continuously. For example, the layer of first film layer 231 arranged continuously only covers the first regions 01 corresponding to the light-emitting elements 200 that emit light of the same color, and the layer of second film layer 232 arranged continuously can not only cover the first regions 01 corresponding to the light-emitting elements 200 that emit light of the same color, but also cover the first regions 01 corresponding to the light-emitting elements 200 that emit light of different colors.

For example, the average thicknesses of the first film layers 231 of two adjacent light-emitting elements 200 arranged in the second direction are different. For example, the average thicknesses of the first film layers 231 in the first regions 01 corresponding to two adjacent light-emitting elements 200 arranged in the second direction are different. For example, the average thicknesses of the first film layers 231 in the sub-regions 020 corresponding to two adjacent light-emitting elements 200 arranged in the second direction are different. For example, the maximum thicknesses of the first film layers 231 in the third regions 03 corresponding to two adjacent light-emitting elements 200 arranged in the second direction are different.

For example, in two adjacent light-emitting elements 200 arranged in the second direction, the ratio, of the average thickness of the first film layer 231 located in the sub-region 020 to the average thickness of the first film layer 231 located in the first region 01, of one light-emitting element 200 is different from that of the other one light-emitting element 200. For example, in two adjacent light-emitting elements 200 arranged in the second direction, the ratio, of the maximum thickness of the first film layer 231 located in the third regions 03 to the maximum thickness of the first film layer 231 located in the first region 01, of one light-emitting element 200 is different from that of the other one light-emitting element 200.

For example, in two adjacent light-emitting elements 200 arranged in the second direction, the average thickness of the light-emitting functional layer of one light-emitting element 200 in the sub-region 020 is different from that of the other one light-emitting element 200, the average thickness of the light-emitting functional layer of one light-emitting element 200 in the first region 01 is different from that of the other one light-emitting element 200. For example, in two adjacent light-emitting elements 200 arranged in the second direction, the maximum thickness of the light-emitting functional layer, in the sub-region 020, of one light-emitting element 200 is different from that of the other light-emitting element 200, and the maximum thickness of the light-emitting functional layer, in the first region 01, of one light-emitting element 200 is different from that of the other light-emitting element 200.

For example, the average thicknesses of the first film layers 231 in the light-emitting elements 200 of different colors are different, and the average thicknesses of the second film layers 232 in the light-emitting elements 200 of different colors are different.

For example, the average thickness of the first film layer 231 of the red light-emitting element is greater than the average thickness of the first film layer 231 of the green light-emitting element, and the average thickness of the first film layer 231 of the green light-emitting element is greater than the average thickness of the first film layer 231 of the blue light-emitting element.

For example, the thickness of the entire light-emitting functional layer of the red light-emitting element 201 is greater than the thickness of the entire light-emitting functional layer of the green light-emitting element 202, and the thickness of the entire light-emitting functional layer of the green light-emitting element 202 is greater than the thickness of the entire light-emitting functional layer of the blue light-emitting element 203.

For example, in two adjacent light-emitting elements 200 arranged in the second direction, the average thicknesses of the light-emitting functional layers 230 in the first regions 01 respectively corresponding to different light-emitting elements 200 are different.

For example, in two adjacent light-emitting elements 200 arranged in the second direction, the average thicknesses of the light-emitting functional layers 230 in the second regions 02 respectively corresponding to different light-emitting elements 200 are different. For example, in two adjacent light-emitting elements 200 arranged in the second direction, the ratio, of the maximum thickness of the light-emitting functional layer 230 in the second region 02 to the maximum thickness of the light-emitting functional layer 230 in the first region 01, of one light-emitting element 200 is different from that of the other one light-emitting element 200. For example, in two adjacent light-emitting elements 200 arranged in the second direction, the maximum thicknesses of the light-emitting functional layers 230 in the third regions 03 respectively corresponding to different light-emitting elements 200 are different. For example, in two adjacent light-emitting elements 200 arranged in the second direction, the ratio, of the maximum thickness of the light-emitting functional layer 230 in third regions 03 to the maximum thickness of the light-emitting functional layer 230 in the first region 01, of one light-emitting element 200 is different from that of the other one light-emitting element 200.

For example, at least one of the first film layer 231 in the second region 02 and the first film layer 231 in the third region 03 is continuous with the first film layer 231 in the first region 01. In the embodiments of the present disclosure, the film layers located in different regions are continuous means that the film layers located in different regions are a continuous film layer. For example, the first film layer 231 in the first region 01 and at least one of the first film layer 231 in the second region 02 and the first film layer 231 in the third region 03 are continuous. For example, the continuous film layer is provided with substantially the same thickness, or provided with different thicknesses. For example, the thicknesses of different positions of the continuous film layer are different, for example, the thickness of the light-emitting functional layer in at least part of the second region is less than the thickness of the light-emitting functional layer in at least a central portion of the first region.

For example, in the light-emitting element 200 that emits light of one color, the first film layer 231 in the first region 01 is continuous with the first film layer 231 in the second region 02 located on both sides of the first region 01 in the first direction and immediately adjacent to the first region 01. The second region being located on both sides of the first region in the first direction and immediately adjacent to the first region mentioned above means that there is no other first region or second region between the first region and the second region. The above mentioned being continuous with means a continuous layer.

For example, as illustrated in FIG. 10 and FIG. 11, in the light-emitting element 200 that emits light of one color, the first film layer 231 in the first region 01 and the first film layer 231 in the third region 03, which is located on both sides of the first region 01 in the first direction and immediately adjacent to the first region 01, are a continuous film layer

For example, as illustrated in FIG. 10 and FIG. 11, the first film layer 231 in a column of the first region 01 arranged in the first direction is continuous with the first film layer 231 in a column of the second region 02 arranged in the first direction. For example, the first film layer 231 in the third region 03 arranged in a column along the first direction is a continuous film layer.

For example, the first film layer 231 located in at least one of the sub-region 020 and the third region 03 is continuous with the first film layer 231 located in the light-emitting region of the light-emitting element 200, which can make the solvent atmosphere of the ink more uniform, and the flatness of the light-emitting functional layer in the light-emitting region is better.

For example, the first film layer 231 in a column of the first region 01 arranged in the first direction is continuous. For example, the first film layer 231 in a column of the second region 02 arranged in the first direction is continuous. For example, the first film layer 231 in the light-emitting region is continuous with the first film layer 231 in the sub-regions 020 located on both sides of the light-emitting region in the first direction.

For example, in the light-emitting elements 200 of different colors, the first film layer 231 in the light-emitting region of the light-emitting element 200 of at least one color is continuous with the first film layer 231 in the second regions 02 located on both sides of the light-emitting region in the first direction. For example, in the light-emitting element 200 with a thinner first film layer 231, the first film layer 231 in the light-emitting region is continuous with the first film layer 231 in the second regions 02 located on both sides of the light-emitting region in the first direction, so that the drying speed of the first film layer 231 in the light-emitting region can be slowed down, which is beneficial to improve the uniformity of the first film layer in the light-emitting region. For example, in the light-emitting element 200 with a thicker first film layer 231, the first film layer 231 in the light-emitting region is not continuous with the first film layer 231 in the second regions 02 located on both sides of the light-emitting region in the first direction.

For example, in the light-emitting elements 200 of different colors, the first film layer 231 in the light-emitting region of the light-emitting element 200 of at least one color is continuous with the first film layer 231 in the third regions 03 located on both sides of the light-emitting region in the second direction. For example, in the light-emitting element 200 with a thinner first film layer 231, the first film layer 231 in the light-emitting region is continuous with the first film layer 231 in the third regions 03 located on both sides of the light-emitting region in the second direction, so that the drying speed of the first film layer 231 in the light-emitting region can be slowed down, which is beneficial to improve the uniformity of the first film layer in the light-emitting region. For example, in the light-emitting element 200 with a thicker first film layer 231, the first film layer 231 in the light-emitting region is not continuous with the first film layer 231 in the third region 03 located on both sides of the light-emitting region in the second direction.

For example, the first film layer 231 in the light-emitting regions of two adjacent light-emitting elements 200 arranged in the first direction is continuous.

For example, at least one film layer in the light-emitting functional layer 230 includes a first portion located in the first region 01, a second portion located in the second region 02, a third portion connecting the first portion and the second portion, and a fourth portion located in the third region 03, the thicknesses of the first portion, the second portion and the third portion are all different, and the thickness of the second portion may be identical to the thickness of the fourth portion. For example, the above-mentioned at least one film layer is a film layer formed by the inkjet printing process. For example, the above-mentioned at least one film layer is any one of the hole injection layer, the hole transport layer and the light-emitting layer. For example, in the above-mentioned at least one film layer, the maximum thickness of at least one of the second portion and the fourth portion is greater than the maximum thickness of the first portion, and the maximum thickness of the first portion is greater than the maximum thickness of the third portion. For example, the thicknesses of the first portions of the at least one film layer in different light-emitting elements are identical to or different from each other. For example, the thicknesses of the second portions of the at least one film layer in different light-emitting elements are identical to or different from each other. For example, the thicknesses of the third portions of the at least one film layer in different light-emitting elements are identical to or different from each other.

For example, the total thickness of the plurality of film layers, included in the light-emitting functional layer 230, overlapping with the defining portion 320 is different from the total thickness of the plurality of film layers, included in the light-emitting functional layer 230, in the opening 310. For example, the total thickness of the plurality of film layers, included in the light-emitting functional layer 230, overlapping with the defining portion 320 is less than the total thickness of the plurality of film layers, included in the light-emitting functional layer 230, in the opening 310.

For example, the first film layer 231 in the third region 03, which is located on at least one side of the first region 01 and immediately adjacent to the first region 01 in the second direction, is continuous with the first film layer 231 in the first region 01. For example, the second film layer 232 in the third region 03, which is located on at least one side of the first region 01 and immediately adjacent to the first region 01 in the second direction, is continuous with the second film layer 232 in the first region 01. For example, the first film layer 231 in the third region 03, which is located on at least one side of the light-emitting region and immediately adjacent to the light-emitting region in the second direction, is continuous with the first film layer 231 in the light-emitting region. For example, the second film layer 232 in the third region 03, which is located on at least one side of the light-emitting region and immediately adjacent to the light-emitting region in the second direction, is continuous with the second film layer 232 in the light-emitting region.

For example, as illustrated in FIG. 10 and FIG. 11, the maximum thickness of the first film layer 231 in at least partial region of the third region 03 is greater than the maximum thickness of the first film layer 231 in the light-emitting functional layer 230 in the first region 01.

For example, as illustrated in FIG. 10 and FIG. 11, the first regions 01 and the third region 03 are arranged alternately in the second direction, and the light-emitting functional layer 230 in the third region 03, which is located on at least one side of the first region 01 and immediately adjacent to the first region 01 in the second direction, is continuous with the light-emitting functional layer 230 in the first region 01. The third region being located on at least one side of the first region and immediately adjacent to the first region mentioned above means that there is no other first region or third region between the first region and the third region. In the embodiments of the present disclosure, the light-emitting functional layer in the third region is continuous with the light-emitting functional layer in the first region, and the thickness of the light-emitting functional layer in the third region is greater than the thickness of the light-emitting functional layer in the first region, which can reduce the drying rate of the light-emitting functional layer in the first region, balance the solvent atmosphere when the film layer is formed by inkjet printing, and improve the uniformity of the light-emitting functional layer formed in the first region by inkjet printing.

For example, as illustrated in FIG. 10 and FIG. 11, the first film layer 231 in two adjacent third regions 03 arranged in the first direction is continuous. For example, the second film layer 232 in two adjacent third regions 03 arranged in the first direction is continuous. For example, the light-emitting functional layers 230 in a column of third regions 03 arranged in the first direction are all continuous.

For example, as illustrated in FIG. 10 and FIG. 11, the distances between two third regions 03 located on both sides of the first region 01 in the second direction and the first region 01 are different, and the light-emitting functional layer 230 in the third region 03 that is closer to the first region 01 is continuous with the light-emitting functional layer 230 in the first region 01. For example, the film layer formed in the light-emitting functional layer 230 in the third region 03 that is closer to the first region 01 by inkjet printing process is continuous with the corresponding film layer in the light-emitting functional layer 230 in the first region 01.

For example, as illustrated in FIG. 10 and FIG. 11, the light-emitting functional layer 230 in the third region 03 is continuous with the light-emitting functional layer 230 in the first region 01 corresponding to the light-emitting element 200 including the first electrode 210 overlapping with the third region 03. For example, the first film layer 231 in the third region 03 is continuous with the first film layer 231 in the first region 01 corresponding to the light-emitting element 200 including the first electrode 210 overlapping with the third region 03. For example, the second film layer 232 in the third region 03 is continuous with the second film layer 232 in the first region 01 corresponding to the light-emitting element 200 including the first electrode 210 overlapping with the third region 03.

For example, light-emitting functional layers 230 that are continuous with the light-emitting functional layer 230 in the same light-emitting region and are respectively located in different second regions 02 are continuous.

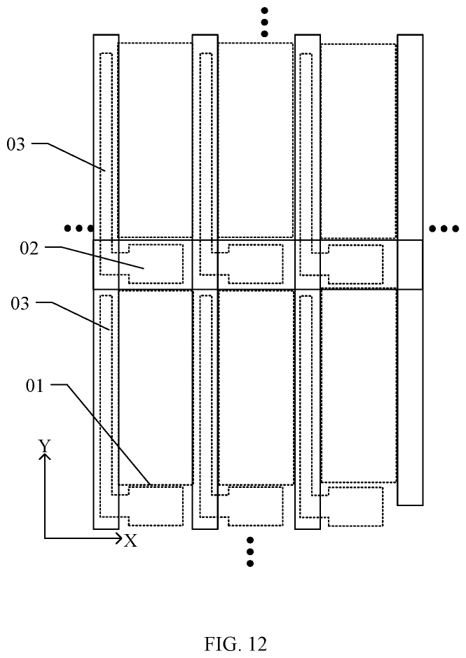

FIG. 12 is a schematic diagram illustrating a planar relationship between a first region and a second region in another example of the display substrate illustrated in FIG. 1 and FIG. 2A, and the difference between the display substrate illustrated in FIG. 12 and the display substrate illustrated in FIG. 11 is that, in the display substrate provided by the present example, the light-emitting functional layer located in the third region 03 is continuous with the light-emitting functional layer located in the second region 02. The structures such as the first region, the pixel-defining pattern and the light-emitting element in the display substrate illustrated in FIG. 12 may have the same characteristics as the structures such as the first region, the pixel-defining pattern and the light-emitting element in the display substrate illustrated in FIG. 10, which will not be repeated here.

For example, as illustrated in FIG. 12, the light-emitting functional layer 230 in the second region 02 being continuous with the light-emitting functional layer in the first region 01 is continuous with the light-emitting functional layer 230 in the third region 03 being continuous with the light-emitting functional layer 230 in the first region 01. For example, the light-emitting functional layers of the first region 01, the second region 02 and the third region 03 corresponding to the same light-emitting element are all continuous.

For example, as illustrated in FIG. 12, the light-emitting functional layers of the first region 01, the second region 02 and the third region 03 corresponding to one light-emitting element are all continuous, and light-emitting functional layers of two first regions 01, two second regions 02 and two third regions 03 corresponding to two adjacent light-emitting elements arranged in the first direction are all not continuous.

For example, as illustrated in FIG. 12, the light-emitting functional layers of a column of first regions 01, a column of second regions 02 and a column of third regions 03 corresponding to a column of light-emitting elements arranged in the first direction are all continuous.

For example, as illustrated in FIG. 12, the second region 02 and the third region 03 in which the light-emitting functional layers are continuous to each other are formed into an integral structure.

For example, as illustrated in FIG. 12, the second region 02 and the third region 03 corresponding to one light-emitting element are formed into an integral structure, and the two second regions 02 and the two third regions 03 corresponding to two adjacent light-emitting elements arranged in the first direction are not formed into an integral structure.

For example, as illustrated in FIG. 12, a column of second regions 02 and a column of third regions 03 corresponding to a column of light-emitting elements arranged in the first direction are formed into an integral structure.

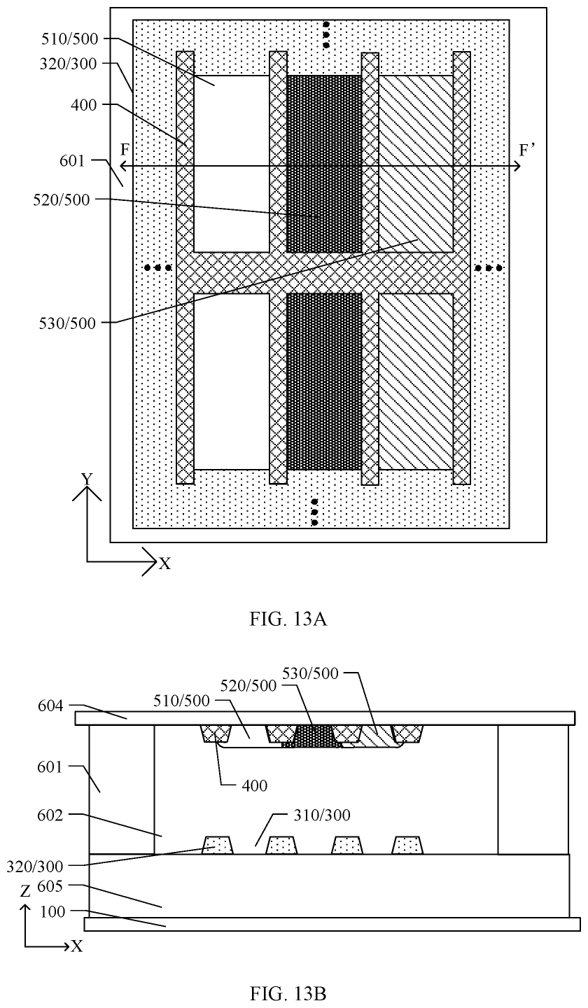

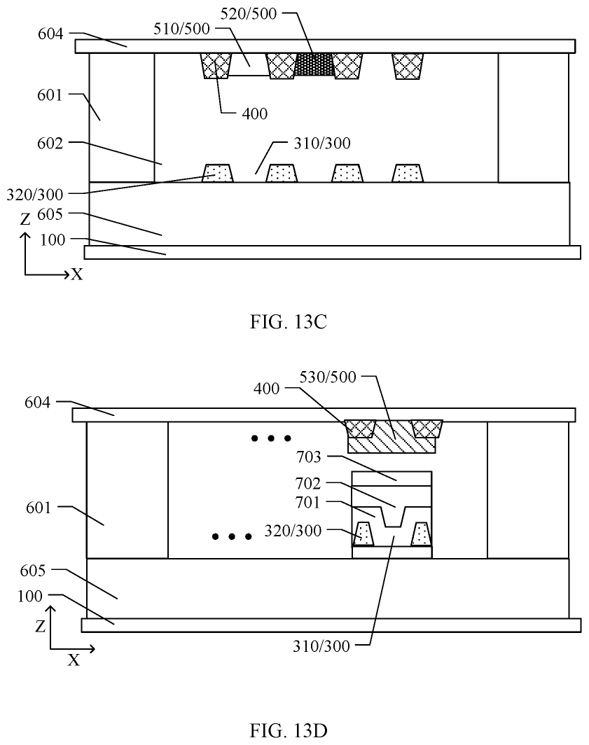

FIG. 13A is a schematic diagram of a partial planar structure of a color filter layer and a black matrix in the display substrate illustrated in FIG. 1, FIG. 13B is a schematic diagram of a partial cross-sectional structure along a line FF′ illustrated in FIG. 13A, and FIG. 13C and FIG. 13D are schematic cross-sectional views of different examples of the display substrate illustrated in FIG. 13A.

For example, as illustrated in FIG. 1-FIG. 8 and FIG. 13A-FIG. 3D, the display substrate further includes a color filter layer 500 and a black matrix 400, and the black matrix 400 and the color filter layer 500 are located on a side of the pixel-defining pattern 300 away from the base substrate 100. For example, the orthographic projection of the black matrix on the base substrate 100 at least partially overlaps with the orthographic projection of the defining portion 320 on the base substrate 100. For example, the orthographic projection of the black matrix on the base substrate 100 falls within the orthographic projection of the defining portion 320 on the base substrate 100. For example, along the extending direction of a center connection line of adjacent openings 310, the width of at least part of the black matrix 400 is smaller than the width of the defining portion 320. For example, the width of the black matrix 400 extending in the first direction is smaller than the width of the defining portion extending in the first direction. For example, the width of the black matrix 400 extending in the second direction is smaller than the width of the defining portion extending in the second direction. For example, the width of the black matrix 400 extending in the first direction is smaller than the width of the defining portion extending in the first direction, and the width of the black matrix 400 extending in the second direction is smaller than the width of the defining portion extending in the second direction. For example, the difference between the width of the black matrix 400 extending in the first direction and the width of the defining portion extending in the first direction is different from the difference between the width of the black matrix 400 extending in the second direction and the width of the defining portion extending in the second direction different. By setting the width of the black matrix, the light can be converged to the black matrix through an optical structure, thereby reducing the abnormal light emitted by a non-light-emitting region. For example, at least part of the orthographic projection of an opaque portion of the first electrode or the second electrode on the base substrate overlaps with the orthographic projection of the black matrix on the base substrate, and the abnormal light in the non-light-emitting region is reflected to the black matrix region through the reflection of the first electrode or the second electrode to reduce the emission. For example, the surface of the first electrode or the second electrode corresponding to the color filter layer or the light-emitting region away from the base substrate is provided with a portion recessed toward the base substrate, so that the light can be emitted through the color filter layer as much as possible through the convergence of the first electrode or the second electrode to improve the light-exiting efficiency.

For example, the orthographic projection of the black matrix 400 on the base substrate covers the orthographic projection of the sub-region 020 on the base substrate. For example, the black matrix 400 at least covers the center of the sub-region 020, so that upon unnecessary light being emitted, the light can be blocked by the black matrix.

For example, the width of the black matrix 400 in the row direction is different from the width of the black matrix 400 in the column direction; for example, the width of the black matrix between the light-emitting elements of the same color is larger, and the width of the black matrix between the light-emitting elements of different colors is narrower; for example, a strip-shaped portion of the black matrix extending along the column direction has a wider width in the row direction, and a strip-shaped portion of the black matrix extending along the row direction has a narrower width in the column direction. For example, the widths of a plurality of strip-shaped portions of the black matrix extending in the column direction and arranged in the row direction are different, and the widths of a plurality of strip-shaped portions of the black matrix extending in the row direction and arranged in the column direction are different. The dimension of the black matrix can be adjusted according to parameters such as the aperture ratio, light-emitting characteristics, and color characteristics of each light-emitting element.

For example, the shape of the opening in the color filter layer is the same as or different from the shape of the opening in the pixel-defining pattern. For example, at least part of the opening in the pixel-defining pattern does not overlap with the opening in the color filter layer, and at least part of the opening in the color filter layer does not overlap with at least part of the opening in the pixel-defining pattern, and the openings of the color filter layer and the pixel-defining pattern cooperate to finally obtain the shape and dimension of the light-emitting region.

For example, the opening in the pixel-defining pattern may also have the same shape and the same area as the opening in the color filter layer, or the opening in the pixel-defining pattern and the opening in the color filter layer may have the same shape and different areas; or the opening in the pixel-defining pattern and the opening in the color filter layer may have different shapes and the same area; or the opening in the pixel-defining pattern and the opening in the color filter layer may have different shapes and different areas.

For example, the area of the opening in the pixel-defining pattern accounts for more than 50% of the area of the opening in the corresponding color filter layer. For example, the area of the opening in the pixel-defining pattern accounts for more than 60% of the area of the opening in the corresponding color filter layer. For example, the area of the opening in the pixel-defining pattern accounts for more than 70% of the area of the opening in the corresponding color filter layer. For example, the area of the opening in the pixel-defining pattern accounts for more than 80% of the area of the opening in the corresponding color filter layer. For example, the area of the opening in the pixel-defining pattern accounts for more than 90% of the area of the opening in the corresponding color filter layer. For example, the area of the opening in the pixel-defining pattern accounts for 100% of the area of the opening in the corresponding color filter layer.

For example, the area of an overlapping portion of the opening in the color filter layer and the opening in the pixel-defining pattern accounts for 100% of the area of the opening in the pixel-defining pattern. For example, the area of the overlapping portion of the opening in the color filter layer and the opening in the pixel-defining pattern accounts for 90% of the area of the opening in the pixel-defining pattern. For example, the area of the overlapping portion of the opening in the color filter layer and the opening in the pixel-defining pattern accounts for 80% of the area of the opening in the pixel-defining pattern. For example, the area of the overlapping portion of the opening in the color filter layer and the opening in the pixel-defining pattern accounts for 70% of the area of the opening in the pixel-defining pattern. For example, the area of the overlapping portion of the opening in the color filter layer and the opening in the pixel-defining pattern accounts for 60% of the area of the opening in the pixel-defining pattern. For example, the area of the overlapping portion of the opening in the color filter layer and the opening in the pixel-defining pattern accounts for 50% of the area of the opening in the pixel-defining pattern.

For example, the shape of the opening in the color filter layer and the shape of the opening in the pixel-defining pattern include a combination of any two of circle, rectangle, ellipse, parallelogram, trapezoid, hexagon, octagon, triangle, pentagon, long strip or irregular patterns (such as patterns with at least part of the sides being straight and part of the sides being curved, or patterns with at least part of the straight sides being concave or convex).

For example, as illustrated in FIG. 13A, in the black matrix 400 and the defining portion 320 between two adjacent openings 310 arranged in the first direction, the ratio of the dimension of the black matrix 400 in the first direction to the dimension of the defining portion 320 in the first direction is 0.2-0.8; or, the ratio of the dimension of the black matrix 400 in the first direction to the dimension of the defining portion 320 in the first direction is 0.3-0.7; or, the ratio of the dimension of the black matrix 400 in the first direction to the dimension of the defining portion 320 in the first direction is 0.4-0.6; or, the ratio of the dimension of the black matrix 400 in the first direction to the dimension of the defining portion 320 in the first direction is 0.45-0.55.

For example, as illustrated in FIG. 13A, in the black matrix 400 and the defining portion 320 between two adjacent openings 310 arranged in the second direction, the ratio of the dimension of the black matrix 400 in the second direction to the dimension of the defining portion 320 in the second direction is 0.2-0.8; or, the ratio of the dimension of the black matrix 400 in the second direction to the dimension of the defining portion 320 in the second direction is 0.3-0.7; or, the ratio of the dimension of the black matrix 400 in the second direction to the dimension of the defining portion 320 in the second direction is 0.4-0.6; or, the ratio of the dimension of the black matrix 400 in the second direction to the dimension of the defining portion 320 in the second direction is 0.5.

For example, as illustrated in FIG. 13A, the direction indicated by the arrow in the Y direction is upward, and when inkjet printing is performed from top to bottom to form the light-emitting functional layer of the light-emitting element, the black matrix 400 can be closer to the upper row of light-emitting elements, that is, the black matrix can be closer to the light-emitting elements printed first.

For example, the Y direction may be the horizontal direction when the picture is actually displayed, or the vertical direction when the picture is actually displayed, which is not limited in the present disclosure.

For example, the areas of the light-emitting regions corresponding to the light-emitting elements of respective colors are at least partially different. For example, the dimension ratio of the light-emitting regions respectively corresponding to the first color light-emitting element and the second color light-emitting element in the Y direction is less than the dimension ratio of the light-emitting regions respectively corresponding to the first color light-emitting element and the second color light-emitting element in the X direction. For example, the light-emitting regions corresponding to the first color light-emitting element and the second color light-emitting element have substantially the same dimension in the Y direction, and the light-emitting regions corresponding to the first color light-emitting element and the second color light-emitting element have different dimensions in the X direction.

For example, as illustrated in FIG. 13B, the color filter layer 500 includes a first color filter layer 510, a second color filter layer 520 and a third color filter layer 530. For example, the first color filter layer 510, the second color filter layer 520 and the third color filter layer 530 are a red color filter layer 510, a green color filter layer 520 and a blue color filter layer 530, respectively. For example, the red color filter layer 510 is provided corresponding to the red light-emitting element, the green color filter layer 520 is provided corresponding to the green light-emitting element, and the blue color filter layer 530 is provided corresponding to the blue light-emitting element.

For example, the thicknesses of the color filter layers of different colors may be identical to or different from each other. For example, the thickness of the color filter layer corresponding to one light-emitting element is uneven, for example, the thickness of the color filter layer corresponding to a central region of the light-emitting element is thinner, and the thickness of the color filter layer corresponding to an edge region of the light-emitting element is thicker; or for example, the thickness of the color filter layer corresponding to a central region of the light-emitting element is thicker, and the thickness of the color filter layer corresponding to an edge region of the light-emitting element is thinner. Setting the thickness of the color filter layer can play a certain role in light enhancement or uniformity.

For example, as illustrated in FIG. 13B, the structure 605 located between the defining portion 320 and the base substrate 100 includes structures such as the first electrode of the above-mentioned light-emitting element, a pixel circuit, and the like. For example, the thickness of the pixel circuit in the direction perpendicular to the base substrate is 5-6.5 microns, such as 5.2-6 microns, such as 6.2-6.4 microns. For example, the thickness of the first electrode is 0.1-0.2 microns, such as 0.13-0.14 microns. For example, the thickness of the defining portion is 1-2 microns, such as 1.2-1.8 microns.

For example, as illustrated in FIG. 13B, the structure 602 provided between the defining portion 320 and the black matrix 400 includes at least one thin film encapsulation layer. For example, in the case where the structure 602 is provided with one thin film encapsulation layer, the thickness of the thin film encapsulation layer is 4-6 microns, such as 5 microns. For example, the structure 602 is provided with three thin film encapsulation layers, and the thickness of a layer farthest away from the base substrate of the three thin film encapsulation layers is 0.3-0.7 microns, such as 0.5-0.6 microns; the thickness of a layer closest to the base substrate of the three thin film encapsulation layers is 0.5-1.5 microns, such as 1 micron; the thickness of the middle film layer of the three thin film encapsulation layers is 5.5-7 microns, such as 6-6.5 microns. For example, the three thin film encapsulation layers are an inorganic layer, an organic layer and an inorganic layer in sequence.

For example, as illustrated in FIG. 13B, the structure 602 provided between the defining portion 320 and the black matrix 400 further includes a filler. For example, the thickness of the filler is 5-8 microns, such as 6-7 microns.

For example, as illustrated in FIG. 13B, the thickness of the entire color filter layer 500 and the thickness of the entire black matrix 400 are 2-3 microns, such as 2.2-2.4 microns.

For example, as illustrated in FIG. 13B, the display substrate further includes a blocking portion 601 surrounding the display region where the plurality of light-emitting elements are located. The thickness of the blocking portion 601 may be 15-20 microns, such as 17-19 microns.

For example, as illustrated in FIG. 13B, the display substrate is further provided with another substrate 604, and the black matrix 400 and the color filter layer 500 are provided on the substrate 604. For example, the distance between the base substrate 100 and the substrate 604 is 20-26 microns, such as 24-25 microns, such as 20-22 microns.

For example, in an example of the embodiments of the present disclosure, the black matrix 400 is formed by stacking a plurality of color filter layers. For example, the black matrix 400 is formed by stacking a red color filter layer and a green color filter layer, or formed by stacking a green color filter layer and a blue color filter layer, or formed by stacking a red color filter layer and a blue color filter layer; then along the direction perpendicular to the base substrate 100, the thickness of the black matrix 400 is greater than the thickness of at least one of the red color filter layer 510, the green color filter layer 520 and the blue color filter layer 530.

For example, the display substrate in a different example illustrated in FIG. 13C may not be provided with a blue color filter layer, or may be provided with a quantum dot material corresponding to blue light. For example, all light-emitting elements emit blue light, and the red color film layer 510 and the green color film layer 520 can use different quantum dot materials to convert blue light into red light and green light respectively.

For example, three thin film encapsulation layers 701, 702, and 703 are illustrated in the display substrate illustrated in FIG. 13D. Of course, the embodiments of the present disclosure are not limited thereto, and the display substrate may also include only one thin film encapsulation layer. For example, a filler is provided between the thin film encapsulation layer, and the black matrix and the color filter layer.

For example, the region surrounded by the blocking portion 601 is entirely filled by the filler, and the filled region includes a display region and a periphery. For example, the thin film encapsulation layer also covers the plurality of light-emitting elements as a whole. For example, a portion of the thin film encapsulation layer corresponding to the light-emitting region of the light-emitting element fills the opening of the pixel-defining pattern, and the thickness of this portion of the thin film encapsulation layer is thicker.

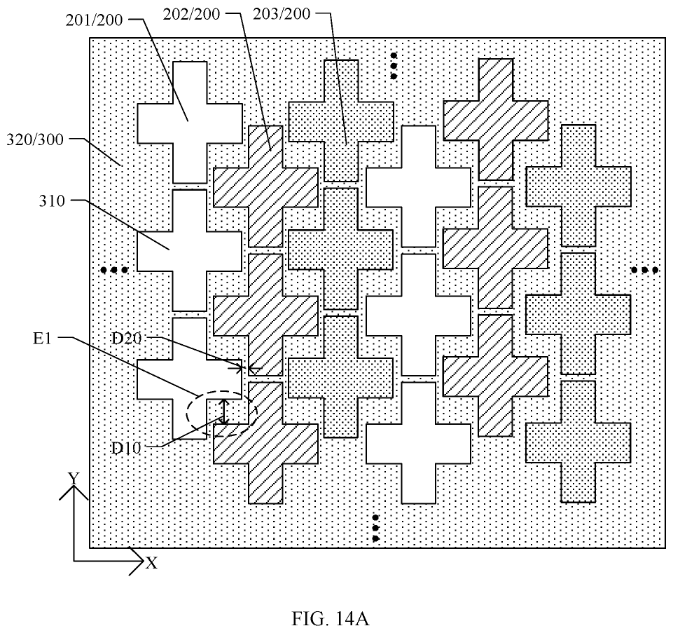

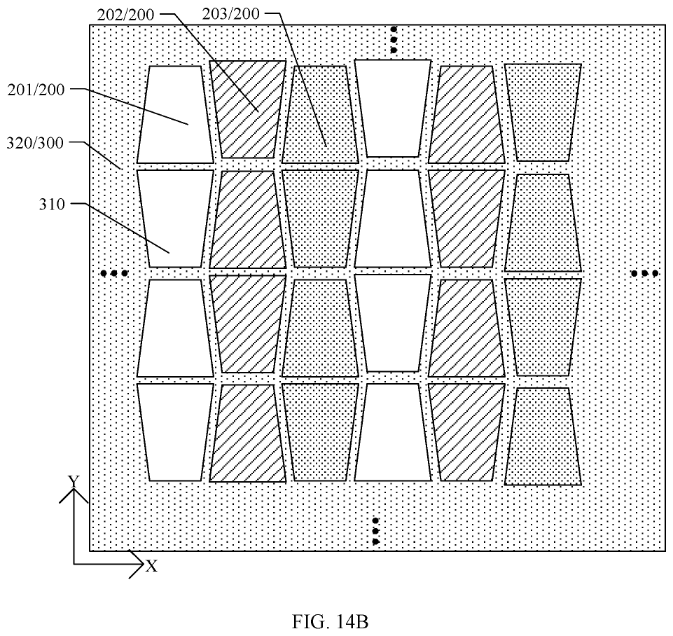

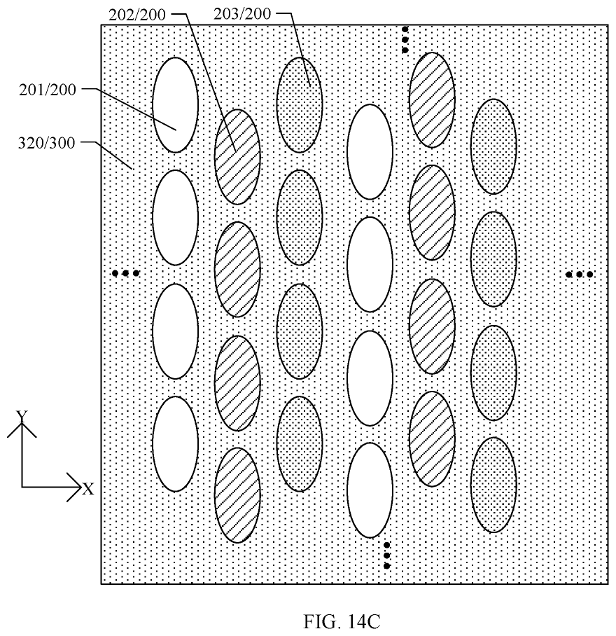

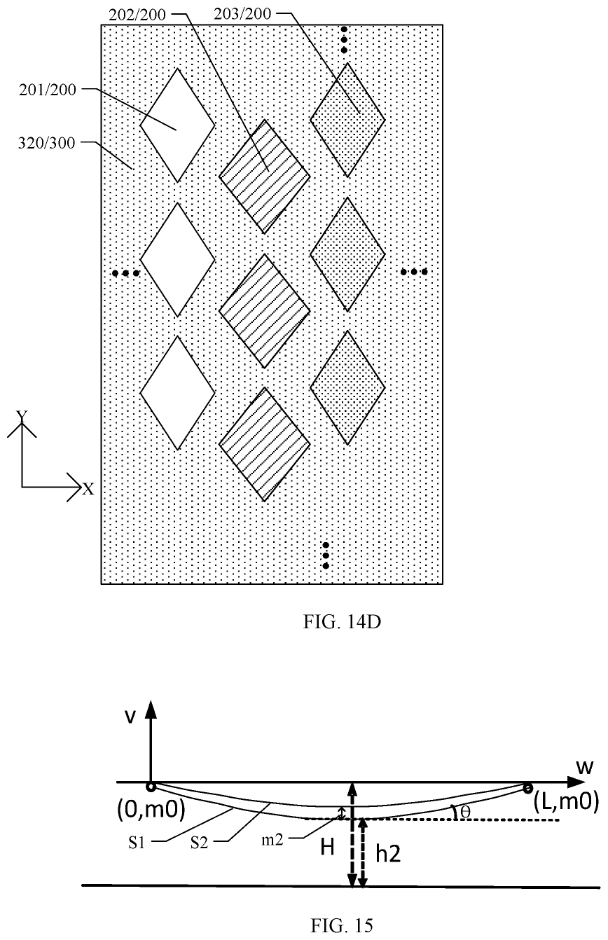

FIG. 14A-FIG. 14D are schematic diagrams of partial planar structures of display substrates provided by different examples of the embodiments of the present disclosure. FIG. 14A-FIG. 14D schematically illustrate that a column of light-emitting elements arranged along the Y direction are light-emitting elements that emit light of the same color. At least one layer of the light-emitting functional layers of the light-emitting elements in the same column is a continuous film layer, or a discontinuous film layer, the embodiments of the present disclosure are not limited in this aspect.

The difference between the display substrates illustrated in FIG. 14A-FIG. 14D and the display substrate illustrated in FIG. 1 mainly includes that the shapes of the light-emitting regions of the light-emitting elements 200 are different, and the shapes of the light-emitting regions of the light-emitting elements 200 in the examples illustrated in FIG. 14A-FIG. 14D may include a cross (as illustrated in FIG. 14A), a circle, an ellipse (as illustrated in FIG. 14C), a semicircle, a semi-ellipse, a triangle, a rhombus (as illustrated in FIG. 14D), a trapezoid (as illustrated in FIG. 14B), an arc shape and other shapes. The light-emitting regions corresponding to the light-emitting elements of respective colors may have the same shape or different shapes. Opposite sides of the light-emitting regions corresponding to adjacent light-emitting elements may be approximately parallel or approximately complementary to utilize the area more efficiently and increase the aperture ratio. For example, as illustrated in FIG. 14A-FIG. 14D, the light-emitting elements 200 include a red light-emitting element 201 configured to emit red light, a green light-emitting element 202 configured to emit green light, and a blue light-emitting element 203 configured to emit blue light. In the present example, the characteristics of the first region, the second region, the film layers included in the light-emitting element, the thickness relationship of the defining portions in different regions, and the thicknesses of the light-emitting functional layers in different regions are identical to corresponding characteristics in any example illustrated in FIG. 1-FIG. 13D, and will not be repeated here.

For example, as illustrated in FIG. 14B, the distances between the light-emitting regions of the light-emitting elements located in the same column and with the same color can also be different, for example, a short edge of a trapezoidal shape of a light-emitting region of an odd-numbered light-emitting element in the column direction faces upward, a long edge of a trapezoidal shape of a light-emitting region of an even-numbered light-emitting element faces upward, and the distance between two adjacent short edges is different from the distance between two adjacent long edges; for example, the distance between two adjacent long edges is smaller than the distance between the two adjacent short edges. The embodiments of the present disclosure are not limited thereto, the display region of the display substrate includes a central region and a peripheral region, and the distance between light-emitting regions of two adjacent light-emitting elements located in the central region may be smaller than the distance between light-emitting regions of two adjacent light-emitting elements located in the peripheral region to facilitate the providing of a sub-region with a larger region in the peripheral region and reduce the probability of uneven solvent in the peripheral region.

For example, as illustrated in FIG. 14D, the dimensions of the light-emitting regions of different columns of light-emitting elements in the column direction may be identical to each other, but the dimensions (such as widths) in the row direction may be different from each other, so as to facilitate printing.

For example, in the case where the light-emitting regions of light-emitting elements of different colors intersect in an ink flow direction, for example, in the column direction, as illustrated in FIG. 14A, in the region E1, the dimension D10 of the defining portion between light-emitting regions of the light-emitting elements of different colors in the ink flow direction is greater than the dimension D20 of the defining portion between light-emitting regions of the light-emitting elements of different colors in the row direction to reduce the risk of ink overflowing in the ink flow direction.

FIG. 15 is a schematic diagram of a cross-sectional model of a light-emitting functional layer of the display substrate illustrated in FIG. 3A. For example, as illustrated in FIG. 1-FIG. 15, the area of the light-emitting functional layer 230 in the sub-region 020 cut by a plane perpendicular to the base substrate 100 is S. For example, the plane perpendicular to the base substrate 100 is a plane perpendicular to the base substrate where a point closest to the base substrate of the sub-region is located. For example, the plane perpendicular to the base substrate 100 is a plane perpendicular to the base substrate where the point closest to the base substrate of the sub-region and a point closest to at least one adjacent light-emitting region are located. For example, the plane perpendicular to the base substrate 100 is a plane perpendicular to the base substrate where a point, which is deepest away from the surface of the base substrate relative to the defining portion, of the sub-region is located. For example, the plane perpendicular to the base substrate 100 is a plane perpendicular to the base substrate where the point, which is deepest away from the surface of the base substrate relative to the defining portion, of the sub-region and a point closest to at least one adjacent light-emitting region are located. For example, the plane perpendicular to the base substrate 100 is a plane perpendicular to the base substrate where the center point of the sub-region is located. For example, the plane perpendicular to the base substrate 100 is a plane perpendicular to the base substrate where the center point of the sub-region and a point closest to at least one adjacent light-emitting region are located. For example, the plane perpendicular to the base substrate 100 is a plane perpendicular to the base substrate where a line connecting the center point of the sub-region and the center point of at least one light-emitting region adjacent to the sub-region is located. For example, S is the largest one of the cross-sections of the light-emitting functional layer cut by a plane perpendicular to the base substrate.

For example, the lower surface of the sub-region is a portion of the corresponding planarization layer (if the anode or other conductive pattern on the planarization layer overlaps with the sub-region, the anode or other conductive pattern is also included) that is away from a surface of a side of the base substrate and is closest to the base substrate, for example, the lower surface is a plane or an arc surface. For example, the light-emitting functional layer is directly formed on the lower surface of the sub-region. For example, the upper surface of the sub-region is a surface of an opening of the sub-region away from the substrate, and the slope angle of the upper surface relative to the surface parallel to the base substrate is less than 20°. For example, the upper surface of the sub-region is a surface of an opening of the sub-region away from the substrate, and the slope angle of the upper surface relative to the surface parallel to the base substrate is less than 15°. For example, the upper surface of the sub-region is a surface of an opening of the sub-region away from the substrate, and the slope angle of the upper surface relative to the surface parallel to the base substrate is less than 10°. For example, the light-emitting functional layer is at least partially formed in the opening (the pixel-defining pattern recess/planarization layer recess/anode recess/other conductive pattern recess) of the sub-region. For example, S is a cross-sectional area of a portion of the light-emitting functional layer located in the opening (the pixel-defining pattern recess/planarization layer recess/anode recess/other conductive pattern recess) of the sub-region in a plane perpendicular to the base substrate. For example, the upper surface of the sub-region is not an actual surface, and the upper surface of the sub-region is a plane that is approximately parallel to the surface of the base substrate and intersects with the boundary of the sub-region. For example, the lower surface of the sub-region intersects with the boundary of the upper surface, that is, a portion where the slope angle of the side wall, which is from the lower surface of the sub-region along the side wall (the pixel-defining pattern recess, a surface of the planarization layer, or a surface of the anode or a surface of other conductive pattern) of the sub-region and continuously extends into the sub-region away from the base substrate, of the sub-region relative to the plane of the base substrate is less than a predetermined value is the boundary of the upper surface of the sub-region, and the boundary outline of the upper surface of the sub-region may be in various shapes such as a circle, a ellipse, a square, a rounded rectangle, etc. For example, the lower surface of the sub-region includes one or a combination of various types such as an arc surface, a spherical surface, a plane, an inclined surface, an uneven surface, etc. The depth of the sub-region is less than or equal to the thickness of the planarization layer.

S satisfies the relationship: S=[(r/r+1)×m2×L+(1/r+1)×m0×L]±Δ.

For example, the above-mentioned L is the maximum dimension of a cross-section, taken by a plane perpendicular to the base substrate, of the light-emitting functional layer 230 in the sub-region 020 in the direction parallel to the base substrate 100. r is a shape coefficient and r≥1, m2 is the maximum thickness of the light-emitting functional layer in the sub-region, m0 is the maximum thickness of the light-emitting functional layer on the defining portion between the light-emitting elements of different colors, and A is not greater than 0.1 microns. In the case where the sub-regions corresponding to the light-emitting elements of different colors are provided with the same depth, the less Lis, the greater r is, and the greater S is; in the case where L corresponding to the light-emitting elements of different colors are identical to each other, the greater the depth of the sub-region is, the greater r is; the amount of ink required can be determined according to the depth and width of the sub-region to print more accurately.

For example, A is less than 0.1 microns. For example, the value range of A is from 0.01 to 0.08. For example, the value range of A is 0.02-0.05. For example, the value range of A is 0.02-0.04. For example, the value range of A is 0.02-0.03. For example, the value range of A is 0.01-0.06. For example, the value range of A is 0.01-0.07. For example, the value range of A is 0.01-0.09.

For example, the portion of the light-emitting functional layer outside the sub-region and the portion inside the sub-region extend integrally, then L is the dimension of the cross-section of the light-emitting functional layer within the boundary of the sub-region. For example, the boundary of the sub-region is defined by the slope angle between the surface of the defining portion and the surface of the base substrate, and the portion with the slope angle greater than 5° is the scope of the sub-region. For example, the boundary of the sub-region is defined by the slope angle between the surface of the defining portion and the surface of the base substrate, and the portion with the slope angle greater than 6° is the scope of the sub-region. For example, the boundary of the sub-region is defined by the slope angle between the surface of the defining portion and the surface of the base substrate, and the portion with the slope angle greater than 7° is the scope of the sub-region. For example, the boundary of the sub-region is defined by the slope angle between the surface of the defining portion and the surface of the base substrate, and the portion with the slope angle greater than 8° is the scope of the sub-region. For example, the boundary of the sub-region is defined by the slope angle between the surface of the defining portion and the surface of the base substrate, and the portion with the slope angle greater than 9° is the scope of the sub-region. For example, the boundary of the sub-region is defined by the slope angle between the surface of the defining portion and the surface of the base substrate, and the portion with the slope angle greater than 10° is the scope of the sub-region. For example, the boundary of the sub-region is defined by the slope angle between the surface of the defining portion and the surface of the base substrate, and the portion with the slope angle greater than 11° is the scope of the sub-region. For example, the boundary of the sub-region is defined by the slope angle between the surface of the defining portion and the surface of the base substrate, and the portion with the slope angle greater than 12° is the scope of the sub-region. For example, the boundary of the sub-region is defined by the slope angle between the surface of the defining portion and the surface of the base substrate, and the portion with the slope angle greater than 13° is the scope of the sub-region. For example, the boundary of the sub-region is defined by the slope angle between the surface of the defining portion and the surface of the base substrate, and the portion with the slope angle greater than 14° is the scope of the sub-region. For example, the boundary of the sub-region is defined by the slope angle between the surface of the defining portion and the surface of the base substrate, and the portion with the slope angle greater than 15° is the scope of the sub-region. For example, the boundary of the sub-region is defined by the slope angle between the surface of the defining portion and the surface of the base substrate, and the portion with the slope angle greater than 20° is the scope of the sub-region.

For example, the area of the largest cross-section of the light-emitting functional layer in the sub-region cut by a plane perpendicular to the base substrate is S, and S satisfies the relationship:

$$S = [ ( r / r + 1 ) \times ( p \times λ \times k ) \times L + ( 1 / r + 1 ) \times m 0 \times L ] \pm Δ .$$

L is the maximum dimension of a cross-section, taken by a plane perpendicular to the base substrate, of the light-emitting functional layer 230 in the sub-region 020 in the direction parallel to the base substrate 100, r is a shape coefficient and r≥1, m2 is the maximum thickness of the light-emitting functional layer in the sub-region, m0 is the maximum thickness of the light-emitting functional layer on the defining portion between the light-emitting elements of different colors, λ is the wavelength of the light emitted by the nearest light-emitting element of the sub-region, k is a multiple of the cavity length, and the range of k includes 1-3, the range of p includes 0.1-1.5, and A is not greater than 0.1 microns.

In the case where the sub-regions corresponding to the light-emitting elements of different colors are provided with the same depth, the less Lis, the greater r is, and the greater S is; in the case where L corresponding to the light-emitting elements of different colors are identical to each other, the greater the depth of the sub-region is, the greater r is; the amount of ink required can be determined according to the depth and width of the sub-region to print more accurately.

For example, the range of S includes 3.5-5.5 square microns. For example, the range of S includes 3.6-5.4 square microns. For example, the range of S includes 3.7-5.3 square microns. For example, the range of S includes 3.8-5.2 square microns. For example, the range of S includes 4-5 square microns. For example, the range of S includes 4.2-4.8 square microns. For example, the range of S includes 4.5-4.7 square microns.

For example, the values of k corresponding to sub-regions adjacent to the light-emitting elements of different colors are identical to each other, and k is 1 or 2.

For example, the range of p corresponding to the sub-region adjacent to the red light-emitting element is (0.15-0.25)*y; and/or, the range of p corresponding to the sub-region adjacent to the green light-emitting element is (0.11-0.24)*y; and/or, the range of p corresponding to the sub-region adjacent to the green light-emitting element is (0.1-0.23)*y; y=m2/m1, and the range of y includes 1-10.

For example, the range of p corresponding to the sub-region adjacent to the red light-emitting element is (0.16-0.24)*y. For example, the range of p corresponding to the sub-region adjacent to the red light-emitting element is (0.17-0.23)*y. For example, the range of p corresponding to the sub-region adjacent to the red light-emitting element is (0.18-0.22)*y. For example, the range of p corresponding to the sub-region adjacent to the red light-emitting element is (0.19-0.21)*y. For example, the range of p corresponding to the sub-region adjacent to the red light-emitting element is (0.2-0.22)*y.

For example, the range of p corresponding to the sub-region adjacent to the green light-emitting element is (0.12-0.23)*y. For example, the range of p corresponding to the sub-region adjacent to the green light-emitting element is (0.13-0.22)*y. For example, the range of p corresponding to the sub-region adjacent to the green light-emitting element is (0.14-0.21)*y. For example, the range of p corresponding to the sub-region adjacent to the green light-emitting element is (0.15-0.2)*y. For example, the range of p corresponding to the sub-region adjacent to the green light-emitting element is (0.16-0.19)*y. For example, the range of p corresponding to the sub-region adjacent to the green light-emitting element is (0.17-0.18)*y.

For example, the range of p corresponding to the sub-region adjacent to the blue light-emitting element is (0.11-0.22)*y. For example, the range of p corresponding to the sub-region adjacent to the blue light-emitting element is (0.12-0.21)*y. For example, the range of p corresponding to the sub-region adjacent to the blue light-emitting element is (0.13-0.2)*y. For example, the range of p corresponding to the sub-region adjacent to the blue light-emitting element is (0.14-0.19)*y. For example, the range of p corresponding to the sub-region adjacent to the blue light-emitting element is (0.15-0.18)*y. For example, the range of p corresponding to the sub-region adjacent to the blue light-emitting element is (0.16-0.17)*y.

For example, the value range of y is 1-5. For example, the value range of y is 1.1-4.5. For example, the value range of y is 1.2-4. For example, the value range of y is 1.3-3.5. For example, the value range of y is 1.4-3. For example, the value range of y is 1.5-2. For example, the value range of y is 1.1-1.9. For example, the value range of y is 1.2-1.8.

For example, the range of S includes 3.5-5.5 square microns. For example, the range of S includes 3.6-5.4 square microns. For example, the range of S includes 3.7-5.3 square microns. For example, the range of S includes 3.8-5.2 square microns. For example, the range of S includes 4-5 square microns. For example, the range of S includes 4.2-4.8 square microns. For example, the range of S includes 4.5-4.7 square microns.

For example, the above-mentioned L is the dimension of the upper surface of the sub-region on a cross-sectional plane of the light-emitting functional layer. For example, r≥1. For example, m1=p×λ×n, the range of λ includes 615 nm-620 nm, 530 nm-540 nm or 460 nm-380 nm, and the range of n includes 1-31. For example, the range of p includes 0.16-0.23, 0.13-0.22 or 0.12-0.2. For example, the range for Δ includes ±0.5 microns. For example, the range for Δ includes ±0.4 microns. For example, the range for Δ includes ±0.3 microns. For example, the range for Δ includes ±0.2 microns. For example, the range for Δ includes ±0.1 microns.

For example, m2 is the maximum thickness of the light-emitting functional layer in the sub-region. For example, m2 is the maximum thickness of the light-emitting functional layer in the central region of the sub-region. For example, m2 is the maximum thickness from the surface of the defining portion away from the base substrate to the second electrode in the sub-region. For example, the thickness of the light-emitting functional layer in the sub-region gradually decreases from the central region to the peripheral region. For example, the thickness of the light-emitting functional layer gradually decreases from the central region to both sides on the plane perpendicular to the base substrate with the same amplitude, that is, on the plane perpendicular to the base substrate, the shape of the light-emitting functional layer is approximately symmetrical on both sides. m2 is positively correlated with the depth of the sub-region, the greater the depth of the sub-region is, the greater the m2 is, and the thickness of the light-emitting functional layer can be controlled and a reasonable amount of ink required can be obtained by controlling the depth of the sub-region.

For example, as illustrated in FIG. 1-FIG. 15, the cross-section, taken by a plane perpendicular to the base substrate 100, of the light-emitting functional layer 230 in the sub-region 020 includes two curves S1 and S2. For example, both S1 and S2 are represented by a quadratic equation in one variable. For example, both S1 and S2 are represented by a one-variable equation of degree n, where n is an integer multiple of 2. For example, both S1 and S2 are fitted with other curves, such as parabola. For example, S1 and S2 are also fitted with different curves. For example, the cross-section of the light-emitting functional layer is symmetrical, that is, S1 and S2 in FIG. 15 are both symmetrical curves, and the symmetry axis of S1 is identical to the symmetry axis of S2, for example, the symmetry axis is a straight line parallel to the v-axis where w=½L in FIG. 15.

For example, two points of the curve S1 are represented as (0, −m0) and (L, −m0) respectively in the coordinate system wv. For example, two points of the curve S2 are represented as (0, 0) and (L, 0) respectively in the coordinate system wv. For example, the maximum distance between a surface of a side of the defining portion close to the base substrate and a surface of a side of the light-emitting functional layer close to the base substrate is h2 (i.e., the maximum thickness of the defining portion in the sub-region). For example, the above-mentioned r is greater than or equal to 1 to satisfy the recess shape of the light-emitting functional layer. For example, r is 2, and the area S of the above-mentioned cross-section can satisfy: S=[(⅔)×m2×L+(⅓)×m0×L]×(1+Δ) %.

For example, the above-mentioned L is 10-15 microns. For example, the range of the area S of the above-mentioned cross-section includes 2-7 square micrometers. For example, the range of the area S of the above-mentioned cross-section includes 3.5-5.5 square microns. For example, the range of the area S of the above-mentioned cross-section includes 4-5 square microns.

For example, the above-mentioned L is 3-18 microns. For example, the above-mentioned L is 5-13 microns. For example, the above-mentioned L is 6-12 microns. For example, the above-mentioned L is 7-14 microns. For example, the above-mentioned L is 4-11 microns.

The embodiments of the present disclosure can design the shape of the light-emitting functional layer and the dimension and depth of the sub-regions according to the amount of ink formed by the inkjet printing process in the light-emitting functional layer that needs to be formed, which can make more efficient use of the ink and reduce the cost on the premise of ensuring the quality of the film layers.

For example, the shape of the light-emitting functional layer is designed according to the drying conditions, the drying speed is first fast and then slow, the larger the openings of the curve S1 and the curve S2 are, that is, the more obvious the change of the opening diameter before and after, and the larger the included angle θ between the curve S1 and the w direction is or the deeper the depth of the sub-region is. For example, the range of 0 is 5°-30°, or 10°-20°, etc. For example, the depth of the sub-region is 1˜4 microns. For example, the depth of the sub-region is 1.5-6 microns.

For example, the shape of the light-emitting functional layer is designed according to the dimension of the light-emitting element (that is, the dimension of the pixel region). For example, the ranges of the area of the opening and the area of the pixel region are 0.02-0.1, or 0.05-0.08, etc. The larger the area of the pixel region, the more the amount of ink required. In the case where the opening diameter is a set value, the depth of the sub-region or the light-emitting function layer needs to be increased, that is, the difference between H and h2 increases (H is the distance between the defining portion and the w-axis), and the range of h2/h0 may be 1-3, or 1.2-2.5, etc.

For example, the shape of the light-emitting functional layer is designed according to the distance between the sub-region and the opening of the pixel-defining pattern, for example, the closer the distance between the sub-region and the opening of the pixel-defining pattern, the smaller the area of the sub-region that is required, for example, the range of the distance between the sub-region and the opening of the pixel-defining pattern is 5-10 microns, or 7-9 microns, etc.

For example, the shape of the light-emitting functional layer is designed according to the ink conditions, for example, the higher the ink concentration, the larger the m2/m1, and the range of m2/m1 is 1-3, or 1.5-2.5, etc.

When the inkjet printing process is used to form part of the film layers of the light-emitting functional layer, the evaporation rate of the ink is fast in the initial stage of printing, and a larger area of ink balance is required. In the later stage of printing, as the ink concentration increases, the evaporation rate slows down, and the required balance ink also decreases. The solvent concentration can be dynamically adjusted, and the amount of ink can be reduced by controlling the ink area in the sub-region to gradually increase from the direction close to the base substrate to the direction away from the base substrate.

Another embodiment of the present disclosure provides a display device, including any one of the above-mentioned display substrates.

For example, the display device provided by the embodiments of the present disclosure is an organic light-emitting diode display device.

For example, the display device further includes a cover plate on the display side of the display substrate.

For example, the display device is any product or component with a display function, such as a mobile phone, a tablet computer, a notebook computer, a TV, a monitor, a navigator, etc., with an under-screen camera, and the present embodiment is not limited thereto.

Another embodiment of the present disclosure provides a display substrate, and the display substrate is not limited to be used for display, and may also be other devices including a camera, a display board, an e-book, an optical equipment, a rearview mirror, and a smart mirror.

Another embodiment of the present disclosure provides a display substrate, and the display substrate includes a base substrate, a plurality of functional elements being located on the base substrate, the plurality of functional elements being configured to exit light, the plurality of functional elements including a functional layer, and the functional layer including at least one film layer; the pixel-defining pattern, which includes a plurality of openings and a defining portion surrounding the plurality of openings, and the functional layer is at least partially located in the plurality of openings. The display substrate is distributed with a plurality of first regions and a plurality of second regions, the plurality of first regions respectively correspond to the plurality of openings, at least part of the plurality of second regions are covered by the defining portion, the at least one film layer in the functional layer is located in at least part of at least one of the plurality of first regions and located in at least part of at least one of the plurality of second regions, the plurality of first regions are configured to exit light, and the plurality of second regions are provided with at least one light-shielding layer overlapping with the defining portion; the plurality of functional elements include functional elements for exiting light of at least two colors, the functional elements for exiting light of at least two colors include a first color functional element configured to exit first color light and a second color functional element configured to exit second color light, and an area of a light-exiting region of the first color functional element is greater than an area of a light-exiting region of the second color functional element; and the plurality of second regions include a plurality of recessed regions, the at least one film layer of the functional layer includes a portion located in at least one recessed region and a portion located in a light-exiting region adjacent to the at least one recessed region, an area of the at least one recessed region is not greater than an area of the light-exiting region adjacent to the at least one recessed region, a height of a surface, closest to the base substrate, of the least one film layer located in the recessed region relative to the base substrate is a first height, a height of a surface, closest to the base substrate, of the least one film layer located in the light-exiting region adjacent to the recessed region relative to the base substrate is a second height, and the first height is not greater than the second height. The display substrate provided by the embodiments of the present disclosure is beneficial to adjust the uniformity of the film layer formed in the light-exiting region by inkjet printing by setting the first height of the film layer in the recessed region relative to the base substrate to be no greater than the second height of the film layer in the light-exiting region relative to the base substrate. In some examples, the recessed region can accommodate ink overflowing from the light-exiting region or ink remaining in regions outside the light-exiting region due to the printing process, to avoid problems such as cross-color, poor display, etc.

In some examples, the embodiments of the present disclosure further provide a display substrate, including a base substrate, a plurality of light-emitting elements located on the base substrate, the light-emitting element including a light-emitting functional layer and a first electrode and a second electrode located on both sides of the light-emitting functional layer in a direction perpendicular to the base substrate, the first electrode being located between the light-emitting functional layer and the base substrate, and the light-emitting functional layer including a plurality of film layers; the pixel-defining pattern being located on a side of the first electrode away from the base substrate, the pixel-defining pattern including a plurality of openings and a defining portion surrounding the plurality of openings, and the plurality of light-emitting elements are at least partially located in the plurality of openings. The display substrate is distributed with a plurality of first regions and a plurality of second regions, the first region corresponds to the opening, at least a portion of the second region is covered by the defining portion, and at least one film layer in the light-emitting functional layer is located in at least part of at least one first region and at least part of at least one second region; the plurality of light-emitting elements include light-emitting elements of at least two colors, the light-emitting elements of at least two colors include first color light-emitting element configured to exit first color light and second color light-emitting element configured to exit second color light, and the area of the light-emitting region of the first color light-emitting element is greater than the area of the light-emitting region of the second color light-emitting element; the plurality of second regions include a plurality of recessed regions, and the maximum thickness of a portion of the light-emitting functional layer located in the recessed region is greater than the maximum thickness of a portion of the light-emitting functional layer located in other regions outside the recessed region, or the maximum thickness of a portion of at least one film layer in the light-emitting functional layer located in the recessed region is greater than the maximum thickness of a portion of at least one film layer in the light-emitting functional layer located in other regions outside the recessed region; each light-emitting element corresponds to at least one recessed region, the distance between a center of the light-emitting region of the first color light-emitting element and a center of a recessed region corresponding to the first color light-emitting element is a first distance, and the distance between a center of the light-emitting region of the second color light-emitting element and a center of a recessed region corresponding to the second color light-emitting element is a second distance, and the first distance is greater than the second distance. In the display substrate provided by the embodiments of the present disclosure, providing the distances between the centers of the first color light-emitting element and the second color light-emitting element with different areas of light-emitting regions and the centers of corresponding recessed regions to be different is beneficial to balance the drying speeds of the film layers formed by inkjet printing in the light-emitting functional layers of the light-emitting elements with different areas of light-emitting regions.

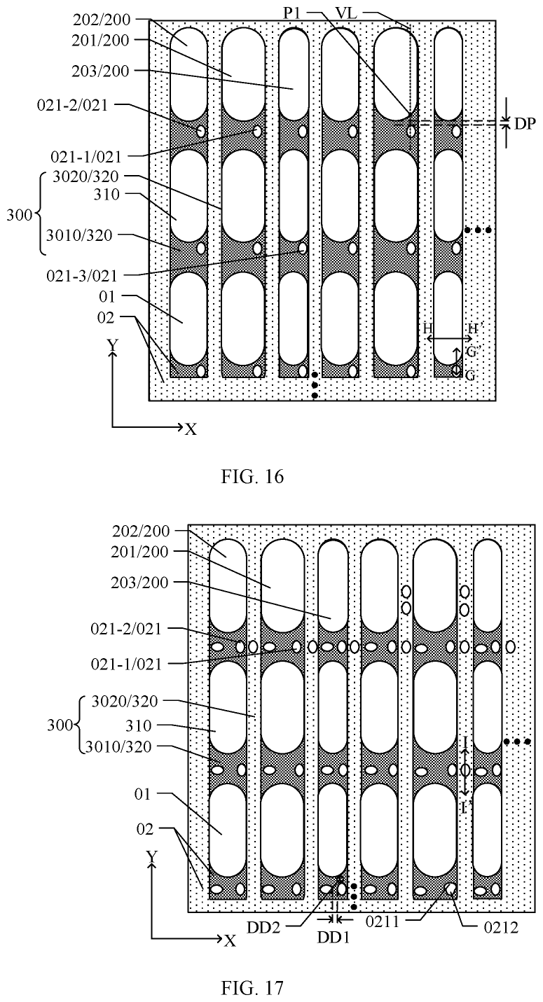

FIG. 16 is a schematic diagram of a partial planar structure of a display substrate provided by an embodiment of the present disclosure. For the sake of clarity, FIG. 16 only schematically illustrates positions of the pixel-defining pattern, the recessed region and the light-emitting element, but does not illustrate the light-emitting functional layer, the first electrode and the second electrode included in the light-emitting element.

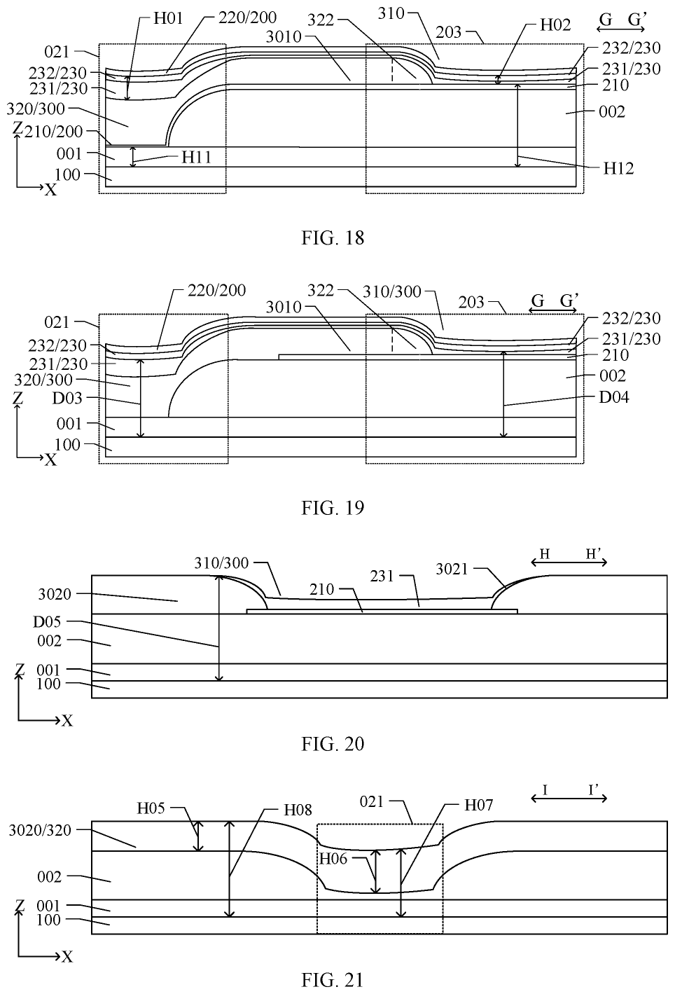

As illustrated in FIG. 16, the display substrate includes a base substrate, a plurality of functional elements 200 and a pixel-defining pattern 300. The plurality of functional elements 200 are located on the base substrate, the plurality of functional elements 200 are configured to exit light, the plurality of functional elements 200 include a functional layer, and the functional layer includes at least one film layer; the pixel-defining pattern 300 includes a plurality of openings 310 and a defining portion 320 surrounding the plurality of openings 310, and the functional layer is at least partially located in the plurality of openings 310. The display substrate is distributed with a plurality of first regions 01 and a plurality of second regions 02, the plurality of first regions 01 respectively correspond to the plurality of openings 310, at least part of the plurality of second regions 02 are covered by the defining portion 320, the at least one film layer in the functional layer is located in at least part of at least one of the plurality of first regions 01 and located in at least part of at least one of the plurality of second regions 02, the plurality of first regions 01 are configured to exit light, and the plurality of second regions 02 are provided with at least one light-shielding layer overlapping with the defining portion 320; the plurality of functional elements 200 include functional elements 200 for emitting light of at least two colors, the functional elements 200 for emitting light of at least two colors include a first color functional element 201 configured to exit first color light and a second color functional element 202 configured to exit second color light, and an area of a light-exiting region of the first color functional element 201 is greater than an area of a light-exiting region of the second color functional element 202; and the plurality of second regions 02 include a plurality of recessed regions 021, the at least one film layer of the functional layer includes a portion located in at least one recessed region 021 and a portion located in a light-exiting region adjacent to the at least one recessed region 021, an area of the at least one recessed region 021 is not greater than an area of the light-exiting region adjacent to the at least one recessed region 021, a height of a surface, closest to the base substrate, of a film layer located in the recessed region 021 relative to the base substrate is a first height (H11 as illustrated in FIG. 18), a height of a surface, closest to the base substrate, of a film layer located in the light-exiting region adjacent to the recessed region 021 relative to the base substrate is a second height (H12 as illustrated in FIG. 18), and the first height is not greater than the second height. The display substrate provided by the embodiments of the present disclosure is beneficial to adjust the uniformity of the film layer formed in the light-exiting region by inkjet printing by setting the first height of the film layer in the recessed region relative to the base substrate to be no greater than the second height of the film layer in the light-exiting region relative to the base substrate.

For example, the surface, closest to the base substrate, of the film layer located in the recessed region 021 is the lowest point of the film layer located in the recessed region 021, and the surface, closest to the base substrate, of the film layer located in the light-exiting region adjacent to the recessed region 021 is the lowest point of the film layer located in the light-exiting region.

For example, the display substrate provided by the embodiments of the present disclosure may be a substrate for display, such as an array substrate (such as a substrate including a driving circuit), a color filter substrate including a color filter, a substrate including quantum dots, a substrate including an electrochromic layer, an electronic paper, or other substrates formed with functional film layers.

In some examples, the functional layer includes at least one selected from the group consisting of electroluminescence material, photoluminescence material, electrochromic material, electrowetting material, color filter material and optical medium material.

For example, the above-mentioned “functional layer” may include an electroluminescent layer, a photoluminescent layer, an electrochromic layer, a color filter layer, or a simple optical adjustment layer. The optical adjustment layer is, for example, a dielectric layer, and the dielectric layer is, for example, a high refractive index film layer (the refractive index is greater than or equal to 1.5), a low refractive index film layer (the refractive index is less than 1.5), a stacked layer including a plurality of layers, a film layer doped with optical particles, or a film layer that can partially or completely shield light such as an electrowetting layer, etc.

For example, in the case where the display substrate is an array substrate, at least one light-shielding layer provided in the second region 02 and overlapping with the defining portion 320 is the black matrix 400 in the above-mentioned embodiments; but not limited thereto, in the case where the display substrate is a substrate including quantum dots, the light-shielding layer is a black matrix between the defining portion and the base substrate (described later).

In some examples, as illustrated in FIG. 16, a portion of the functional layer located in a recessed region 021 has the maximum thickness greater than that of a portion of the functional layer located in a light-exiting region adjacent to the recessed region 021, or the maximum thickness of the portion of the at least one film layer in the functional layer located in a recessed region 021 is greater than the maximum thickness of the portion of the at least one film layer in the functional layer located in a light-exiting region adjacent to the recessed region 021; the maximum thickness is the maximum dimension of the functional layer or the at least one film layer in the functional layer in the direction perpendicular to the base substrate; and the plurality of recessed regions 021 at least include a first recessed region 021-1 and a second recessed region 021-2, the functional layer in the first recessed region 021-1 includes the same material as the functional layer of the first color functional element 201, the functional layer in the second recessed region 021-2 includes the same material as the functional layer of the second color functional element 202, the distance between a center of the light-exiting region of the first color functional element 201 and a center of the first recessed region 021-1 corresponding to the first color functional element 201 is a first distance, the distance between a center of the light-exiting region of the second color functional element 202 and a center of the second recessed region 021-2 corresponding to the second color functional element 202 is a second distance, and the first distance is not equal to the second distance.

The center of the above-mentioned recessed region may refer to: in the case where the bottom of the film layer in the recessed region is a gradual surface, then the center of the recessed region is the lowest point at the bottom of the film layer; and in the case where the bottom of the film layer in the recessed region includes a plane, then the center of the recessed region is the geometric center of the plane, if the plane is a circle, the geometric center is the center of the circle; if the plane is a polygon, the geometric center is the intersection of lines connecting the midpoints of each side.

For example, the above-mentioned display substrate is an array substrate, the functional element 200 is a light-emitting element, and the functional layer is a light-emitting functional layer; and the light-exiting region of the above-mentioned functional element is the light-emitting region of the light-emitting element.

For example, as illustrated in FIG. 16, a display substrate includes a base substrate, a plurality of light-emitting elements 200 and a pixel-defining pattern 300. The plurality of light-emitting elements 200 are located on the base substrate, the light-emitting element 200 includes a light-emitting functional layer and a first electrode and a second electrode located on both sides of the light-emitting functional layer in the direction perpendicular to the base substrate, the first electrode is located between the light-emitting functional layer and the base substrate, and the light-emitting functional layer includes a plurality of film layers; the pixel-defining pattern 300 is located on a side of the first electrode away from the base substrate, the pixel-defining pattern 300 includes a plurality of openings 310 and a defining portion surrounding the plurality of openings 310, and the plurality of light-emitting elements 200 are at least partially located in the plurality of openings 310. The display substrate is distributed with a plurality of first regions 01 and a plurality of second regions 02, the first region 01 corresponds to the opening 310, at least a portion of the second region 02 is covered by the defining portion 320, and at least one film layer in the light-emitting functional layer is located in at least part of at least one first region 01 and at least part of at least one second region 02; the plurality of light-emitting elements 200 include light-emitting elements emitting light of at least two colors, the light-emitting elements emitting light of at least two colors include a first color light-emitting element 201 configured to exit first color light and a second color light-emitting element 202 configured to exit second color light, and the area of the light-emitting region of the first color light-emitting element 201 is greater than the area of the light-emitting region of the second color light-emitting element 202. For example, in the case where the light-emitting element is a light-emitting element of an organic light-emitting diode, the light-exiting region of the light-emitting element is the light-emitting region of the light-emitting element, and the “light-emitting region” here may have the same meaning as the “light-emitting region” in any of the embodiments illustrated in FIG. 1-FIG. 15, which will not be repeated here.

For example, as illustrated in FIG. 16, the maximum thickness of a portion of the light-emitting functional layer located in the recessed region 021 is greater than the maximum thickness of a portion of the light-emitting functional layer located in other regions outside the recessed region 021, or the maximum thickness of a portion of at least one film layer in the light-emitting functional layer located in the recessed region 021 is greater than the maximum thickness of a portion of at least one film layer in the light-emitting functional layer located in other regions outside the recessed region 021. The “recessed region 021” here may have the same characteristics as the sub-region 020 illustrated in FIG. 1-FIG. 3B, but is not limited to this. The “recessed region 021” here may also be other regions in the second sub-region 02 except the sub-region 020.

For example, in some examples, the recessed region and the sub-region both exist, and the recessed region and the sub-region may both include the functional layer material of the non-display region. For example, in some other examples, the recessed region and the sub-region both exist, but only one of the recessed region and the sub-region is provided with the functional layer material. For example, in some other examples, the recessed region and the sub-region may be combined into one region, that is, the region has both the characteristics of the sub-region and the characteristics of the recessed region, that is, the region functions as a sub-region and further functions as a recessed region. For example, in some other examples, the amount of recessed regions is different from the amount of sub-regions. For example, in some other examples, the recessed region and the sub-region may be separated from each other, or may at least partially overlap with each other. For example, in some other examples, the portion corresponding to the recessed region is formed by the removal or thinning of the first layer, and the portion corresponding to the sub-region is formed by the removal or thinning of the second layer; and the first layer and the second layer may be film layers of the same material or different materials. For example, in some other examples, the portion corresponding to the recessed region is formed by the removal or thinning of the first layer, and the portion corresponding to the sub-region is formed by the removal or thinning of the second layer; and the first layer and the second layer are located on the upper and lower sides of the functional layer in the direction perpendicular to the base substrate. For example, in some other examples, the portion corresponding to the recessed region is formed by the removal or thinning of the first layer, and the portion corresponding to the sub-region is formed by the removal or thinning of the second layer; and the depth of the recessed region may be identical to or different from the depth of the sub-region.

For example, as illustrated in FIG. 16, each light-emitting element 200 corresponds to at least one recessed region 021, the distance between the center of the light-emitting region of the first color light-emitting element 201 and the center of the recessed region 021 corresponding to the first color light-emitting element 201 is a first distance, the distance between the center of the light-emitting region of the second color light-emitting element 202 and the center of the recessed region 021 corresponding to the second color light-emitting element 202 is a second distance, and the first distance is greater than the second distance. The “center of the light-emitting region” mentioned above may refer to the geometric center of the light-emitting region, such as the geometric center of the orthographic projection of the light-emitting region on the base substrate. The above-mentioned “each light-emitting element 200 corresponds to at least one recessed region 021” may mean that at least one recessed region is provided within a certain distance from the light-emitting region of each light-emitting element, the at least one recessed region corresponds to the light-emitting element, and one recessed region only corresponds to one light-emitting element. The above-mentioned “recessed region” may refer to a region where the thickness of at least one layer of the light-emitting functional layer (or the entire light-emitting functional layer) is the greatest, for example, the center of the recessed region is the position where the thickness of at least one layer of the light-emitting functional layer (or the entire light-emitting functional layer) is the greatest.

In the display substrate provided by the embodiments of the present disclosure, providing the distance between the center of the first color light-emitting element with different light-emitting region area from that of the second color light-emitting element and the center of corresponding recessed region to be different from the distance between the center of the second color light-emitting element and the center of corresponding recessed region is beneficial to balance the drying speeds of the film layers formed by inkjet printing in the light-emitting functional layers of the light-emitting elements with different areas of light-emitting regions.

The display substrate provided by the present embodiment may include the base substrate 100 illustrated in FIG. 2A; the display substrate provided by the present embodiment may include a plurality of light-emitting elements 200 located on the base substrate 100, and the first electrode 210 and the second electrode 220 included in the light-emitting element 200 may have the same characteristics as the first electrode 210 and the second electrode 220 included in the light-emitting element 200 illustrated in FIG. 3A-FIG. 6; the display substrate provided by the present embodiment may include a pixel-defining pattern 300 located on the side of the first electrode 210 away from the base substrate 100, and the opening 310 included in the pixel-defining pattern 300 may have the same characteristics as the opening 310 included in the pixel-defining pattern 300 illustrated in FIG. 1. A plurality of film layers included in the light-emitting functional layer in the display substrate provided by the present embodiment may be the same as the light-emitting functional layer in the above-mentioned embodiment, including a hole injection layer (HIL), a hole transport layer (HTL), a light-emitting layer (EL), an electron transport layer (ETL), an electron injection layer (EIL) and other film layers, and the light-emitting functional layer may have the same characteristics as the light-emitting functional layer in the above-mentioned embodiment.

In some examples, as illustrated in FIG. 16, a portion, located between light-exiting regions of adjacent functional elements 200 exiting light with the same color, in the defining portion 320 is a first defining portion 3010, and the distance between a center of a recessed region 021, located between the light-exiting regions of adjacent functional elements 200 with the same light-exiting color, and a center of the first defining portion 3010 is in a range of 5-40 microns.

For example, as illustrated in FIG. 16, a portion, located between light-emitting regions of adjacent light-emitting elements 200 with the same light-emitting color, in the defining portion 320 is a first defining portion 3010, and the distance between a center of a recessed region 021, located between the light-emitting regions of adjacent light-emitting elements 200 with the same light-exiting color, and a center of the first defining portion 3010 is in a range of 5-40 microns.

For example, the first defining portion 3010 in the display substrate in the present embodiment is the third sub-defining portion 323 in the display substrate illustrated in FIG. 3A and FIG. 3B. For example, the boundary of the first defining portion 3010 extending along the Y direction is flush with the light-emitting region of the light-emitting element 200, for example, the dimension of the first defining portion 3010 along the X direction is identical to the dimension, along the X direction, of the light-emitting regions on both sides of the first defining portion 3010 in the Y direction, but not limited thereto; for example, the dimension of the first defining portion 3010 along the X direction is greater than the dimension, along the X direction, of the light-emitting regions on both sides of the first defining portion 3010 in the Y direction, or the dimension of the first defining portion 3010 along the X direction is smaller than the dimension, along the X direction, of the light-emitting regions on both sides of the first defining portion 3010 in the Y direction.

In some examples, as illustrated in FIG. 16, at least two adjacent functional elements 200 arranged along a first direction are provided with the same light-exiting color, and at least two adjacent functional elements 200 arranged along a second direction are provided with different light-exiting colors.

For example, as illustrated in FIG. 16, at least two adjacent light-emitting elements 200 arranged in the first direction are provided with the same light-emitting color, at least two adjacent light-emitting elements 200 arranged in the second direction are provided with different light-emitting colors, and the first direction intersects with the second direction. For example, the first direction is the Y direction, and the second direction is the X direction. The first direction and the second direction in the present embodiment may have the same characteristics as the first direction and the second direction in the above-mentioned embodiments, and details are not repeated here.

For example, as illustrated in FIG. 16, the light-emitting elements 200 with the same light-emitting color are arranged along the Y direction, and the first defining portion 3010 is located between the light-emitting regions of two adjacent light-emitting elements 200 arranged along the Y direction.

For example, the distance between the center of the recessed region 021 between the light-emitting regions of two adjacent light-emitting elements 200 arranged along the Y direction and the center of the first defining portion 3010 is 6-38 microns, such as 8-36 microns, such as 10-35 microns, such as 12-32 microns, such as 15-30 microns, such as 18-28 microns, such as 20-25 microns, such as 22-24 microns. For example, the center of the recessed region 021 does not coincide with the center of the first defining portion 3010, and a certain spacing is provided between the center of the recessed region 021 and the center of the first defining portion 3010.

By setting the center of the first defining portion to be not coincide with the center of the recessed region, the embodiments of the present disclosure can enable the recessed region to be distributed in a larger region of the second region in the first direction, which can not only facilitate the setting of the area of the recessed region, but also reduce the impact of the recessed region on the light-emitting region of the adjacent light-emitting elements in the first direction.

For example, as illustrated in FIG. 16, a connection line between the center of the light-emitting region of the light-emitting element 200 and the center of the first defining portion 3010 is parallel to the Y direction, and the center of the recessed region 021 is located on one side of the connection line. For example, the entire recessed region 021 is located on one side of the connection line.

For example, as illustrated in FIG. 16, in the light-emitting elements 200 that emit light of different colors, the relative positional relationship between a light-emitting region of a light-emitting element 200 emitting light of one color and a recessed region 021 corresponding to the light-emitting region is identical to the relative positional relationship between a light-emitting region of a light-emitting element 200 emitting light of another color and a recessed region 021 corresponding to the light-emitting region; for example, if the direction indicated by the arrow in the Y direction is upward, and the direction indicated by the arrow in the X direction is rightward, the recessed region 021 corresponding to the light-emitting region is located at the lower right corner of the light-emitting region. But not limited thereto, the recessed region corresponding to the light-emitting region may also be located at the upper right corner, lower left corner or upper left corner of the light-emitting region, which is not limited in the embodiments of the present disclosure.

In some examples, as illustrated in FIG. 16, in the first direction, the ratio of dimensions of the light-exiting regions of at least two functional elements 200 of different colors is in a range of 0.7-1.5.

In some examples, in the second direction, the ratio of dimensions of the light-exiting regions of at least two functional elements 200 of different colors is in a range of 0.7-1.5.

For example, as illustrated in FIG. 16, in the first direction, the ratio of dimensions of the light-emitting regions of the light-emitting elements 200 of different colors is in a range of 0.7-1.5. For example, in the second direction, the ratio of dimensions of the light-emitting regions of the light-emitting elements 200 of different colors is in a range of 0.7-1.5.

For example, as illustrated in FIG. 16, the areas of the light-emitting regions of the light-emitting elements 200 of different colors are different from each other. For example, the ratio of dimensions of the light-emitting regions of the light-emitting elements 200 of different colors in the first direction is 0.8-1.4. For example, the ratio of dimensions of the light-emitting regions of the light-emitting elements 200 of different colors in the first direction is 0.9-1.3. For example, the ratio of dimensions of the light-emitting regions of the light-emitting elements 200 of different colors in the first direction is 1.1-1.2. For example, the ratio of dimensions of the light-emitting regions of the light-emitting elements 200 of different colors in the second direction is 0.8-1.4. For example, the ratio of dimensions of the light-emitting regions of the light-emitting elements 200 of different colors in the second direction is 0.9-1.3. For example, the ratio of dimensions of the light-emitting regions of the light-emitting elements 200 of different colors in the second direction is 1.1-1.2.

For example, the dimensions of the light-emitting regions of the light-emitting elements 200 of different colors in the first direction are identical to each other, but the dimensions of the light-emitting regions of the light-emitting elements 200 of different colors in the second direction are different from each other. For example, the dimensions of the light-emitting regions of the light-emitting elements 200 of different colors in the second direction are identical to each other, but the dimensions of the light-emitting regions of the light-emitting elements 200 of different colors in the first direction are different from each other.

For example, the light-emitting elements 200 of different colors include a blue light-emitting element that emits blue light, a green light-emitting element that emits green light, and a red light-emitting element that emits red light. For example, the shapes of the light-emitting regions of the light-emitting elements 200 of different colors may be identical to or different from each other.

In some examples, as illustrated in FIG. 16, the first color functional element 201 is a functional element that exits blue light, and the second color functional element 202 is a functional element that exits green light or a functional element that exits red light; and the first distance is greater than the second distance.

In some examples, as illustrated in FIG. 16, the first color functional element 201 is a functional element that exits red light, the second color functional element 202 is a functional element that exits green light, and the first distance is greater than the second distance; or, the first color functional element 201 is a functional element that exits green light, the second color functional element 202 is a functional element that exits red light, and the first distance is greater than the second distance.

For example, the distance between the center of the first defining portion 3010 and the center of the recessed region 021 between adjacent light-emitting elements of one color arranged along the Y direction is different from the distance between the center of the first defining portion 3010 and the center of the recessed region 021 between adjacent light-emitting elements of another color arranged along the Y direction.

For example, the distance between the center of the first defining portion 3010 and the center of the recessed region 021 which are located between adjacent blue light-emitting elements arranged along the Y direction is greater than the distance between the center of the first defining portion 3010 and the center of the recessed region 021 which are located between adjacent green light-emitting elements arranged along the Y direction. For example, the distance between the center of the first defining portion 3010 and the center of the recessed region 021 which are located between adjacent blue light-emitting elements arranged along the Y direction is greater than the distance between the center of the first defining portion 3010 and the center of the recessed region 021 which are located between adjacent red light-emitting elements arranged along the Y direction.

For example, the distance between the center of the first defining portion 3010 and the center of the recessed region 021 which are located between adjacent green light-emitting elements arranged along the Y direction may be greater than the distance between the center of the first defining portion 3010 and the center of the recessed region 021 which are located between adjacent red light-emitting elements arranged along the Y direction, but not limited thereto, the distance between the center of the first defining portion 3010 and the center of the recessed region 021 which are located between adjacent green light-emitting elements arranged along the Y direction may be equal to or less than the distance between the center of the first defining portion 3010 and the center of the recessed region 021 which are located between adjacent red light-emitting elements arranged along the Y direction.

For example, the distance between the center of the first defining portion 3010 and the center of the recessed region 021 which are located between adjacent blue light-emitting elements arranged along the Y direction is 10-40 microns, such as 12-38 microns, such as 15-30 microns, such as 18-28 microns, such as 20-25 microns. For example, the distance between the center of the first defining portion 3010 and the center of the recessed region 021 which are located between adjacent red light-emitting elements arranged along the Y direction is 5-25 microns, such as 8-22 microns, such as 10-20 microns, such as 12-18 microns, such as 14-15 microns. For example, the distance between the center of the first defining portion 3010 and the center of the recessed region 021 which are located between adjacent green light-emitting elements arranged along the Y direction is 5-25 microns, such as 8-22 microns, such as 10-20 microns, such as 12-18 microns, such as 14-15 microns.

For example, in the case where the dimensions (such as width) of light-emitting regions of the blue light-emitting element, the green light-emitting element, and the red light-emitting element along the X direction are different from each other, the distances between the center of the recessed region 021 and the center of the light-emitting region are different from each other, and the distances between the center of the first defining portion 3010 and the center of the recessed region 021 between the light-emitting elements of the same color are different from each other. The embodiments of the present disclosure adjust the distance between the center of the first defining portion and the center of the recessed region according to the widths of the light-emitting regions of the light-emitting elements of different colors, which is beneficial to match the evaporation rate of at least one film layer (such as ink) of the light-emitting functional layer.

In some examples, as illustrated in FIG. 16, the first color light-emitting element 201 is a blue light-emitting element, and the second color light-emitting element 202 is a green light-emitting element or a red light-emitting element; and the first distance is greater than the distance between the center of the light-emitting region of the light-emitting element 200 of another color and the center of the recessed region 021 corresponding to the light-emitting region. For example, the area of the light-emitting region of the blue light-emitting element 201 is greater than the area of the light-emitting region of the light-emitting element 200 of another color.

For example, the distance between the center of the light-emitting region of the blue light-emitting element 201 and the center of the recessed region 021 corresponding to the light-emitting region is greater than the distance between the center of the light-emitting region of the red light-emitting element and the center of the recessed region 021 corresponding to the light-emitting region; for example, the distance between the center of the light-emitting region of the blue light-emitting element 201 and the center of the recessed region 021 corresponding to the light-emitting region is greater than the distance between the center of the light-emitting region of the green light-emitting element and the center of the recessed region 021 corresponding to the light-emitting region.

For example, the distance between the center of the light-emitting region of the green light-emitting element and the center of the recessed region 021 corresponding to the light-emitting region, and the distance between the center of the light-emitting region of the red light-emitting element and the center of the recessed region 021 corresponding to the light-emitting region are determined according to the dimensions of the areas of the light-emitting region of the red light-emitting element and the light-emitting region of the green light-emitting element. For example, the area of the light-emitting region of the green light-emitting element is smaller than the area of the light-emitting region of the red light-emitting element, and the distance between the center of the light-emitting region of the green light-emitting element and the center of the recessed region 021 corresponding to the light-emitting region is less than the distance between the center of the light-emitting region of the red light-emitting element and the center of the recessed region 021 corresponding to the light-emitting region.

In some examples, as illustrated in FIG. 16, the orthographic projections of some recessed regions 021 of a plurality of recessed regions 021 on a straight line extending in the first direction are overlapped with each other, and the distance between adjacent recessed regions 021 of the some recessed regions 021 is in a range of 2-50 microns. For example, the distance between adjacent recessed regions 021 of the some recessed regions 021 is 5-48 microns, such as 7-45 microns, such as 10-42 microns, such as 12-40 microns, such as 15-35 microns, such as 20-30 microns, such as 22-28 microns, such as 25-27 microns.

For example, as illustrated in FIG. 16, the distance between the adjacent recessed regions 021, arranged in the second direction, of a plurality of recessed regions 021 is in a range of 2-50 microns. For example, the distance between the adjacent recessed regions 021, arranged in the second direction, of a plurality of recessed regions 021 is 10-48 microns, such as 20-45 microns, such as 22-42 microns, such as 25-40 microns, such as 28-37 microns, such as 30-35 microns.

For example, as illustrated in FIG. 16, the recessed regions 021 arranged in the second direction are not equally spaced. For example, the recessed regions 021 arranged in the first direction are equally spaced.

For example, the above-mentioned “the recessed regions arranged in the second direction” includes that the recessed regions are strictly arranged in the second direction, and the recessed regions are approximately arranged in the second direction; and the fact that the recessed regions are approximately arranged in the second direction means that a connection line extending through the centers of these recessed regions is not a straight line parallel to the second direction.

In some examples, as illustrated in FIG. 16, the orthographic projection of at least one light-exiting region on a straight line extending in the second direction overlaps with an orthographic projection of a recessed region 021 corresponding to the at least one light-exiting region on the straight line extending in the second direction.

For example, the orthographic projection of at least one light-emitting region on a straight line extending in the second direction overlaps with an orthographic projection of a recessed region 021 corresponding to the at least one light-emitting region on the straight line extending in the second direction. For example, the recessed region 021 corresponding to the light-emitting region is located in a region between extension lines of two edges of the light-emitting region extending along the Y direction.

In some examples, as illustrated in FIG. 16, a virtual straight line VL parallel to the first direction passes through a light-exiting region and a recessed region 021 closest to the light-exiting region, edges close to each other of the light-exiting region and the recessed region 021 intersect with the virtual straight line VL to form two intersection points P1 and P2, and the distance between the two intersection points P1 and P2 is greater than the distance DP between the orthographic projection of the light-exiting region on a straight line extending in the first direction and the orthographic projection of the recessed region 021 on the straight line extending in the first direction. In the embodiments of the present disclosure, the recessed region is distributed in a larger region of the second region in the first direction, which can not only facilitate the setting of the area of the recessed region, but also reduce the impact of the recessed region on the light-emitting region of the adjacent light-emitting elements in the first direction.

For example, as illustrated in FIG. 16, the second color sub-pixel 202 may be a red sub-pixel, and the display substrate further includes a third color sub-pixel 203, and the third color sub-pixel 203 may be a green sub-pixel. For example, the first color sub-pixels 201, the second color sub-pixels 202 and the third color sub-pixels 203 are sequentially and circularly arranged in the second direction.

For example, as illustrated in FIG. 16, a recessed region 021 corresponding to the first color sub-pixel 201 is a first recessed region 021-1, a recessed region 021 corresponding to the second color sub-pixel 202 is a second recessed region 021-2, a recessed region 021 corresponding to the third color sub-pixel 203 is a third recessed region 021-3, and the distance between the first recessed region 021-1 and the second recessed region 021-2 immediately adjacent to the first recessed region 021-1 is different from the distance between the first recessed region 021-1 and the third recessed region 021-3 immediately adjacent to the first recessed region 021-1.

For example, the distance between the second recessed region 021-2 and the third recessed region 021-3 adjacent to each other is less than the distance between the first recessed region 021-1 and the second recessed region 021-2 adjacent to each other, and greater than the distance between the first recessed region 021-1 and the third recessed region 021-3 adjacent to each other. Here, the distance between adjacent recessed regions may be the distance between the centers of the recessed regions.

In some examples, as illustrated in FIG. 16, the distance between the light-exiting region of the functional element 200 and a nearest adjacent recessed region 021 corresponding to the functional element 200 is less than 30 microns.

In some examples, as illustrated in FIG. 16, the distance between the light-emitting region of the light-emitting element 200 and the recessed region 021 corresponding to the light-emitting element 200 is less than 30 microns. For example, the distance between the light-emitting region of the light-emitting element 200 and the recessed region 021 corresponding to the light-emitting element 200 is less than 25 microns, such as less than 20 microns, such as less than 15 microns, such as less than 10 microns, such as less than 5 microns.

FIG. 17 is a schematic diagram of a partial planar structure of a display substrate provided by another example of an embodiment of the present disclosure. For the sake of clarity, FIG. 17 only schematically illustrates positions of the pixel-defining pattern, the recessed region and the light-emitting element, but does not illustrate the light-emitting functional layer, the first electrode and the second electrode included in the light-emitting element.

For example, the difference between the display substrate illustrated in FIG. 17 and the display substrate illustrated in FIG. 16 is that the light-emitting region of one light-emitting element 200 in the display substrate illustrated in FIG. 16 corresponds to one recessed region 021, and the light-emitting region of at least one light-emitting element 200 in the display substrate in FIG. 17 corresponds to two or more recessed regions 021. For example, as illustrated in FIG. 17, the light-emitting region of each light-emitting element 200 corresponds to two recessed regions 021.

In some examples, as illustrated in FIG. 17, at least two recessed regions 021 are provided between the light-exiting regions of adjacent functional elements 200 with the same light-exiting color, and the at least two recessed regions 021 are located on at least one side of the center of the first defining portion 3010.

For example, as illustrated in FIG. 17, two recessed regions 021 are provided between the light-emitting regions of adjacent light-emitting elements 200 with the same light-emitting color, and the two recessed regions 021 are located on at least one side of the center of the first defining portion 3010. For example, the two recessed regions 021 are located on both sides of the center of the first defining portion 3010.

In some examples, as illustrated in FIG. 17, the nearest distance DD1 between at least two adjacent recessed regions 021 is less than the distance DD2 from one recessed region 021 of the at least two adjacent recessed regions 021 to a light-exiting region close to the one recessed region. For example, the distance between adjacent recessed regions 021 may be the distance between the opposite edges of adjacent recessed regions 021, or the distance between the centers of adjacent recessed regions 021. For example, the distance between the recessed region 021 and the light-exiting region may be the distance between opposite edges of the recessed region 021 and the light-exiting region, or the distance between the center of the recessed region 021 and the edge of the light-exiting region.

In some examples, at least part of the opposite edges of two adjacent light-exiting regions are not parallel, and the distance between the part of the opposite edges of the two light-exiting regions close to a first end is greater than the distance between the part of the opposite edges of the two light-exiting regions close to a second end, then the recessed region is provided at the side of the first end where the distance between the opposite edges of the two light-exiting regions is relatively larger; or relative to a center connection line of the two light-exiting regions, the center of the recessed region deviates to the side of the first end where the distance between the opposite edges of the two light-exiting regions is relatively larger. By arranging the recessed region on the side where the distance between the opposite edges of the two adjacent light-exiting regions is relatively far can provide more space for the recessed region, so that the dimension of the recessed region can be designed according to requirements, and the recessed region can be as far away from the light-exiting region as possible, so as to avoid the unevenness of the light-exiting region caused by the shape of the recessed region, as well as avoid problems such as poor printing process or color shift of display.

For example, as illustrated in FIG. 17, the recessed region 021 can not only be located between the light-emitting regions of adjacent light-emitting elements 200 with the same light-emitting color, but the recessed region 021 can also be located between the light-emitting regions of adjacent light-emitting elements 200 with different light-emitting colors.

For example, as illustrated in FIG. 17, a line of light-emitting elements 200 arranged along the X direction among the plurality of light-emitting elements 200 is a row of light-emitting elements 200, and a line of light-emitting elements 200 arranged along the Y direction among the plurality of light-emitting elements 200 is a column of light-emitting elements 200. A plurality of recessed regions 021 are provided between adjacent rows of light-emitting elements 200, and/or a plurality of recessed regions 021 are provided between adjacent columns of light-emitting elements 200. For example, the recessed region 021 is provided between adjacent first defining portions 3010.

For example, as illustrated in FIG. 16 and FIG. 17, the shape of the orthographic projection of the recessed region 021 on the base substrate may be an ellipse, a circle, a square, a strip, a rhombus, a trapezoid or other shapes.

For example, as illustrated in FIG. 16 and FIG. 17, the shape of the orthographic projection of the recessed region 021 on the base substrate may be an ellipse, and the major axis of the ellipse may be parallel to the Y direction or the X direction.

In some examples, as illustrated in FIG. 16 and FIG. 17, a portion, located between light-emitting regions of adjacent light-emitting elements 200 with different light-emitting colors, in the defining portion 320 is a second defining portion 3020, and the extending direction of at least part of the second defining portion 3020 is identical to the arrangement direction of two adjacent light-emitting elements 200 with different light-emitting colors. The second defining portion 3020 in the display substrate provided in the present embodiment may include the first sub-defining portion 321 and the second sub-defining portion 322 in the above-mentioned embodiments.

For example, the second defining portion 3020 is called high bank, and the first defining portion 3010 is called low bank. For example, the transition between high bank and low bank is slow, as illustrated in FIG. 17, the portion with the same dimension (such as width) of the light-emitting region in the X direction is the first defining portion 3010, and the portion exceeding the width of the light-emitting region is the second defining portion 3020.

For example, as illustrated in FIG. 16 and FIG. 17, the second defining portion 3020 includes a portion between the light-emitting elements 200 of different colors and a portion surrounding the edge of the display region where the plurality of light-emitting elements 200 are located.

In some examples, as illustrated in FIG. 17, the orthographic projection of at least part of the at least one recessed region 021 on the base substrate overlaps with the orthographic projection of the second defining portion 3020 on the base substrate, or the orthographic projection of the at least one recessed region 021 on the base substrate is contiguous with the orthographic projection of the second defining portion 3020 on the base substrate.

For example, as illustrated in FIG. 17, a part of the orthographic projection of the recessed region 021 on a straight line extending along the X direction does not overlap with the orthographic projection of the light-emitting region on the straight line.

In some examples, as illustrated in FIG. 17, the orthographic projection of at least one recessed region 021 on the base substrate completely falls within the orthographic projection of the second defining portion 3020 on the base substrate.

For example, as illustrated in FIG. 17, the dimension of the recessed region 021 along the X direction is not greater than the dimension of the second defining portion 3020 along the X direction. For example, the dimension of the recessed region 021 along the X direction is less than 20 microns, such as less than 18 microns, such as less than 16 microns, such as less than 15 microns, such as less than 14 microns.

For example, as illustrated in FIG. 16 and FIG. 17, the dimension of at least part of the recessed region 021 along the Y direction is not greater than the dimension thereof along the X direction.

For example, as illustrated in FIG. 16 and FIG. 17, the ratio of the dimension of the recessed region 021 along the X direction to the dimension of the recessed region 021 along the Y direction is 0.8-1.2. For example, the ratio of the dimension of the recessed region 021 along the X direction to the dimension of the recessed region 021 along the Y direction is 0.9-1.1. For example, the dimension of the recessed region 021 along the X direction is identical to the dimension of the recessed region 021 along the Y direction.

In some examples, as illustrated in FIG. 17, the distance between the recessed region 021 and a center of the first defining portion 3010 which are located between light-emitting regions of adjacent light-emitting elements 200 with the same light-emitting color is greater than the distance between the recessed region 021 and the second defining portion 3020.

In some examples, as illustrated in FIG. 16 and FIG. 17, the shape of the orthographic projection of the at least one recessed region 021 on the base substrate is a symmetrical pattern. For example, the orthographic projection of at least one recessed region 021 on the base substrate is an axisymmetric pattern, and the symmetry axis of the axisymmetric pattern is parallel to the X direction or the Y direction.

In some examples, as illustrated in FIG. 17, the orthographic projection of the at least one recessed region 021 on the base substrate includes a first orthographic projection sub-portion 0211 close to a light-emitting region of a light-emitting element 200 corresponding to the recessed region 021, and a second orthographic projection sub-portion 0212 away from the light-emitting region of the light-emitting element 200 corresponding to the recessed region 021. For example, the first orthographic projection sub-portion 0211 and the second orthographic projection sub-portion 0212 are an integral structure.

In some examples, as illustrated in FIG. 17, in the arrangement direction of two adjacent light-emitting elements 200 with different light-emitting colors, the average dimension of the first orthographic projection sub-portion 0211 is greater than the average dimension of the second orthographic projection sub-portion 0212. For example, along the X direction, the average dimension of the first orthographic projection sub-portion 0211 is greater than the average dimension of the second orthographic projection sub-portion 0212. For example, along the X direction, the maximum dimension of the first orthographic projection sub-portion 0211 is greater than the maximum dimension of the second orthographic projection sub-portion 0212.

For example, as illustrated in FIG. 17, the orthographic projection of the recessed region 021 corresponding to the blue light-emitting element 201 is provided with the first orthographic projection sub-portion 0211 and second orthographic projection sub-portion 0212 mentioned above.

In the embodiments of the present disclosure, adjusting the planar shape of the recessed region is beneficial to balance the drying speed of at least one layer (ink layer) of the light-emitting functional layer in the light-emitting region of the light-emitting element corresponding to recessed region. Further, adjusting the planar shape of the recessed region corresponding to the light-emitting element with a larger light-emitting region is beneficial to balance the drying speed of the ink layers of the light-emitting elements of different colors.

FIG. 18 and FIG. 19 are schematic diagrams of partial cross-sectional structures along a line GG′ in different examples of the display substrate illustrated in FIG. 16. FIG. 18 and FIG. 19 illustrate the first electrode 210, the second electrode 220 and the light-emitting functional layer 230 included in the light-emitting element.

In some examples, as illustrated in FIG. 16 and FIG. 18, the thicknesses of portions of the at least one film layer on the base substrate located in the recessed region 021 and located in another region outside the recessed region 021 are a first sub-thickness and a second sub-thickness, and the first sub-thickness is less than the second sub-thickness; or at least one film layer on the base substrate includes a portion located in the light-exiting region, and the at least one film layer does not overlap with at least part of the recessed region 021.

For example, as illustrated in FIG. 16 and FIG. 18, the thickness of at least one film layer, between the light-emitting functional layer 230 and the base substrate 100, located in the recessed region 021 is a first sub-thickness, the thickness of the at least one film layer, between the light-emitting functional layer 230 and the base substrate 100, located in another region outside the recessed region 021 is a second sub-thickness, and the first sub-thickness is less than the second sub-thickness. For example, the at least one film layer is the first electrode 210. For example, the thickness of a portion of the first electrode 210 located in the recessed region 021 is less than the thickness of a portion of the first electrode 210 located in the light-emitting region. For example, the amount of layers of the portion of the first electrode 210 located in the recessed region 021 is less than the amount of layers of the portion of the first electrode 210 located in the light-emitting region.

For example, as illustrated in FIG. 16 and FIG. 19, at least one film layer between the light-emitting functional layer 230 and the base substrate 100 includes a portion located in the light-emitting region of the light-emitting element 200, and the at least one film layer does not overlap with the recessed region 021. For example, the at least one film layer is the first electrode 210. For example, the first electrode 210 does not include a portion located in the recessed region 021.

Of course, the embodiments of the present disclosure are not limited thereto, and the at least one film layer may also be an insulating layer or an organic layer, such as at least one layer of a planarization layer and a defining portion.

In some examples, as illustrated in FIG. 16 and FIG. 18, the thickness of at least one film layer in the recessed region 021 is less than the thickness of at least one film layer in a region where the second defining portion 3020 is located; or the at least one film layer is located in the region where the second defining portion 3020 is located, and the at least one film layer does not overlap with at least part of the recessed region 021.

In some examples, as illustrated in FIG. 16 and FIG. 18, the thickness of a portion of at least one film layer, on a side of the first electrode 210 away from the base substrate 100, located in the recessed region 021 is a third sub-thickness, the thickness of a portion of the at least one film layer, on the side of the first electrode 210 away from the base substrate 100, located in another region outside the recessed region 021 is a fourth sub-thickness, and the third sub-thickness is greater than the fourth sub-thickness.

In some examples, as illustrated in FIG. 16 and FIG. 18, at least one film layer on the side of the first electrode 210 away from the base substrate 100 includes at least one of an organic layer and the light-emitting functional layer 230.

For example, as illustrated in FIG. 18, at least one film layer on the side of the first electrode 210 away from the base substrate 100 is the light-emitting functional layer 230, and the thickness of a portion of the light-emitting functional layer 230 located in the recessed region 021 is greater than the thickness of a portion of the light-emitting functional layer 230 located in another region outside the recessed region 021.

In some examples, as illustrated in FIG. 16 and FIG. 18, at least one film layer on the side of the first electrode 210 away from the base substrate 100 includes the defining portion 320.

For example, at least one film layer on the side of the first electrode 210 away from the base substrate 100 is the defining portion 320, and the thickness of a portion of the defining portion 320 located in the recessed region 021 is greater than the thickness of a portion of the defining portion 320 located in another region except the recessed region 021 and the light-emitting region.

In some examples, as illustrated in FIG. 16 and FIG. 18, the maximum thickness of a portion of the at least one film layer of the light-emitting functional layer 230 located in the recessed region 021 is a first maximum thickness, the maximum thickness of a portion of the at least one film layer of the light-emitting functional layer located in a light-emitting region (such as the light-emitting region of the third color light-emitting element 203) of a light-emitting element 200 corresponding to the recessed region 021 is a second maximum thickness, and the first maximum thickness is not less than the second maximum thickness. For example, the first maximum thickness is greater than the second maximum thickness. For example, at least one film layer of the light-emitting functional layer 230 in the present embodiment is the first film layer 231.

In some examples, as illustrated in FIG. 16 and FIG. 18, the maximum thickness H01 of an entire portion of the light-emitting functional layer 230 located in the recessed region 021 is not less than the maximum thickness H02 of an entire portion of the light-emitting functional layer 230 located in a light-emitting region of a light-emitting element 200 corresponding to the recessed region 021. For example, the above-mentioned maximum thickness H01 is greater than the above-mentioned maximum thickness H02.

In some examples, as illustrated in FIG. 16 and FIG. 19, the distance between a surface, of a portion of at least one film layer of the light-emitting functional layer 230 located in the recessed region 021, away from the base substrate 100 and the base substrate 100 is a third distance D03, the distance between a surface, of a portion of the at least one film layer of the light-emitting functional layer 230 located in a light-emitting region of a light-emitting element 200 corresponding to the recessed region 021, away from the base substrate 100 and the base substrate 100 is a fourth distance D04, and the fourth distance D04 is greater than the third distance D03.

For example, as illustrated in FIG. 19, in a surface of a side of the first film layer 231 in the light-emitting functional layer 230 farthest away from the base substrate 100, a portion located in the recessed region 021 is closer to the base substrate 100 than a portion located in a light-emitting region corresponding to the recessed region 021. For example, in a surface of a side of the light-emitting functional layer 230 farthest away from the base substrate 100, a portion located in the recessed region 021 is closer to the base substrate 100 than a portion located in a light-emitting region corresponding to the recessed region 021.

FIG. 20 is a schematic diagram of a partial cross-sectional structure along a line HH′ illustrated in FIG. 16. For the sake of clarity, FIG. 20 does not illustrate all the layers of the light-emitting functional layer and the second electrode.

In some examples, as illustrated in FIG. 16, FIG. 19, and FIG. 20, a surface of a side, of a portion of the second defining portion 3020 close to the light-emitting region, away from the base substrate 100 includes a defining slope 3021, the distance between a surface of a side, of a portion of at least one film layer of the light-emitting functional layer 230 located at the defining slope 3021, away from the base substrate 100 and the base substrate 100 is a fifth distance D05, and the fifth distance D05 is greater than the fourth distance D04. The defining slope 3021 here may be the second sub-defining portion 322 in the above-mentioned embodiments.

For example, as illustrated in FIG. 16, FIG. 19, and FIG. 20, a surface of a side, of a portion of the first film layer 231 of the light-emitting functional layer 230 located at the defining slope 3021, away from the base substrate 100 is farther away from the base substrate 100 than a surface of a side, of a portion of the first film layer 231 of the light-emitting functional layer 230 located in the light-emitting region, away from the base substrate 100. For example, in the surface of the side of the light-emitting functional layer 230 farthest away from the base substrate 100, a portion located in the light-emitting region is closer to the base substrate 100 than a portion located at the defining slope 3021.

In some examples, as illustrated in FIG. 16, FIG. 19, and FIG. 20, a surface of a side, of a portion of the second defining portion 3020 close to the light-emitting region, away from the base substrate 100 includes a defining slope 3021, the maximum thickness of a portion of at least one film layer of the light-emitting functional layer 230 located at the defining slope 3021 is a third maximum thickness, and the third maximum thickness is less than the second maximum thickness of a portion of at least one film layer of the light-emitting functional layer 230 located in the light-emitting region.

For example, as illustrated in FIG. 16, FIG. 19, and FIG. 20, the thickness of a portion of the first film layer 231 in the light-emitting functional layer 230 located on the second defining portion 3020 is less than the thickness of a portion of the first film layer 231 in the light-emitting functional layer 230 located in the light-emitting region.

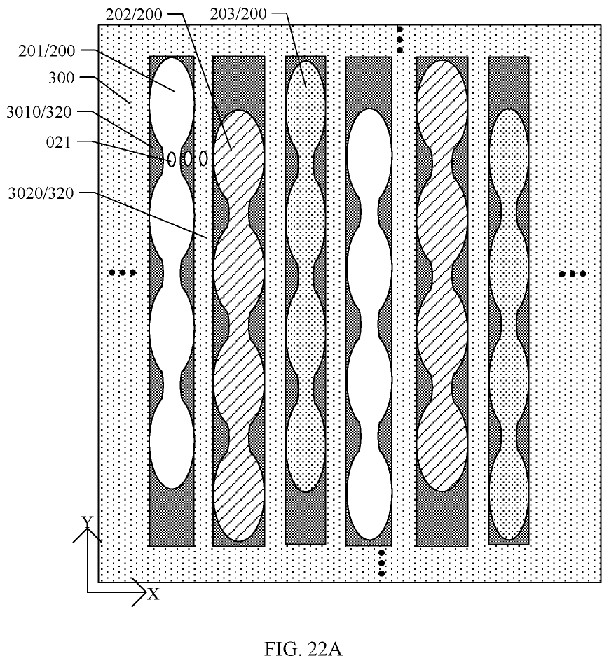

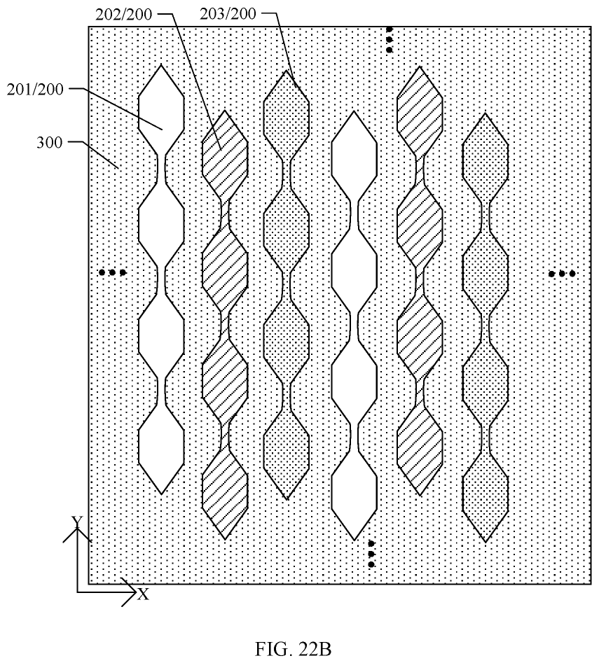

FIG. 21 is a schematic diagram of a partial cross-sectional structure along a line II′ illustrated in FIG. 17. For the sake of clarity, FIG. 21 does not illustrate the light-emitting element.

In some examples, as illustrated in FIG. 17 and FIG. 21, in the direction perpendicular to the base substrate 100, the thickness H06 of a portion of the second defining portion 3020 located in the recessed region 021 is greater than the thickness H05 of a portion of the second defining portion 3020 located in another region except the recessed region 021. Here, the thickness H06 and the thickness H05 may be the maximum thickness or the average thickness.

In some examples, as illustrated in FIG. 17 and FIG. 21, the thickness of the portion of the defining portion 320 (such as the first defining portion 3010 or the second defining portion 3020) located in the recessed region 021 is at least 0.2 microns thicker than the thickness of a portion (such as the second defining portion 3020) of the defining portion 320 located between light-emitting regions of adjacent light-emitting elements 200 with different light-emitting colors. For example, the defining portion 320 located in the recessed region 021 may be the first defining portion 3010 or the second defining portion 3020.

For example, the thickness of the defining portion 320 in the recessed region 021 is at least 0.2 microns thicker than the thickness of the second defining portion 3020. For example, the thickness of the defining portion 320 in the recessed region 021 is at least 0.3 microns thicker than the thickness of the second defining portion 3020. For example, the thickness of the defining portion 320 in the recessed region 021 is at least 0.4 microns thicker than the thickness of the second defining portion 3020. For example, the thickness of the defining portion 320 in the recessed region 021 is at least 0.5 microns thicker than the thickness of the second defining portion 3020. For example, the thickness of the defining portion 320 in the recessed region 021 is at least 0.6 microns thicker than the thickness of the second defining portion 3020. For example, the thickness of the defining portion 320 in the recessed region 021 is at least 0.7 microns thicker than the thickness of the second defining portion 3020. For example, the thickness of the defining portion 320 in the recessed region 021 is at least 0.8 microns thicker than the thickness of the second defining portion 3020. For example, the thickness of the defining portion 320 in the recessed region 021 is at least 0.9 microns thicker than the thickness of the second defining portion 3020. For example, the thickness of the defining portion 320 in the recessed region 021 is at least 1 micron thicker than the thickness of the second defining portion 3020. For example, the thickness of the defining portion 320 in the recessed region 021 is at least 1.1 microns thicker than the thickness of the second defining portion 3020. For example, the thickness of the defining portion 320 in the recessed region 021 is at least 1.2 microns thicker than the thickness of the second defining portion 3020. For example, the thickness of the defining portion 320 in the recessed region 021 is at least 1.3 microns thicker than the thickness of the second defining portion 3020. For example, the thickness of the defining portion 320 in the recessed region 021 is at least 1.4 microns thicker than the thickness of the second defining portion 3020. For example, the thickness of the defining portion 320 in the recessed region 021 is at least 1.5 microns thicker than the thickness of the second defining portion 3020.

In some examples, as illustrated in FIG. 17 and FIG. 21, the height, relative to the base substrate 100, of the portion of the defining portion 320 located in the recessed region 021 is at least 1 micron lower than the height, relative to the base substrate 100, of the portion of the defining portion 320 located between light-exiting regions of adjacent functional elements 200 with different light-exiting colors.

For example, as illustrated in FIG. 17 and FIG. 21, the distance H07 between the surface of the side of the portion of the defining portion 320, located in the recessed region 021, away from the base substrate 100 and the base substrate 100 is at least 1 micron less than the distance H08 between the surface of the side of the portion of the defining portion 320, located between light-emitting regions of adjacent light-emitting elements 200 with different light-emitting colors, and the base substrate 100, such as 2 microns less, such as 3 microns less, such as 4 microns less, such as 5 microns less, such as 6 microns less, such as 7 microns less, such as 8 microns less, such as 9 microns less, such as 10 microns less, such as 11 microns less, such as 12 microns less, such as 13 microns less, such as 14 microns less, such as 15 microns less, such as 16 microns less, such as 17 microns less, such as 18 microns less, such as 19 microns less, such as 20 microns less.

In some examples, as illustrated in FIG. 17 and FIG. 21, the lyophobicity of the portion of the defining portion 320 located in the recessed region 021 is not lower than the lyophobicity of the portion of the defining portion 320 located between light-emitting regions of adjacent light-emitting elements 200 with different light-emitting colors.

For example, the lyophobicity of the portion of the defining portion 320 located in the recessed region 021 is higher than the lyophobicity of the portion of the defining portion 320 located between light-emitting regions of adjacent light-emitting elements 200 with different light-emitting colors.

For example, as illustrated in FIG. 21, the recessed region 021 is contiguous with the second defining portion 3020, or the second defining portion 3020 includes a portion located in the recessed region 021, and the thickness of the portion of the second defining portion 3020 located in the recessed region 021 is greater than the thickness of the portion of the second defining portion 3020 located outside the recessed region 021, in order to make the lyophobicity of the defining portion located in the recessed region more better, and to prevent at least one layer (such as an ink layer) of the light-emitting functional layer in the recessed region from overflowing to the second defining portion, thereby affecting the display of the light-emitting region.

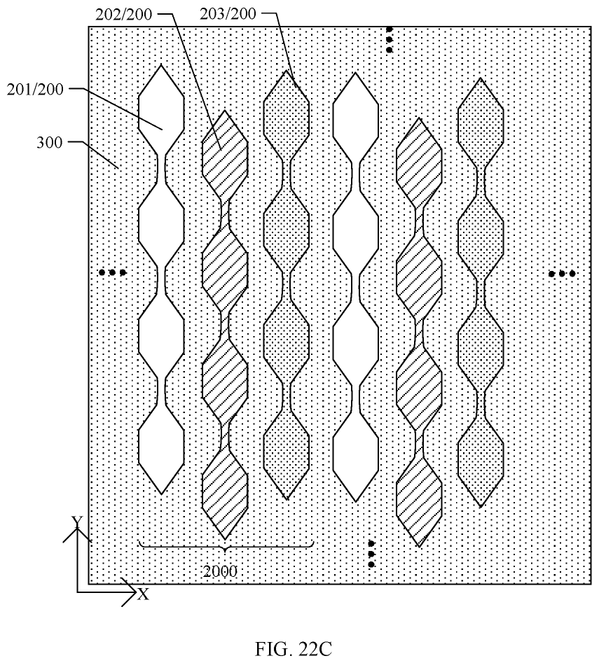

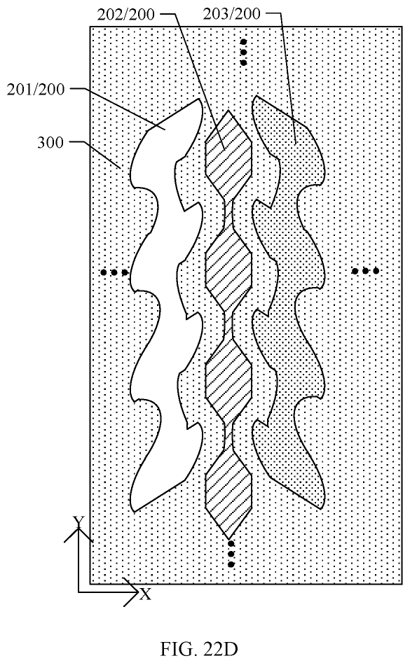

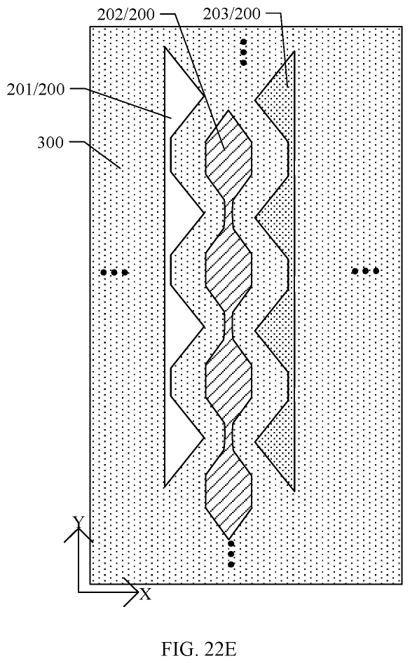

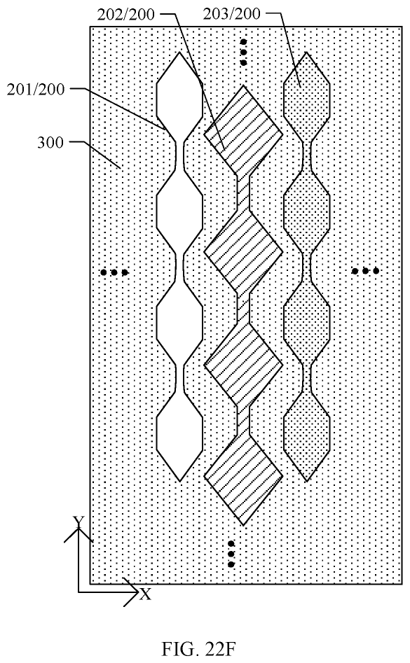

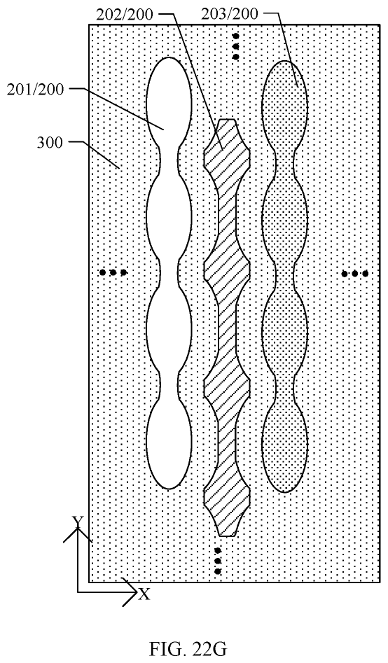

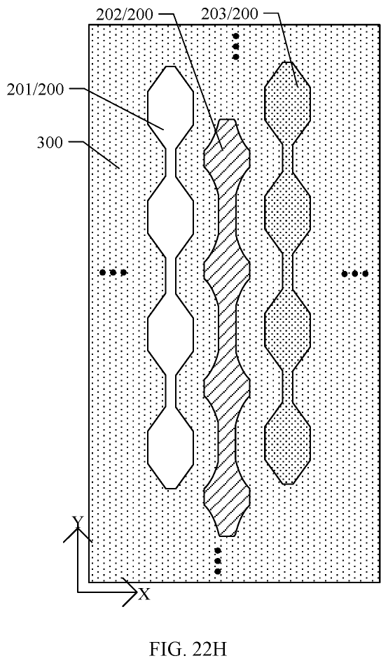

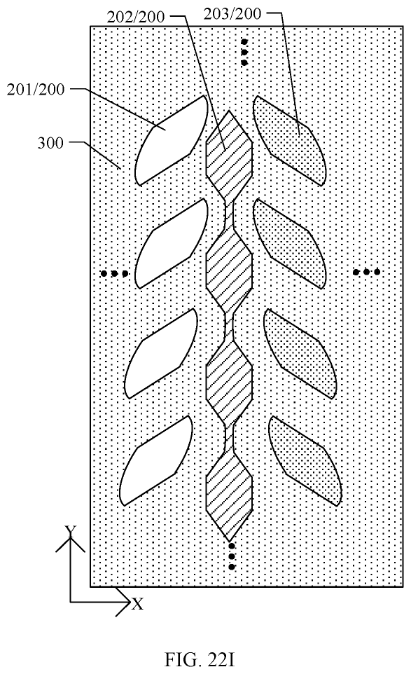

FIG. 22A-FIG. 22J are schematic diagrams of partial planar structures of some film layers of light-emitting functional layers in display substrates provided by different examples of the embodiments of the present disclosure. The difference between the display substrate illustrated in FIG. 22A-FIG. 22J and the display substrate illustrated in FIG. 16 mainly includes the difference in the shape of the light-emitting region of the light-emitting element 200. FIG. 22A illustrates the first defining portion 3010 and the second defining portion 3020 included in the defining portion 320, and FIG. 22B-FIG. 22J only illustrate the defining portion 320 of the pixel-defining pattern 300, without illustrating the first defining portion 3010 and the second defining portion 3020.

For example, as illustrated in FIG. 22A-FIG. 22H, the light-emitting elements 200 arranged along the Y direction are light-emitting elements 200 that emit light of the same color, and at least one layer of the light-emitting functional layers of these light-emitting elements 200 is a continuous film layer, such as ink. The light-emitting elements 200 arranged along the X direction are light-emitting elements 200 that emit light of different colors, and at least one layer of the light-emitting functional layers of these light-emitting elements 200 can be film layers arranged at intervals. FIG. 16 does not illustrate whether the light-emitting functional layer of the light-emitting element includes a continuous film layer, the light-emitting functional layer illustrated in FIG. 16-FIG. 17 may include a continuous film layer or may not include a continuous film layer, and the embodiments of the present disclosure are not limited in this aspect.

For example, as illustrated in FIG. 22I, the light-emitting elements 200 arranged along the Y direction are light-emitting elements 200 that emit light of the same color, and at least one layer of the light-emitting functional layer of the light-emitting element 200 of at least one color is a continuous film layer, such as ink. For example, at least one layer of the light-emitting functional layer of the light-emitting element 200 of only one color is a continuous film layer, or at least one layer of the light-emitting functional layers of the light-emitting elements 200 of two colors is a continuous film layer.

For example, as illustrated in FIG. 22J, the light-emitting functional layers of the light-emitting elements 200 of the same color are discontinuous film layers.

For example, as illustrated in FIG. 22A, the recessed region 021 may be located in a region where the continuous film layer of the light-emitting elements 200 of the same color is located, and may also be located in a region outside the region where the continuous film layer is located. For example, the region outside the region where the continuous film layer is located may include the region of the first defining portion 3010, and may also include the region of the second defining portion 3020.

For example, as illustrated in FIG. 22A-FIG. 22J, the shape of the light-emitting region is an ellipse or a polygon, such as a hexagon, a quadrangle, a triangle, an octagon, etc. For example, the edges of the outline of the light-emitting region may be all straight edges, or may be all curved edges, or may include both straight edges and curved edges.

For example, the outline of the light-emitting region may be a symmetrical pattern, or an asymmetrical pattern, for example, the outlines of the light-emitting regions of the second color light-emitting element 202 and the third color light-emitting element 203 illustrated in FIG. 22J are asymmetric patterns, and the outline of the light-emitting region of the first color light-emitting element 201 illustrated in FIG. 22J is a symmetrical pattern. For example, as illustrated in FIG. 22J, the outline of the light-emitting region of the first color light-emitting element 201 includes both straight edges and curved edges, the outline of the light-emitting region of the second color light-emitting element 202 only includes straight edges, and the outline of the light-emitting region of the third color light-emitting element 202 includes only curved edges. FIG. 22J only schematically illustrates the arrangement of the light-emitting regions, and the light-emitting regions of the light-emitting elements of at least one color can also be rotated by a certain angle, such as 30-90 degrees, or flipped along the X direction or the Y direction.

The shape of the light-emitting region in the embodiments of the present disclosure may be symmetrical in the length direction of the light-emitting region and asymmetrical in the width direction of the light-emitting region. For example, the light-emitting regions of the light-emitting elements of the same color are arranged in the column direction, the light-emitting regions of the light-emitting elements of different colors are arranged in the row direction, and the shape of at least part of the light-emitting regions is symmetrical relative to the row direction and asymmetrical relative to the column direction. In the embodiments of the present disclosure, for three adjacent consecutive columns of light-emitting regions of different colors, the shape of one column of light-emitting regions includes at least two symmetry axes, and the shape of two adjacent columns of light-emitting regions on both sides of the column includes at most one symmetry axis. For example, the light-emitting region emitting green light include at least two symmetry axes. Because the human eyes are more sensitive to green, and the uniformity of the distribution of green light-emitting elements has the greatest impact on display uniformity, the shape symmetry of the light-emitting region that emits green light is better. For example, the shape of the light-emitting region of the green light-emitting element is one of a rectangle, a hexagon, an octagon, an ellipse and a circle. For example, for the light-emitting regions of three adjacent consecutive columns of the light-emitting elements of different colors, the light-emitting regions of at least two columns overlap in the projection in the row direction. For example, for three adjacent consecutive columns of light-emitting regions of different colors, the projection of the light-emitting region emitting red light overlaps with the projection of the light-emitting region emitting green light. For example, for three adjacent consecutive columns of light-emitting regions of different colors, the projection of the light-emitting region emitting blue light overlaps with the projection of the light-emitting region emitting green light. For example, for three adjacent consecutive columns of light-emitting regions of different colors, the projection of the light-emitting region emitting red light overlaps with the projection of the light-emitting region emitting green light, and the projection of the light-emitting region emitting blue light overlaps with the projection of the light-emitting region emitting green light.

The embodiments of the present disclosure are not limited to the case that the shape of the light-emitting region of the light-emitting element is only the shape illustrated in the figures, the shape of the light-emitting region of the light-emitting element may be various combinations of the straight edge and the curved edge, the shape of the light-emitting region may be symmetrical or asymmetrical, the shapes of the light-emitting regions of the light-emitting elements of different colors may be identical to or different from each other, and the dimension along the Y direction may be greater than the dimension along the X direction of the light-emitting region, or the dimension along the Y direction may be less than or equal to the dimension along the X direction of the light-emitting region.

For example, as illustrated in FIG. 22A and FIG. 22B, the shapes of the light-emitting regions of the light-emitting elements 200 emitting light of different colors may be identical to each other, and the light-emitting regions of two adjacent columns of light-emitting elements 200 are offset with respect to each other in the column direction.

For example, as illustrated in FIG. 22C, one column of first color light-emitting elements 201, one column of second color light-emitting elements 202, and one column of third color light-emitting elements 203 form one light-emitting element group 2000, and the arrangements of the light-emitting elements 200 in different light-emitting element groups 2000 are identical to each other. For example, the middle column of light-emitting elements in the light-emitting element group 2000 are blue light-emitting elements, and the light-emitting elements on both sides are red light-emitting elements and green light-emitting elements. For example, the middle column of light-emitting elements in the light-emitting element group 2000 are green light-emitting elements, and the light-emitting elements on both sides are red light-emitting elements and blue light-emitting elements.

For example, as illustrated in FIG. 22D-FIG. 22H, the shapes of the light-emitting regions of the light-emitting elements 200 of different color are different from each other, for example, the shape of the light-emitting region of one column of light-emitting elements 200 is different from the shapes of the light-emitting regions of two columns of light-emitting elements 200 on both sides thereof.

For example, as illustrated in FIG. 22D-FIG. 22H, the light-emitting element group includes three columns of light-emitting elements 200, and the shape of the light-emitting region of the middle column of light-emitting elements 200 may be an ellipse, a hexagon, a quadrangle, an octagon, etc. The shapes of the light-emitting regions of two columns of light-emitting elements 200 on both sides are identical to each other, and may be a hexagon, an ellipse, a quadrangle, a triangle, etc. The shape of the light-emitting regions of the above-mentioned middle column of light-emitting elements 200 can be combined with the shapes of the light-emitting regions of the two columns of light-emitting elements 200 on both sides in any combination.

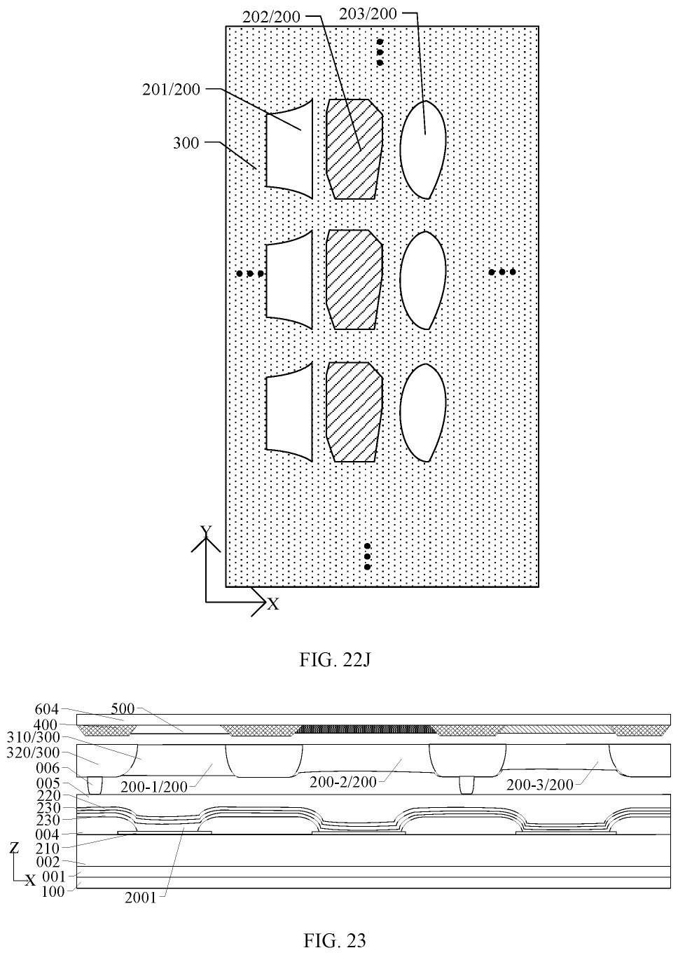

FIG. 23 is a schematic diagram of a partial cross-sectional structure of a display substrate provided by another embodiment of the present disclosure. As illustrated in FIG. 23, the display substrate is a quantum dot substrate, and at least part of the functional elements 200 in the display substrate include quantum dot materials. At least part of the functional elements in the present embodiment may include the characteristics of the ink layer in the light-emitting functional layer in the above-mentioned embodiments. The pixel-defining pattern 300 in the present embodiment may be the structure defining the functional elements 200 illustrated in FIG. 23, and the pixel-defining pattern 300 may have the same characteristics as the pixel-defining pattern in the above-mentioned embodiments.

For example, as illustrated in FIG. 23, a plurality of light-emitting elements 2001 emitting blue light are provided on a light incident side of the display substrate, for example, the light-emitting element 2001 may be a light-emitting element emitting blue light, an organic light-emitting element, or an inorganic light-emitting element, an LED lamp bead, or the like. For example, the functional elements 200 include a first functional element 200-1, a second functional element 200-2, and a third functional element 200-3, the first functional element 200-1 may include a filling layer, and the blue light emitted by the light-emitting element 2001 emitting blue light passes through the filling layer and then emits; the second functional element 200-2 may include a first quantum dot material to convert the incident blue light into red light and exit it; and the third functional element 200-3 may include a second quantum dot material to convert the incident blue light into green light and exit it.

For example, the first functional element 200-1 includes an organic material. For example, the first functional element 200-1 includes at least one of polyimide, acrylic material, optical glue, and the like. For example, the first functional element 200-1 includes an inorganic material. For example, the dam includes at least one of silicon oxide, silicon oxynitride, silicon nitride and the like. For example, the refractive index of the first functional element is not less than 1.4 to improve the light-exiting efficiency and avoid total reflection. For example, the refractive index of the first functional element is not less than 1.5. For example, the refractive index of the first functional element is not less than 1.6. For example, the refractive index of the first functional element is not less than 1.7. For example, the refractive index of the first functional element is not less than 1.8. For example, the first functional element includes at least two materials. For example, the first functional element includes at least two materials, and the two materials have different refractive indices. For example, the first functional element includes at least two materials, and the refractive index of the material with high volume content is less than the refractive index of the material with low volume content to better exit light. For example, the first functional element includes at least two materials, for example, one organic material is doped with another material with a high refractive index to balance process difficulty and optical requirements.

For example, the surface of the side of at least one of the first functional element 200-1, the second functional element 200-2 and the third functional element 200-3 facing the light-emitting element 2001 is a non-flat surface. For example, the surface of the side of at least one of the first functional element 200-1, the second functional element 200-2 and the third functional element 200-3 facing the light-emitting element 2001 is thicker at least in a portion near the defining portion 320 than in a central portion, that is, forming a structure similar to a concave lens to balance and compensate the light-exiting efficiency of each color. For example, the surface of the side of at least one of the first functional element 200-1, the second functional element 200-2 and the third functional element 200-3 facing the light-emitting element 2001 is thinner at least in a portion near the defining portion 320 than in a central portion, that is, forming a structure similar to a convex lens to balance and compensate the light-exiting efficiency of each color. For example, in the first functional element 200-1, the second functional element 200-2, and the third functional element 200-3, the difference between the maximum thickness of a portion, near the defining portion 320, of the surface of the side facing the light-emitting element 2001 and the thickness of the central portion in one functional element is at least partially different from the difference in another functional element, to balance and compensate the light-exiting efficiency of each color. For example, the difference between the maximum thickness of a portion, near the defining portion 320, of the surface of the side of the first functional element 200-1 facing the light-emitting element 2001 and the thickness of the central portion is less than the difference between the maximum thickness of a portion, near the defining portion 320, of the surface of the side of at least one of the second functional element 200-2 and the third functional element 200-3 facing the light-emitting element 2001 and the thickness of the central portion, to balance and compensate the light-exiting efficiency of each color. For example, the maximum thickness of a portion, near the defining portion 320, of the surface of the side of the first functional element 200-1 facing the light-emitting element 2001 is less than the thickness of the central portion to form a structure similar to a convex lens; and the maximum thickness of a portion, near the defining portion 320, of the surface of the side of at least one of the second functional element 200-2 and the third functional element 200-3 facing the light-emitting element 2001 is greater than the thickness of the central portion to form a structure similar to a concave lens.

For example, as illustrated in FIG. 23, a color filter substrate is provided on the light-exiting side of the quantum dot substrate, and the black matrix 400 and the color filter layer 500 provided on the color filter substrate may have the same characteristics as the black matrix 400 and the color filter layer 500 in the above-mentioned embodiments, which will not be repeated here.

For example, as illustrated in FIG. 23, the side, away from the light-emitting functional layer 230, of the second electrode 220 of the light-emitting element that emits blue light is provided with an encapsulation layer 005, and the encapsulation layer 005 may have the same characteristics as the thin film encapsulation layers 701, 702 and 703 in the above-mentioned embodiments.

For example, as illustrated in FIG. 23, the side of the defining portion 320 of the quantum dot substrate away from the color filter layer 500 is provided with a dam 006, and the distance between the light-emitting element 2001 and each functional element can be adjusted as required and maintained at a stable distance to ensure the efficiency and stability of light-exiting. For example, the dam 006 includes the same material as the defining portion 320. For example, the dam 006 includes the same material as the first functional element 200-1. For example, the dam includes an organic material. For example, the dam includes at least one of polyimide, acrylic optical glue material and the like. For example, the dam includes an inorganic material. For example, the dam includes at least one of silicon oxide, silicon oxynitride, silicon nitride and the like. For example, the height of the dam is not less than 1 micron. For example, the height of the dam is not less than 2 microns. For example, the height of the dam is not less than 3 microns. For example, the height of the dam is not less than 4 microns. For example, the height of the dam is not less than 5 microns. For example, the height of the dam is not less than 6 microns. For example, the height of the dam is not less than 7 microns. For example, the height of the dam is not less than 8 microns. For example, the dam is doped with high-refractive-index particles to further improve the light-exiting efficiency. For example, the dam includes reflective material to avoid crosstalk of light. For example, reflective particles such as metal or metal oxide particles or other particles are doped in the dam to further improve the light-exiting efficiency.

For example, the orthographic projection of the first functional element on the base substrate, the orthographic projection of the second functional element on the base substrate and the orthographic projection of the third functional element on the base substrate all completely cover the light-emitting regions of their respective corresponding light-emitting elements 2001. For example, the respective areas of the first functional element, the second functional element, and the third functional element located in the region defined by the defining portion are greater than the areas of the light-emitting regions of their respective corresponding light-emitting elements 2001.

For example, the area of the light-exiting region corresponding to one first functional element is smaller than the area of the light-exiting region corresponding to one second functional element. For example, the area of the light-exiting region corresponding to one first functional element is smaller than the area of the light-exiting region corresponding to one third functional element. For example, the area of the light-exiting region corresponding to one second functional element is smaller than the area of the light-exiting region corresponding to one third functional element. For example, the ratio of the area of the light-exiting region corresponding to one first functional element to the area of the light-exiting region corresponding to one second functional element is less than the ratio of the area of the light-exiting region corresponding to one second functional element to the area of the light-exiting region corresponding to one third functional element.

For example, the centers of at least two of the first functional element, the second functional element, and the third functional element have different thicknesses.

For example, at least one of the first functional element, the second functional element, and the third functional element includes at least two layers. For example, the at least two layers included in at least one of the first functional element, the second functional element, and the third functional element may include the same material or different materials.

For example, the amount of film layers of at least one of the first functional element, the second functional element, and the third functional element is different from the amount of film layers of another functional element.

Another embodiment of the present disclosure provides a display device, including any one of the display substrates in the above-mentioned examples illustrated in FIG. 16-FIG. 23.

For example, the display device provided by the embodiments of the present disclosure is an organic light-emitting diode display device.

For example, the display device further includes a cover plate on the display side of the display substrate.

For example, the display substrate includes a cover plate of at least one of a quantum dot layer and a color filter layer. For example, the display device may be any product or component with a display function, such as a mobile phone, a tablet computer, a notebook computer, a TV, a monitor, a navigator, etc., with an under-screen camera, and the present embodiment is not limited thereto.

For example, the display substrate may also be various types of substrates with optical units, such as a camera, an electronic tag, a display board, an ATM machine, a projector, etc. The display device may also include an electronic device including the above-mentioned display substrate.

The following statements should be noted:
(1) In the accompanying drawings of the embodiments of the present disclosure, the drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto, and the protection scope of the present disclosure should be based on the protection scope of the claims.

1. A display substrate, comprising:
a base substrate;
a plurality of functional elements, located on the base substrate, wherein the plurality of functional elements are configured to exit light, a functional element comprises a functional layer, and the functional layer comprises at least one film layer;
a pixel-defining pattern, wherein the pixel-defining pattern comprises a plurality of openings and a defining portion surrounding the plurality of openings, and the functional layer is at least partially located in the plurality of openings;
wherein the display substrate is distributed with a plurality of first regions and a plurality of second regions, the plurality of first regions respectively correspond to the plurality of openings, at least part of the plurality of second regions are covered by the defining portion, at least one film layer in the functional layer is located in at least part of at least one of the plurality of first regions and located in at least part of at least one of the plurality of second regions, the plurality of first regions are configured to exit light, and the plurality of second regions are provided with at least one light-shielding layer overlapping with the defining portion;
the plurality of functional elements comprise functional elements for exiting light of at least two colors, the functional elements for exiting light of at least two colors comprise a first color functional element configured to exit first color light and a second color functional element configured to exit second color light, and an area of a light-exiting region of the first color functional element is greater than an area of a light-exiting region of the second color functional element; and
the plurality of second regions comprise a plurality of recessed regions, the at least one film layer of the functional layer comprises a portion located in at least one recessed region and a portion located in a light-exiting region adjacent to the at least one recessed region, an area of the at least one recessed region is not greater than an area of the light-exiting region adjacent to the at least one recessed region, a height of a surface, closest to the base substrate, of the least one film layer located in the recessed region relative to the base substrate is a first height, a height of a surface, closest to the base substrate, of the least one film layer located in the light-exiting region adjacent to the recessed region relative to the base substrate is a second height, and the first height is not greater than the second height.

2. The display substrate according to claim 1, wherein the functional layer comprises at least one selected from the group consisting of electroluminescence material, photoluminescence material, electrochromic material, electrowetting material, color filter material and optical medium material.

3. The display substrate according to claim 1, wherein a maximum thickness of a portion of the functional layer located in a recessed region is greater than a maximum thickness of a portion of the functional layer located in a light-exiting region adjacent to the recessed region, or a maximum thickness of the portion of the at least one film layer in the functional layer located in a recessed region is greater than a maximum thickness of the portion of the at least one film layer in the functional layer located in a light-exiting region adjacent to the recessed region;
the maximum thickness is a maximum dimension of the functional layer or the at least one film layer in the functional layer in a direction perpendicular to the base substrate; and
the plurality of recessed regions at least comprise a first recessed region and a second recessed region, the functional layer in the first recessed region comprises the same material as the functional layer in the first color functional element, the functional layer in the second recessed region comprises the same material as the functional layer in the second color functional element, a distance between a center of the light-exiting region of the first color functional element and a center of the first recessed region corresponding to the first color functional element is a first distance, a distance between a center of the light-exiting region of the second color functional element and a center of the second recessed region corresponding to the second color functional element is a second distance, and the first distance is not equal to the second distance.

4. The display substrate according to claim 1, wherein a portion, located between light-exiting regions of adjacent functional elements exiting light of a same color, in the defining portion is a first defining portion, and a distance between a center of the recessed region, located between the light-exiting regions of adjacent functional elements exiting light of a same color, and a center of the first defining portion is in a range of 5-40 microns.

5. The display substrate according to claim 4, wherein at least two recessed regions are provided between the light-exiting regions of adjacent functional elements exiting light with the same color, and the at least two recessed regions are located on at least one side of the center of the first defining portion.

6. The display substrate according to claim 1, wherein at least two adjacent functional elements arranged along a first direction exit light of a same color, at least two adjacent functional elements arranged along a second direction exit light of different colors, and the first direction intersects with the second direction.

7-8. (canceled)

9. The display substrate according to claim 3, wherein the first color functional element is a functional element that emits blue light, and the second color functional element is a functional element that emits green light or a functional element that emits red light; and
the first distance is greater than the second distance.

10. The display substrate according to claim 3, wherein the first color functional element is a functional element that emits red light, the second color functional element is a functional element that emits green light, and the first distance is greater than the second distance;
or the first color functional element is a functional element that emits green light, the second color functional element is a functional element that emits red light, and the first distance is greater than the second distance.

11. (canceled)

12. The display substrate according to claim 6, wherein an orthographic projection of at least one light-exiting region on a straight line extending in the second direction overlaps with an orthographic projection of a recessed region corresponding to the at least one light-exiting region on the straight line extending in the second direction.

13. The display substrate according to claim 6, wherein a virtual straight line parallel to the first direction passes through a light-exiting region and a recessed region closest to the light-exiting region, edges close to each other of the light-exiting region and the recessed region intersect with the virtual straight line to form two intersection points, and a distance between the two intersection points is greater than a distance between an orthographic projection of the light-exiting region on a straight line extending in the first direction and an orthographic projection of the recessed region on the straight line extending in the first direction.

14. The display substrate according to claim 1, wherein a nearest distance between at least two adjacent recessed regions is less than a distance from one recessed region of the at least two adjacent recessed regions to a light-exiting region close to the one recessed region.

15. (canceled)

16. The display substrate according to claim 1, wherein thicknesses of two portions, of the at least one film layer on the base substrate, located in the recessed region and another region outside the recessed region are respectively a first sub-thickness and a second sub-thickness; or
the at least one film layer on the base substrate comprises a portion located in the light-exiting region, and the at least one film layer does not overlap with at least part of the recessed region.

17. The display substrate according to claim 16, wherein the functional element comprises a light-emitting element, the functional layer comprises a light-emitting functional layer, the light-emitting element comprises a first electrode, the light-emitting functional layer and a second electrode that are stacked sequentially, and the first electrode is located between the light-emitting functional layer and the base substrate; and
the at least one film layer comprises at least one selected from the group consisting of an insulating layer, the defining portion, and the first electrode.

18. The display substrate according to claim 1, wherein a portion, located between light-exiting regions of adjacent functional elements exiting light of different colors, in the defining portion is a second defining portion, and a thickness of the at least one film layer in the recessed region is less than a thickness of the at least one film layer in a region where the second defining portion is located; or
the at least one film layer is located in the region where the second defining portion is located, and does not overlap with at least part of the recessed region.

19-22. (canceled)

23. The display substrate according to claim 1, wherein the functional element comprises a light-emitting element, the functional layer comprises a light-emitting functional layer, the light-emitting element comprises a first electrode, the light-emitting functional layer and a second electrode that are stacked sequentially, and the first electrode is located between the light-emitting functional layer and the base substrate; and
a thickness of a portion of at least one film layer, on a side of the first electrode away from the base substrate, located in the recessed region is a third sub-thickness, a thickness of at least portions of the at least one film layer, on the side of the first electrode away from the base substrate, located in another region outside the recessed region is a fourth sub-thickness, and the third sub-thickness is not less than the fourth sub-thickness.

24. The display substrate according to claim 23, wherein the at least one film layer on the side of the first electrode away from the base substrate comprises at least one of an organic layer and the functional layer.

25-28. (canceled)

29. The display substrate according to claim 1, wherein maximum thicknesses of two portions, of the at least one film layer of the functional layer, located in the recessed region and located in a light-exiting region of a functional element corresponding to the recessed region are respectively a first maximum thickness and a second maximum thickness, and the first maximum thickness is not less than the second maximum thickness; or
a maximum thickness of an entire portion, of the functional layer, located in the recessed region is not less than a maximum thickness of an entire portion, of the functional layer, located in a light-exiting region of a functional element corresponding to the recessed region.

30. The display substrate according to claim 1, wherein a distance between a surface, of a portion of the at least one film layer of the functional layer located in the recessed region, away from the base substrate and the base substrate is a third distance,
a distance between a surface, of a portion of the at least one film layer of the functional layer located in a light-exiting region of a functional element corresponding to the recessed region, away from the base substrate and the base substrate is a fourth distance, and
the fourth distance is greater than the third distance.

31. The display substrate according to claim 30, wherein a portion, located between light-exiting regions of adjacent functional elements exiting light of different colors, in the defining portion is a second defining portion, and an extending direction of at least part of the second defining portion is identical to an arrangement direction of the adjacent functional elements exiting light of different colors; and
a surface of a side, of a portion of the second defining portion close to the light-exiting region, away from the base substrate comprises a defining slope, a distance between a surface, of a portion of the at least one film layer of the functional layer located at the defining slope, away from the base substrate and the base substrate is a fifth distance, and the fifth distance is greater than the fourth distance.

32-34. (canceled)

35. A display device, comprising the display substrate according to claim 1.
